(19) United States
(12) Patent Application Publication
(10) Pub. No.: US 2025/0035474 A1
(43) Pub. Date: Jan. 30, 2025

(54) METHODS AND SYSTEMS FOR FILTERING AND ESTIMATING CHARACTERISTICS OF AN INPUT SIGNAL USING A TRACKER COMPRISING A PRISM FILTER

(71) Applicants: Oxford University Innovation Limited, Oxford (GB); Coventry University, Coventry (GB)

(72) Inventor: Manus Patrick HENRY, Oxford (Oxfordshire) (GB)

(21) Appl. No.: 18/716,524

(22) PCT Filed: Nov. 14, 2022
(86) PCT No.: PCT/GB2022/052883

§ 371 Date: Jun. 5, 2024

(30) Foreign Application Priority Data
Dec. 7, 2021 (GB) 2117630.0

(51) Int. Cl. G01F 1/84

(52) U.S. Cl. CPC G01F 1/8436; G01F 1/8431

(57) ABSTRACT

A method of estimating characteristics of an input signal comprises inputting the input signal into a first tracker to determine a first estimate of characteristics of the input signal, and determining a normalised signal from the input signal. The normalised signal is input into a second tracker to determine a second estimate of characteristics of the input signal. At least one of the first tracker and the second tracker comprises or is derived from at least one Prism filter. Further, a method of filtering an input signal is provided. The method comprises applying a sequence of one or more filter stages to the input signal to generate respective downsampled signals. A tracker stage is applied to the output of the final filter stage to determine one or more characteristics of the input signal.

The invention relates to a methods and systems for filtering and characterising input signals using filters comprising or derived from Prism filters.

A Prism filter is a filter type that combines the benefits of Finite Impulse Response (FIR) filters and Infinite Impulse Response (IIR) filters. Prism filters are discussed in US2019294649A1 (herein referred to as reference [A]) and WO2019211309A1 (herein referred to as reference [B]). Both of these documents are incorporated herein by reference in their entirety.

The prior art Prism [A, 1] and ultra-narrowband Prism filter [B, 2, 3] provide a number of advantages over conventional convolution-based Finite Impulse Response (FIR) filtering. These advantages may include significantly reduced computational cost for both the initial filter design and for subsequent filter operation, for example in terms of the number of floating point operations required to update the filter output on receipt of a new input. However, these structures do have limitations. One limitation of the filter structure described in [B, 2] is that the stop band attenuation may be no lower than approximately −80 dB. A further limitation is that for long filters, for example exceeding 1 billion samples [2], the memory storage requirements may be large. A yet further limitation is that, although the design cost of an individual filter of the type described in [B, 2] may be low, in applications where large numbers of different filter designs are required, for example in spectral analysis of fixed data sets [3], the total filter design cost may remain high. An additional limitation, common to many filtering systems and well understood by those familiar with the art, is the tradeoff between filtering performance (for example the extent to which unwanted signal components are removed by the filter) and dynamic response (for example the time delay occurring between a change in the filter input and the corresponding change in the filter output). For FIR filters such as the Prism, it is well understood by practitioners of the art that the dynamic response is determined by the length of the filter in samples—the filtered response to a change in a characteristic of the input signal is complete once data with the new characteristic has passed through the entire length of the filter. Accordingly, as shorter filters have a faster dynamic response, it is desirable to find means of maintaining or improving filtering performance while maintaining or reducing filter length.

Ref [4] describes an alternative Prism filter structure, which may be described as ‘low pass’, contrasting with the ‘band pass’ design of [B, 2]. This filter structure consists of a series of layers or sets, where each layer contains three Prisms, and where a weighted sum of the outputs of the individual Prisms in each layer is calculated and used as the input to the next layer. As discussed further below, in the prior-art design, the outputs of the Prisms in each layer or set are all in phase. The weights are selected to provide a desired filter characteristic, for example maximizing the attenuation of the stop band. In reference [4], for example, a six layer filter is described which provides stopband attenuation of −138 dB. For this type of filter structure, the range of frequencies lying in the passband (i.e. those frequencies which are assigned a high gain by the filter) is fixed by the selected set of weights. Typically the pass band will lie between 0 Hz and the characteristic frequency m Hz, and hence the designation of the filter structure as ‘low pass’. However, as further explained in [4] and below, the technique of heterodyning, well-known to practitioners of the art, may be used in combination with a low pass filter to adjust the pass band frequency range. This low pass filtering structure may therefore be used to address several of the limitations of the band pass filter structure taught in the prior art [B, 2], as follows. Firstly, a single filter design, combined with the technique of heterodyning, can be used as a substitute for instantiating a series of distinct band pass filter designs, for example in spectral analysis (as described in [3]), thus reducing filter design cost. Secondly, a wider range of filter characteristics can be incorporated into a layered filter structure compared with the fixed characteristic of the band pass filter in [B, 2]: for example, higher stopband attenuation can be achieved. Thirdly, by applying Prisms in parallel, improved filter design may be possible while maintaining the overall filter length.

The techniques outlined above, which form the prior art, retain a number of limitations, including the tradeoff between filtering performance and dynamic response, and the memory requirements for large filters. It is an object of this invention to improve one or more such limitations.

This disclosure presents new Prism low pass filter structures, which may provide an improved tradeoff between filtering performance and dynamic response. These new filter structures may further provide greater design flexibility, enabling, for example, the ability to create a filter with a desirable degree of passband flatness and/or of stopband attenutation. The disclosure further presents techniques employing multiple Prism low pass filters, which may provide improved tradeoff between filtering performance and dynamic response. As large numbers of Prisms may be used in such layered filter structures, the relative computational advantage over the conventional convolutional calculation form of FIR filter may be reduced. Accordingly, this disclosure further describes methods and systems for converting a Prism-based filter network into one or more corresponding convolutional filters, which may have reduced computation and memory requirements, thus providing a novel and effective means of convolutional filter design. Such convolutional filters may prove particularly effective for spectral analysis, providing powerful, flexible, and precise enhancements to the very widely used Fast Fourier Transform.

According to a first aspect of the invention there is provided a filter system for filtering an input signal, the filter system comprising: a network of Prism filters arranged to receive the input signal as an input, the network of Prism filters comprising at least one cosine Prism filter and at least one sine Prism filter, wherein each Prism filter is configured to evaluate combinations of double integrals of the form:

$${I}_{[ S \vert C ] [ S \vert C ]}^{h} = {m}^{2} {\int }_{- \frac{1}{m}}^{0} [ sin \vert cos ] ( 2 π hmt + q ) ( {{\int }_{t - \frac{1}{m}}}^{t} [ sin \vert cos ] ( 2 π hmt + q ) \cdot s ( t ) dt ) dt ,$$

where s(t) is an input to the respective Prism filter, m is a characteristic frequency of the respective Prism filter, [sin|cos] represents a sine or a cosine operation, q is an optional, arbitrary phase offset variable, and h is a harmonic number of the respective Prism filter of the network of Prism filters. Each cosine Prism filter is configured to determine a respective cosine output Gch, where G_{c}^{h}=I_{cs}^{h}−I_{sc}^{h}. Each sine Prism filter is configured to determine a respective sine output Gₛ^{h}, where Gₛ^{h}=Iₛₛ^{h}+I_{cc}^{h}. The network of Prism filters comprises a first branch in parallel with a second branch, each of the first branch and second branch arranged to receive the input signal as an input, the first branch comprising the at least one cosine Prism filter, the second branch comprising the at least one sine Prism filter, and wherein the network of Prism filters is arranged to generate an output signal based on a combination of an output of the first branch with an output of the second branch.

The input signal is a signal measured from and/or representing a physical entity or physical parameter. The input signal may be a signal measured by a (physical) sensor. The input signal may be a signal measured by a scientific or industrial instrument. The input signal may be, or be a representation of, an audio signal, video signal, communications signal, system control signal, seismological signal, biological signal, electrical power signal, radar signal, sonar signal, or signal representing measurements of physical quantities measured by a scientific or industrial instrument.

In contrast to the prior art filter systems discussed above, the filter systems of the first aspect of the present invention use two branches of filters in parallel, one cosine, one sine. This approach allows more flexibility in the design of the filter system, allowing filtering with a sharper passband cut-off and/or flatter intra-passband shape. This can provide better filtering performance, for the same filter length, and thus same delay time, as the previous systems.

In some embodiments the first branch comprises two or more cosine filter sets connected in series such that an output of a respective preceding cosine filter set in the series is input into a respective subsequent cosine filter set of the series, wherein the output of the first branch is an output of a final cosine filter set in the series, and wherein each cosine filter set comprises at least one cosine Prism filter, and wherein the second branch comprises two or more sine filter sets connected in series such that an output of a respective preceding sine filter set in the series is an input into a respective subsequent sine filter set of the series, wherein the output of the second branch is an output of a final sine filter set in the series, and wherein each sine filter set comprises at least one sine Prism filter.

In some embodiments the first branch comprises an even number of cosine filter sets, and the second branch comprises an even number of sine filter sets.

Using two filter sets (or any even number of filter sets) per branch allows the two branches to be linearly combined (e.g., summed). With even number of filter sets the phase at the output of each branch will be the same, allowing direct combination without additional processing, avoiding distortion of the phase characteristics of the combined signal.

In some embodiments, one or more of the cosine filter sets and/or one or more of the sine filter sets comprises a plurality of cosine/sine Prism filters connected in parallel such that the input to the respective cosine/sine filter set is input into each of the plurality of cosine/sine Prism filters of that cosine/sine filter set, and the output of the respective cosine/sine filter set is a combination of the outputs of the plurality of cosine/sine Prism filters of that cosine/sine filter set. In other words, the filter set may comprise two branches connected in parallel, each branch comprising filters connected in parallel to form respective sets. The various sets of each branch are connected in series. A respective weight may be applied to the output of each of the plurality of cosine/sine Prism filters of a cosine/sine filter set prior to generating the output of that cosine/sine filter set. In this way the impact of each set on the final output can be tailored to the desired properties of the filter set.

In some embodiments, the weights are selected using optimisation based on gain functions of the Prism filters of the filter network. It has been found that this is an efficient process for deriving weightings that achieve a desired filtering response of the filter system.

In some embodiments, the network of Prism filters comprises a combined filter set comprising at least one combined Prism filter, each combined Prism filter configured to determine a respective cosine output G_{c}^{h} and a respective sine output Gₛ^{h}, wherein the combined filter set is arranged to provide a first filter set of both the first branch and the second branch by receiving the input signal and outputting a cosine output to the first branch and a sine output to the second branch. This arrangement generates the same cosine and sine outputs that would be generated by separate first sets of cosine and sine filters, but is more computationally efficient.

In some embodiments, the filter system further comprises a tracker formed of one or more Prism filters, wherein the tracker is configured to receive the output signal from the network of Prism filters, and to generate an output indicative of a parameter of the input signal. For example the output may be indicative of one more or more of the amplitude, phase, and frequency of the input signal. Such embodiments directly provide useful parameters of the input signal by application of the filter system, without requiring further computation.

In some embodiments the filter system further comprises a tracker formed of one or more Prism filters, wherein the tracker is configured to receive the output signal from the network of Prism filters, and to generate one or more outputs selected from the group comprising: G_{c}¹, Gₛ¹, G_{c}², and Gₛ², where G_{c}^{h}=I_{cs}^{h}−I_{sc}^{h}, Gₛ^{h}=Iₛₛ^{h}+I_{cc}^{h}, G_{c}¹=G_{c}^{h} when h=1, G_{c}²=G_{c}^{h} when g=2, Gₛ¹=Gₛ^{h} when h=1, and Gₛ²=Gₛ^{h} when h=2. These outputs can be combined to derive parameters of the input signal. Alternatively such filter systems can be used to generate convolutional filters, with the advantages described below in relation to the fifth aspect of the invention.

In accordance with a second aspect of the invention there is provided a method of filtering an input signal, the method comprising instantiating a filter system according to any embodiment of the first aspect, and inputting the input signal into the instantiated filter system to filter the input signal.

In accordance with a third aspect of the invention there is provided a method of designing a convolutional filter for filtering an input signal, the method comprising: generating a filter system arranged to receive the input signal, the filter system comprising at least one Prism filter, wherein: each Prism filter is configured to evaluate double integrals of the form:

$${I}_{[ S \vert C ] [ S \vert C ]}^{h} = {m}^{2} {\int }_{- \frac{1}{m}}^{0} [ sin \vert cos ] ( 2 π hmt + q ) ( {{\int }_{t - \frac{1}{m}}}^{t} [ sin \vert cos ] ( 2 π hmt + q ) \cdot s ( t ) dt ) dt ,$$

where s(t) is an input to the respective Prism filter, m is a characteristic frequency of the respective Prism filter, [sin|cos] represents a sine or a cosine operation, q is an optional and/or arbitrary phase offset variable, and h is a harmonic number of the respective Prism filter, inputting a test signal into the filter system to generate an impulse response of the filter system; and generating a convolutional filter for filtering the input signal based on the impulse response of the filter system. In preferred embodiments, the test signal is an impulse signal. The motivation behind the prior art Prism filters was to replace convolutional FIR filters to improve computational efficiency. The computational cost of a long Prism filter can be more than ten million times less than an equivalent conventional convolutional FIR filter. However. the memory storage requirements for such Prism filters can be substantially higher than for a convolutional filter. Surprisingly, it has been found that the memory storage requirements can be reduced by converting a constructed Prism filter into a convolutional filter. The resulting convolutional filter retains the beneficial filtering properties from the Prism filter, without requiring the same memory storage requirements.

As for the first aspect, the input signal is a signal measured from and/or representing a physical entity or physical parameter. The input signal may be a signal measured by a (physical) sensor. The input signal may be a signal measured by a scientific or industrial instrument. The input signal may be, or be a representation of, an audio signal, video signal, communications signal, system control signal, seismological signal, biological signal, electrical power signal, radar signal, sonar signal, or signal representing measurements of physical quantities measured by a scientific or industrial instrument.

In some embodiments, the impulse response is output directly as the convolutional filter. In other embodiments additional processing may be performed to generate the convolutional filter.

Some embodiments further comprise combining the generated convolutional filter with a tracker arranged to receive the output of the convolutional filter, wherein the tracker comprises a Prism filter configured to generate an output indicative of a parameter of the input signal input into the convolutional filter. The single (or few) Prism tracker may not add significantly to the memory requirements of the generated filter system, but is able to directly output useful information about the input signal. The parameter of the input signal may be at least one of: amplitude, phase, and frequency. In alternative embodiments the Prism filter system itself is or comprises a tracker configured to generate an output indicative of a parameter of the input signal, such that the generated convolutional filter acts as a tracker configured to generate an output indicative of the parameter of the input signal.

In preferred embodiments, the Prism filter system is a filter system according to any embodiment of the first aspect. However, it will be appreciated that the filter system may comprise any other arrangement of Prism filters.

In some embodiments, the filter system is arranged to generate an output selected from the group comprising: G_{c}¹, Gₛ¹, G_{c}², and Gₛ², such that the convolutional filter is configured to generate a corresponding output G_{c}¹, Gₛ¹, G_{c}², or Gₛ², where G_{c}^{h}=I_{cs}^{h}−I_{sc}^{h}, Gₛ^{h}=Iₛₛ^{h}+I_{cc}^{h}, G_{c}¹=G_{c}^{h} when h=1, G_{c}²=G_{c}^{h} when h=2, Gₛ¹=Gₛ^{h} when h=1, and Gₛ²=Gₛ^{h} when h=2. Alternatively the filter system may comprise a low-pass or band-pass Prism filter and a tracker Prism filter, the low/band-pass filter arranged to filter an input signal, and the tracker filter arranged to generate the respective output G_{c}¹, Gₛ¹, G_{c}², or Gₛ² from the output of the low-pass filter, resulting in the convolutional filter generating the corresponding output. The outputs of such convolutional filters can be combined to generate one or more properties of the input signal, similarly to the equivalent outputs directly from the Prism system discussed above. In cases such as filters with long sample lengths, it may be preferable to use the convolutional form of the filters rather than the Prism filter system. Further advantageously, such outputs can be further processed using a FFT algorithm, as discussed further below.

In accordance with a fourth aspect of the invention there is provided a method of filtering an input signal, the method comprising instantiating one or more convolutional filters designed using the method of any embodiment of the third aspect, and inputting the input signal into the instantiated filter(s) to filter the input signal.

In accordance with a fifth aspect of the invention there is provided a method of filtering an input signal, the method comprising: providing two or more convolutional filters, each convolutional filter of the two or more convolution filters generated using one of the embodiments of the third aspect which cause the convolutional filters to generate a respective one of the outputs G_{c}¹, Gₛ¹, G_{c}² and Gₛ²; applying each of the two or more convolutional filters to the input signal to generate the outputs G_{c}¹, Gₛ¹, G_{c}², and Gₛ²; and generating at least one of the amplitude, frequency and phase of the input signal based on the outputs G_{c}¹, Gₛ¹, G_{c}², and Gₛ².

In some embodiments, the two or more convolutional filters comprise four convolutional filters, each convolutional filter of the four convolutional filters generated wherein: applying each of the four convolutional filters comprises: heterodyning the input signal using a plurality of heterodyne frequencies selected based on a pass-band of the low-pass or band-pass Prism filter, and applying each of the four convolutional filters to the heterodyned input signal for each heterodyne frequency to generate the outputs G_{c}¹, Gₛ¹, G_{c}², and Gₛ² for each heterodyne frequency; and generating at least one of the amplitude, frequency and phase of the input signal comprises generating the at least one of amplitude, frequency and phase of the heterodyned input signal for each heterodyne frequency based on the outputs G_{c}¹, Gₛ¹, G_{c}², and Gₛ² generated for that heterodyne frequency. Heterodyning allows the convolutional filters to be applied to input signals with arbitrary frequencies. Heterodyning shifts a continuous range of frequencies which are to be analysed into the passband range of the convolutional filters (as designed by the initial Prism system). By applying multiple heterodyne frequencies to the input signal, various frequency components of the signal can shifted successively into the filter passband. Thus the filter outputs can be derived for a range of frequencies, allowing spectral analysis of the input signal. For example the filter outputs can be combined to determine a property of the input signal, such as amplitude or phase. The heterodyning approach allows a spectral analysis of such properties.

In some embodiments, a Fourier transform algorithm is applied to the output of each convolutional filter of the two or more convolutional filters to generate two or more of the outputs G_{c}¹, Gₛ¹, G_{c}², and Gₛ². The Fourier transform algorithm is preferably a fast Fourier transform (FFT) algorithm. Such embodiments are particularly advantageous. They allow spectral analysis of an input signal using the computationally efficient FFT process. The initial design from the Prism filter system provides sharp stopband attenuation, which suppresses the spectral leakage that is problematic in conventional FFT applications.

In some embodiments, the method further comprises: estimating frequencies of peaks in the generated amplitude, frequency and/or phase (using either the FFT or heterodyne approaches); and reapplying each of the two or more convolutional filters to the input signal based on the estimated peak frequencies to generate updated values for amplitude, frequency and/or phase by: heterodyning the input signal using heterodyne frequencies corresponding to each of the estimated peak frequencies; and applying each of the two or more convolutional filters to the heterodyned input signal for each heterodyne frequency corresponding to an estimated peak frequency to generate two or more of the outputs G_{c}¹, Gₛ¹, G_{c}² and Gₛ² for each heterodyne frequency; and generating updated values for amplitude, frequency and/or phase of the heterodyned input signal for each heterodyne frequency corresponding to an estimated peak frequency based on the at least two outputs selected from G_{c}¹, Gₛ¹, G_{c}², and Gₛ² generated for that heterodyne frequency. Such embodiments allow the initial estimates of parameters of the input signal, such as amplitude and/or peak frequency, to be refined, providing more accurate results.

In accordance with a sixth aspect there is provided a method of estimating characteristics of an input signal, the method comprising: inputting the input signal into a first tracker to determine a first estimate of characteristics of the input signal, the first estimate comprising a first amplitude estimate and a first frequency estimate, determining a normalised signal from the input signal by: normalising the amplitude of the input signal using the first amplitude estimate; and/or heterodyning the input signal using a heterodyne frequency determined based on a sum and/or difference between the first frequency estimate and a filter frequency; and inputting the normalised signal into a second tracker to determine a second estimate of characteristics of the input signal, the second tracker comprising at least one Prism filter, wherein the second tracker is configured to pass a narrower range of frequencies than the first tracker, and wherein the second tracker is configured to pass the filter frequency; wherein at least one of the first tracker and the second tracker comprises or is derived from at least one Prism filter, wherein: each Prism filter is configured to evaluate double integrals of the form:

$${I}_{[ S \vert C ] [ S \vert C ]}^{h} = {m}^{2} {\int }_{- \frac{1}{m}}^{0} [ sin \vert cos ] ( 2 π hmt + q ) ( {{\int }_{t - \frac{1}{m}}^{t}}^{} [ sin \vert cos ] ( 2 π hmt + q ) \cdot s ( t ) dt ) dt ,$$

where s(t) is an input to the respective Prism filter, m is a characteristic frequency of the respective Prism filter, [sin|cos] represents a sine or a cosine operation, and q is an optional phase offset variable, and h is a harmonic number of the respective Prism filter.

In conventional filters, there is typically a tradeoff between achieving good noise suppression, and successfully tracking a dynamic change in the input signal. A filter which is strong enough to suppress noise may also suppress rapid dynamic changes. Embodiments of the sixth aspect provide tracking of dynamic changes in combination with good noise suppression. This is achieved by using two filtering stages. The first stage provides approximate estimates of amplitude and/or frequency of the input signal. These estimates can be used to normalise the input signal, ‘levelling’ amplitude peaks and placing the frequency of the normalised signal in the range of a narrowband Prism filter. The narrowband filter can then provide a more accurate estimate of the amplitude and/or frequency of the input signal.

In preferred embodiments, the first tracker and/or second tracker comprises or is derived from a filter system according to any embodiment of the first aspect. The first and/or second tracker may be implemented as a Prism, i.e. by instantiating a network of Prism filters and inputting the input signal into the network of Prism filters. Alternatively, the first and/or second tracker (or part thereof) may be a convolutional filter derived from a network of Prism filters. In particular, the first and/or second tracker (or part thereof) may be a convolutional filter generated using the method of any embodiment of the third aspect. Such convolutional filters can provide the filtering advantages of Prism instantiations, without the requirement for large memory storage of Prism coefficients. Inputting the signals into the first tracker and/or second tracker may comprise performing the method of any embodiment of the fifth aspect.

In some embodiments the first tracker and/or second tracker comprises a filtering component and a tracking component. The filtering component may be a convolutional filter as above. The tracking component is or comprises a Prism filter. That is, the tracking component is a Prism instantiation. The tracking component itself may have relatively few coefficients to store, and so may be more practical to implement as a Prism instantiation than the larger filtering component.

In some embodiments, respective values of the first amplitude estimate and/or first frequency estimate are determined for each of a plurality of samples in the input signal. Normalising the amplitude of the input signal may comprise dividing each of the plurality of samples of the input signal by the respective value of the first amplitude estimate. Heterodyning the input signal may comprise heterodyning each of the plurality of samples of the input signal based on a sum and/or difference of the respective value of the first frequency estimate and the target frequency. Such embodiments provide a fully dynamic normalisation of the input signal, adapting to changes during the course of the input signal which allows the second tracker provide accurate estimates of the amplitude and/or frequency of the input signal at a particular moment in the input signal.

According to a seventh aspect of the invention there is provided a signal characterisation device for estimating characteristics of an input signal, the device comprising: a first tracker configured to determine a first estimate of characteristics of the input signal; a second tracker configured to determine a second estimate of the characteristics of the input signal; and a control unit configured to perform the method of any embodiment of the sixth aspect to estimate characteristics of the input signal; wherein at least one of the first tracker and the second tracker comprises or is derived from at least one Prism filter.

According to an eighth aspect of the invention there is provided a method of filtering an input signal, the method comprising: applying a sequence of one or more filter stages to the input signal, wherein: the input to a first filter stage in the sequence is the input signal, and the input to any subsequent filter stages in the sequence is a respective downsampled signal generated by an immediately preceding filter stage; and applying a respective filter stage of the sequence of one or more filter stages comprises: heterodyning the input for the respective filter stage based on a respective target frequency and a respective filter frequency; applying a respective convolutional filter to a subset of samples of the heterodyned input selected based on a respective downsampling factor, the respective convolutional filter configured to pass the respective filter frequency; generating a respective downsampled signal from outputs of the respective convolutional filter applied to the subset of samples; and applying a tracker stage to the downsampled signal generated by a final filter stage in the sequence of one or more filter stages, wherein applying the tracker stage comprises: heterodyning the downsampled signal generated by the final filter stage based on a tracker target frequency and a tracker filter frequency; applying a tracker filter to the heterodyned downsampled signal generated by the final filter stage to determine one or more characteristics of the input signal; wherein each respective convolutional filter is derived from a network of Prism filters comprising at least one Prism filter, and the tracker filter comprises or is derived from at least one Prism filter, wherein each Prism filter is configured to evaluate double integrals of the form:

$${I}_{[ S \vert C ] [ S \vert C ]}^{h} = {m}^{2} {\int }_{- \frac{1}{m}}^{0} [ sin \vert cos ] ( 2 π hmt + q ) ( {{\int }_{t - \frac{1}{m}}^{t}}^{} [ sin \vert cos ] ( 2 π hmt + q ) \cdot s ( t ) dt ) dt ,$$

where s(t) is an input to the respective Prism filter, m is a characteristic frequency of the respective Prism filter, [sin|cos] represents a sine or a cosine operation, and q is an optional phase offset variable, and h is a harmonic number of the respective Prism filter.

Embodiments of the eighth aspect provide ultra-narrowband filtering of an input signal. This may be used for example for tracking small frequency changes of a component of the input signal. It has previously been demonstrated that networks of Prism filters can provide ultra-narrow filtering, for example down to a 0.01 HZ passband on a 20 MHz sampled signal. However, such Prism networks can require a large amount of memory to store filter coefficients. Embodiments of the eighth aspect use the realisation that Prism networks can be converted to a convolutional form (as discussed in relation to the third aspect). Such convolutional filters retain filtering ability with reduced memory requirements. Embodiments of the eighth aspect leverage such convolutional filters in combination with downsampling and heterodyning, resulting in computationally efficient ultra-narrowband filtering.

In some embodiments, applying the final filter stage further comprises determining an estimate of characteristics of the respective input to the final filter stage by applying an estimator tracker to the respective subset of samples of the final filter stage, wherein the estimate of characteristics comprises one or more of frequency, phase and/or amplitude estimates, and wherein the estimator tracker is derived from at least one Prism filter. In some embodiments these estimates can be used as a sense check on the downsampling parameters. Advantageously, however, the estimates can also be used to normalise the signal input into the tracker filter, similarly to the method of the sixth aspect. This can improve the accuracy accurate of the characteristics of the input signal determined by the tracker filter. In particular, in some embodiments the estimate of characteristics comprises a frequency estimate; and in the step of applying the tracker stage, the frequency estimate is used as the tracker target frequency. Alternatively or additionally, in some embodiments the estimate of characteristics comprises an amplitude estimate; and in the step of applying the tracker stage, the heterodyned downsampled signal generated by the final filter stage is normalised using the amplitude estimate prior to before applying the tracker filter. Such embodiments may further use any embodiment of the method of the sixth aspect.

In some embodiments, each respective convolutional filter is generated from an impulse response of a network of Prism filters. In particular, each respective convolutional filter may be generated using the method of any embodiment of the third aspect. The convolutional filters may be derived from a filter system according to any embodiment of the first aspect.

In accordance with an ninth aspect of the invention, there is provided a filter system for filtering an input signal, the filter system comprising: a sequence of one or more filter stages, each filter stage of the one or more filter stages comprising a respective convolutional filter, the first filter stage configured to receive the input signal as an input, and each subsequent filter stage configured to receive an output of an immediately preceding filter stage in the sequence of filter stages as a respective input; a tracker stage comprising a tracker filter configured to receive an output of a final filter stage of the sequence of filter stages as an input; and one or more heterodyne blocks configured to heterodyne the respective inputs of each filter stage; wherein the filter system is configured to perform the method of any embodiment of the eighth aspect.

In any embodiment of the sixth to ninth aspects, the characteristics of the input signal may include a frequency of the input signal. The method may further comprise detecting a change in the frequency of the input signal. Alternatively or additionally, the method may further comprise calibrating a clock frequency based on the determined frequency of the input signal.

In any embodiment of the first to ninth aspects, the input signal may be, or may be a representation of, an audio signal, video signal, communications signal, system control signal, seismological signal, biological signal, electrical power signal, radar signal, sonar signal, or signal representing measurements of physical quantities measured by a scientific or industrial instrument.

In any embodiment of the first to ninth aspects, the filter system or convolutional filter/s (i.e. the convolutional filter/s generated by the method) may be for low pass or bandpass filtering of the signal.

In any embodiment of the first to ninth aspects, the filter system or convolutional filter/s may be for filtering a signal output by a sensor or other physical instrument measuring a physical parameter, or may be configured to filter a signal output by a sensor or other physical instrument. The filter system or convolutional filter/s may be part of the sensor or physical instrument, and/or may directly receive the signal from the sensor and/or physical instrument. In any embodiment of the first to ninth aspects, the input signal may be, or may be a representation of, a signal output by a sensor.

In any embodiment of the first to ninth aspects, the filter system or convolutional filter/s may be for filtering signals from a Coriolis meter, or may be configured to filter an input signal received from a Coriolis meter. In any embodiment of the first to ninth aspects, the input signal may be or may represent a measurement taken by a Coriolis meter.

According to a tenth aspect of the invention there is provided a Coriolis meter comprising a filter system, convolutional filter, signal characterisation device according to any embodiment of the first to fifth, seventh, or ninth aspects, or configured to perform the method of any embodiment of the third, fifth, sixth, or eighth aspects.

In any embodiment of the first to ninth aspects, the filter system or convolutional filter/s may be for filtering signals representative of medical images, or configured to filter signals representative of medical images. In any embodiment of the first to ninth aspects, the input signal may be a signal representative of a medical image.

In any embodiment of the first to ninth aspects the filter system or convolutional filter/s may be for filtering biological signals, or configured to filter biological signals. In any embodiment of the first to ninth aspects the input signal may be a biological signal.

The biological signals may in particular embodiments by neural signals.

In any embodiment of the first to ninth aspects the filter system or convolutional filter/s may be for filtering communications signals or audio signals, or may be configured to filter communications signals or audio signals. In any embodiment of the first to ninth aspects the input signal may be a communications signal or audio signal.

The filter system, convolutional filter/s, signal characterisation device, or method of any embodiment of the first to ninth aspects may be implemented on a computer, or may be implemented on a computer readable medium, or may be implemented as a computer program.

According to an eleventh aspect of the invention there is provided a sensor device comprising a sensor configured to measure one or more physical parameters; and a filter block configured to receive an input signal from the sensor representative of the measured physical parameter and to output a filtered signal. The filter block comprises an instantiation of the filter system and/or convolutional filter/s of any embodiment of the first to ninth aspects, wherein the instantiation of the filter system/convolutional filter/s is configured to receive and filter the input signal to generate the filtered signal. Alternatively or additionally, the filter block may be configured to perform the method of any of the second to sixth or eighth aspects.

According to a twelfth aspect of the invention there is provided a computer program storing instructions which, when executed by a computer cause the computer to perform the method of any embodiment of the second to sixth or eighth aspects.

According to a thirteenth aspect of the invention there is provided a computer readable medium storing instructions which, when executed by a computer cause the computer to perform the method of any embodiment of the second to sixth or eighth aspects. The computer readable medium may be a transitory or non-transitory computer readable medium.

Embodiments of the invention will now be described, by way of example only, with reference to the accompanying drawings in which corresponding reference symbols indicate corresponding parts, and in which:

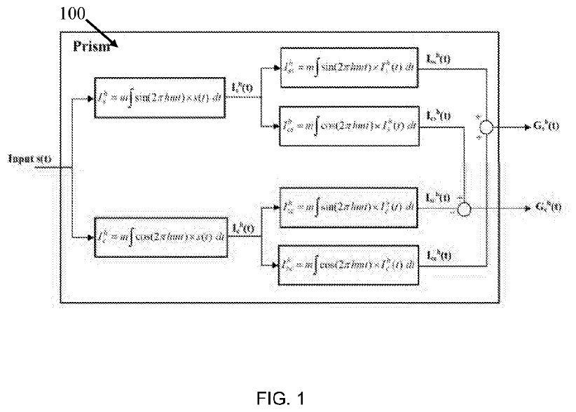

FIG. 1 is an exemplary graph illustrating the structure of Prism signal-process blocks.

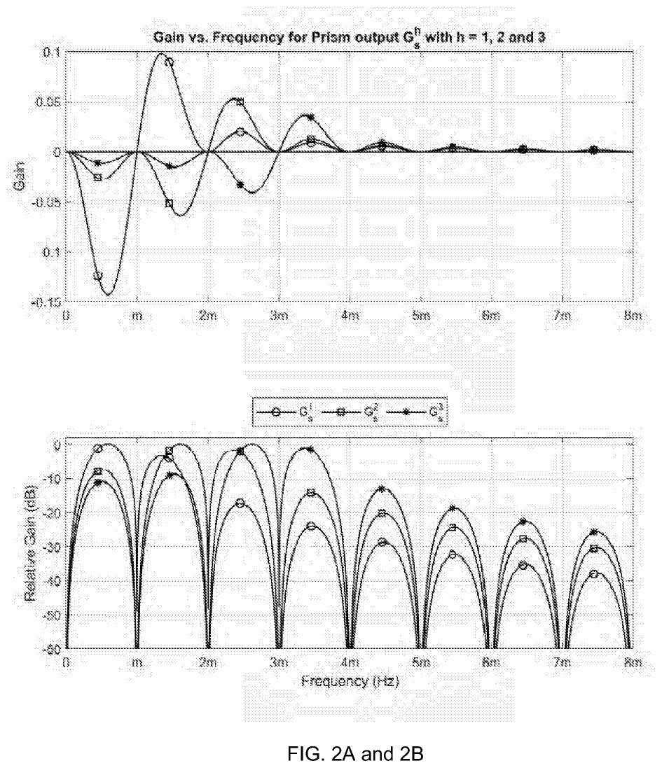

FIG. 2 is an exemplary graph showing gains of Prism output Gₛ^{h} for selected values of h.

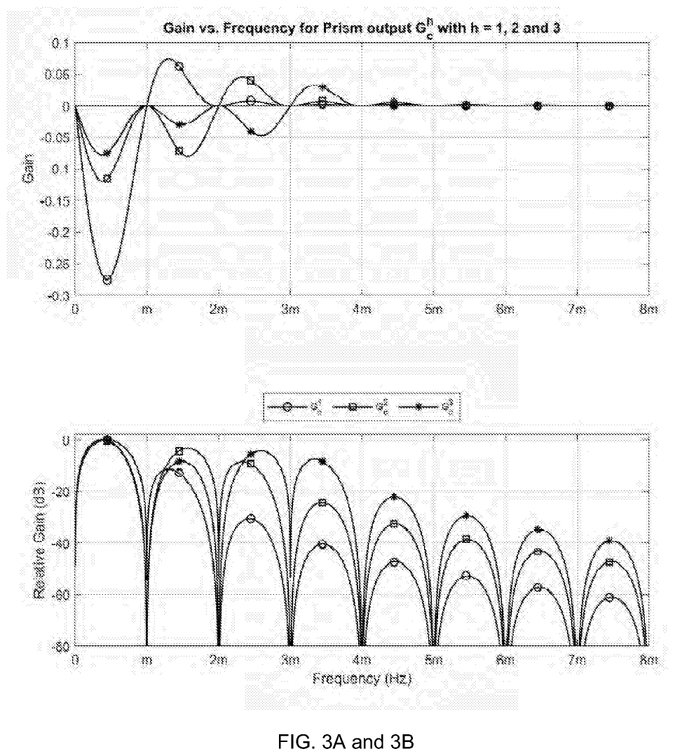

FIG. 3 is an exemplary graph showing gains of Prism output G_{c}^{h} for selected values of h.

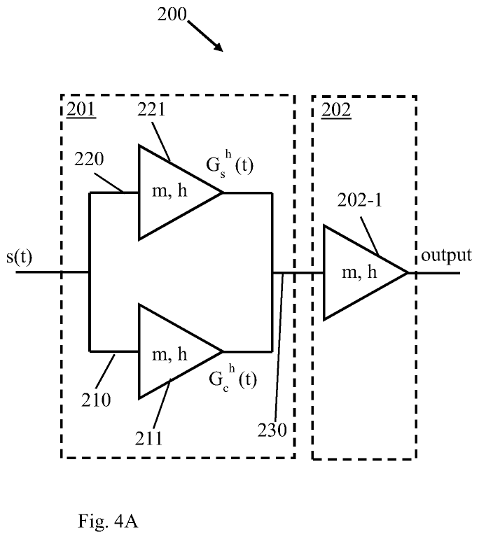

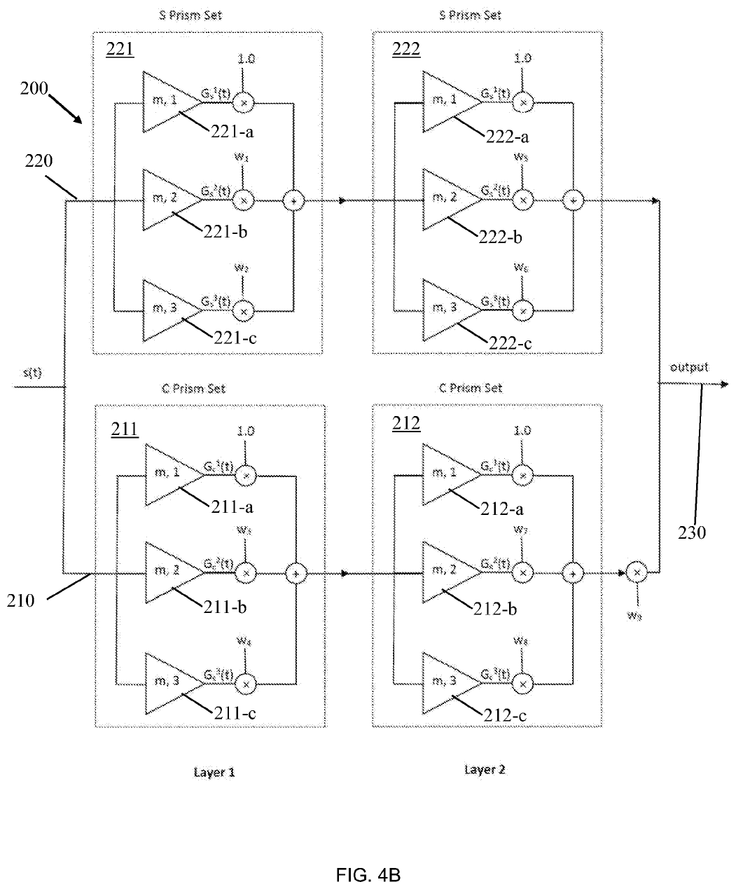

FIG. 4A illustrates an exemplary filter system according to an aspect of the present disclosure;

FIG. 4B is a further example of a filter system, in which the outputs of S and C Prism types are linearly combined to form the filter output.

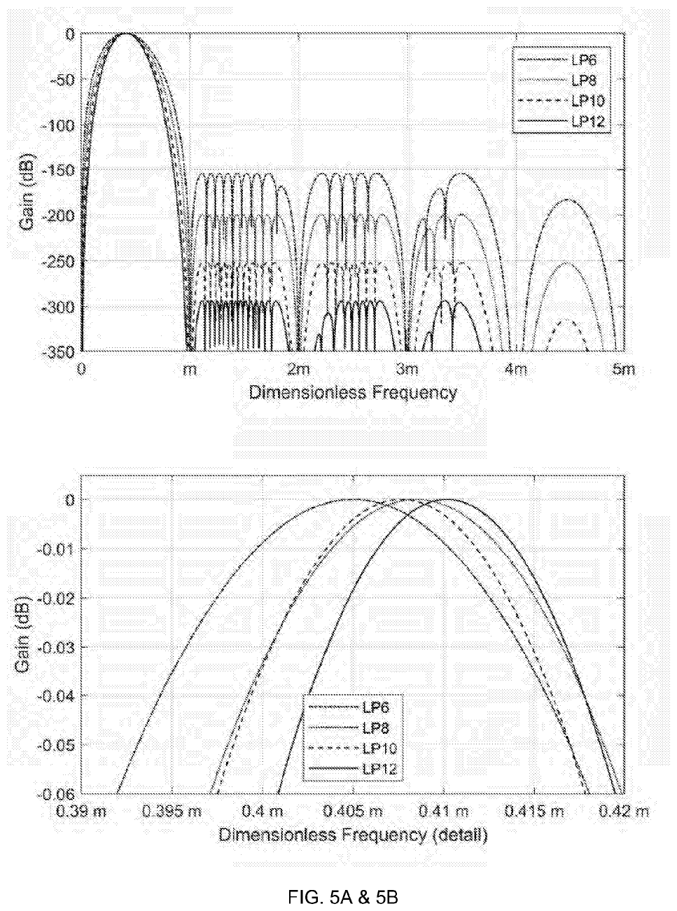

FIG. 5A is an exemplary graph showing the frequency response of three Prism-based filters comprising 8, 10, and 12 layers respectively.

FIG. 5B is an exemplary graph showing a close-up view of FIG. 5A.

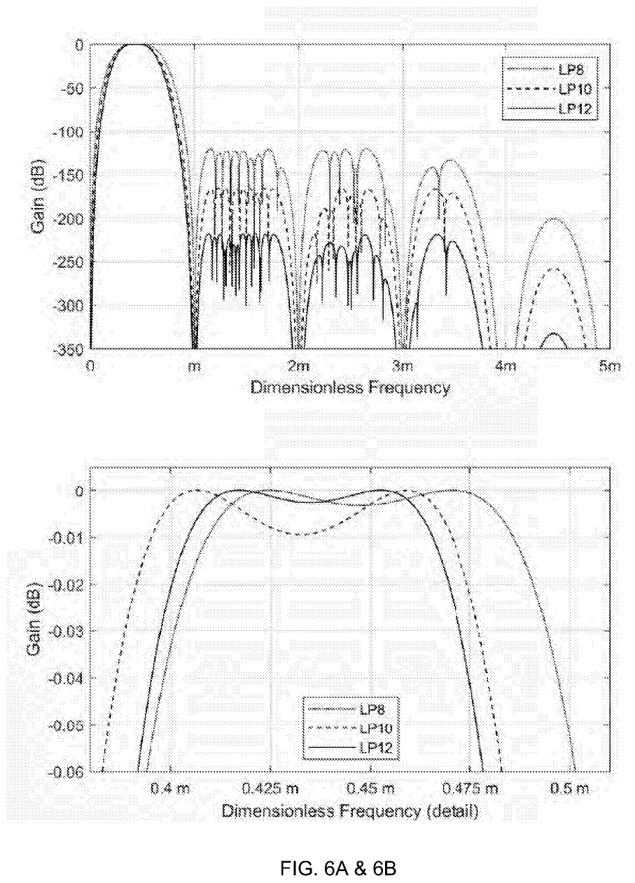

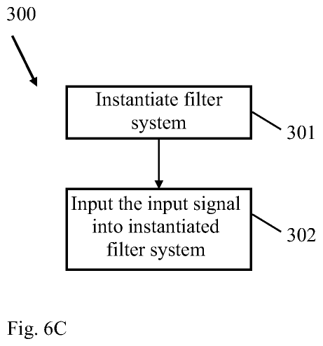

FIG. 6A is another exemplary graph showing the frequency response of a second set of three Prism-based filters comprising 8, 10, and 12 layers respectively.

FIG. 6B is an exemplary graph showing a close-up view of FIG. 6A.

FIG. 6C illustrates an example method of filtering an input signal.

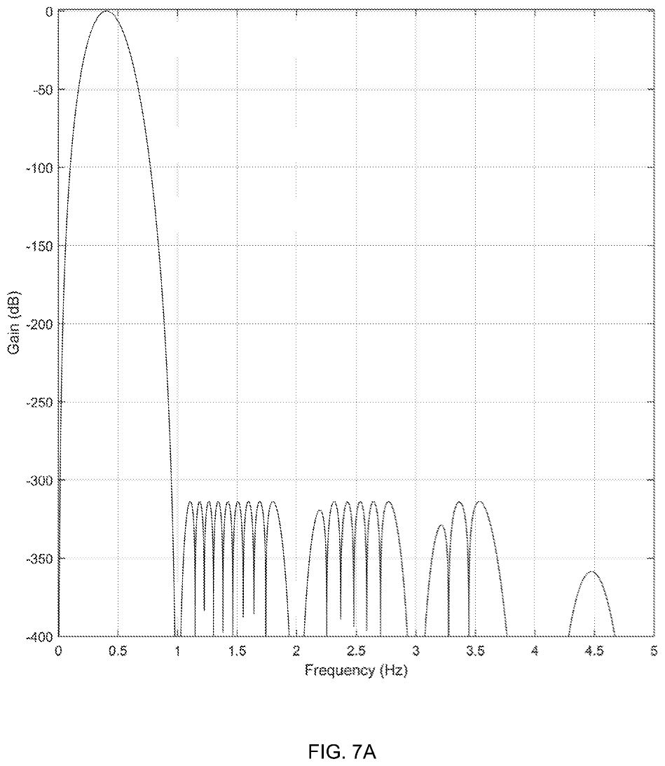

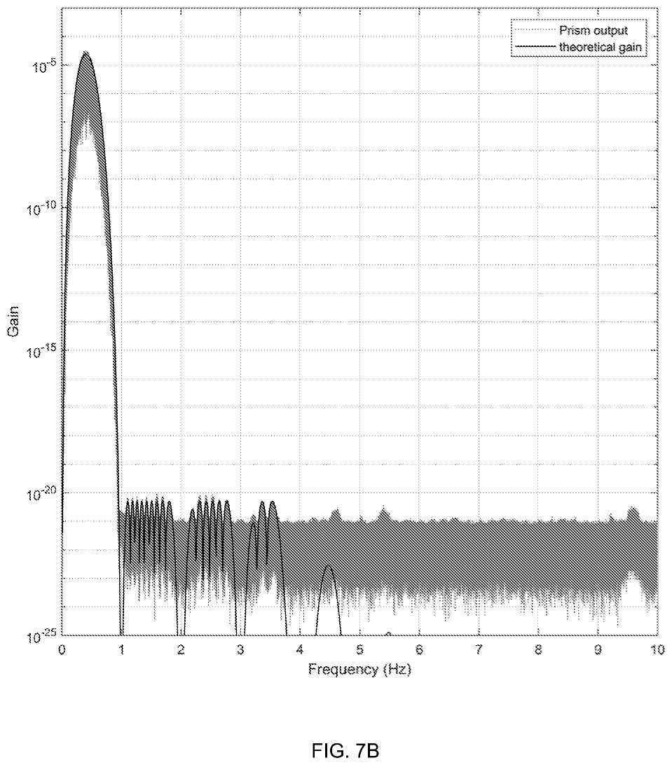

FIG. 7A is an exemplary graph showing a frequency response of a low pass filter formed from twelve Prism layers.

FIG. 7B is an exemplary graph showing the theoretical and numerical performance of a twelve layer low pass filter.

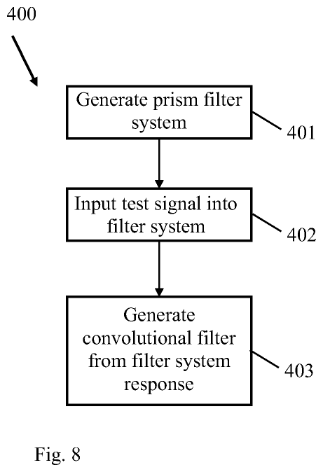

FIG. 8 illustrates an example method of designing a convolutional filter using a Prism filter system.

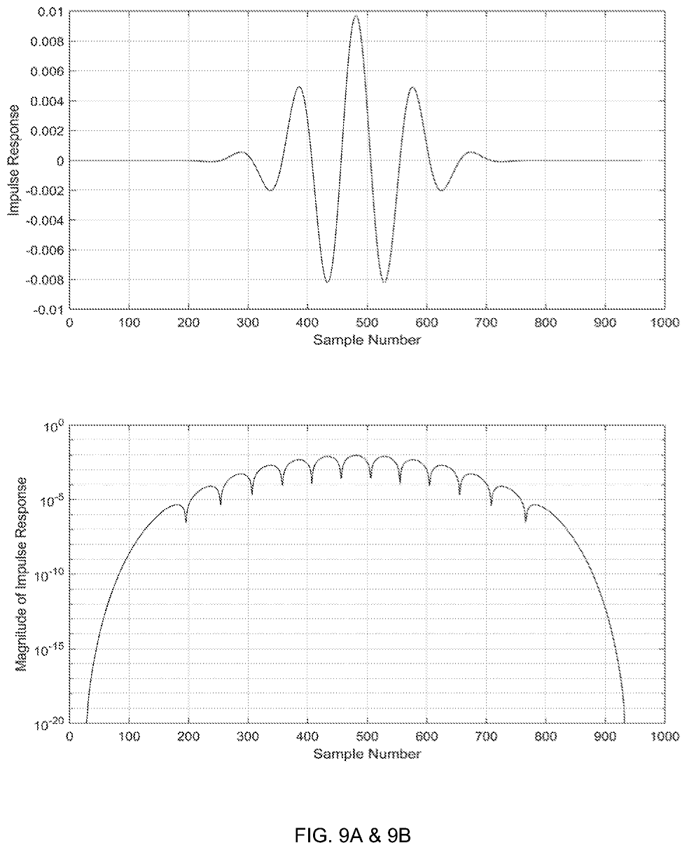

FIG. 9A is an exemplary graph showing the impulse response of a twelve layer low pass filter.

FIG. 9B is an exemplary graph showing the magnitude of the impulse response of FIG. 9A, on a logarithmic scale.

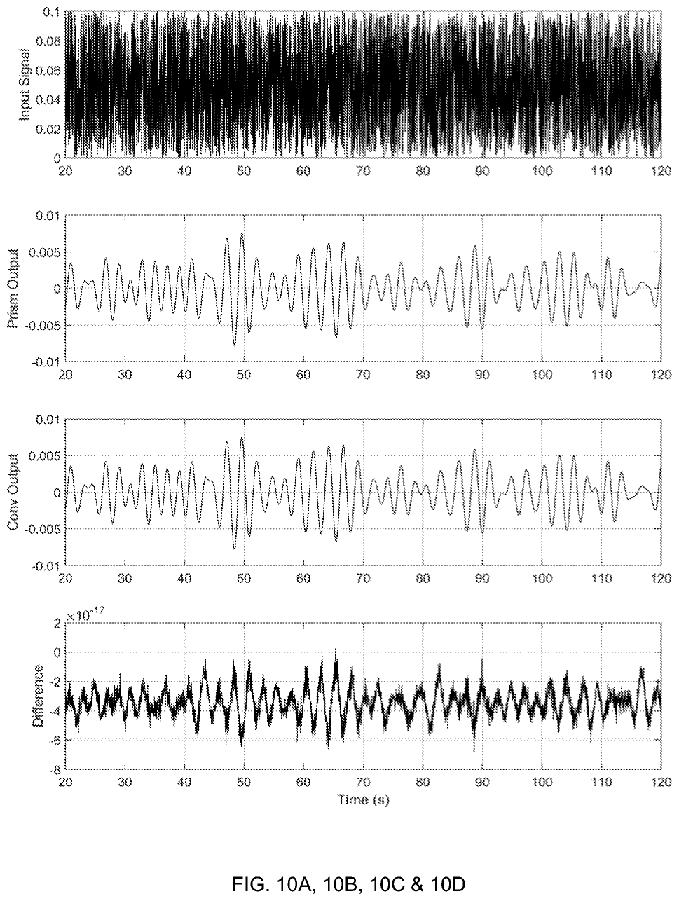

FIG. 10A is an exemplary graph showing a random noise time series.

FIG. 10B is an exemplary graph showing the output generated by passing the time series from FIG. 10A through a twelve layer low pass filter.

FIG. 10C is an exemplary graph showing the output from passing the time series from FIG. 10A through a convolutional filter equivalent to the twelve layer Prism filter used in FIG. 10B.

FIG. 10D is an exemplary graph showing the difference between the signals of FIGS. 10B and 10C.

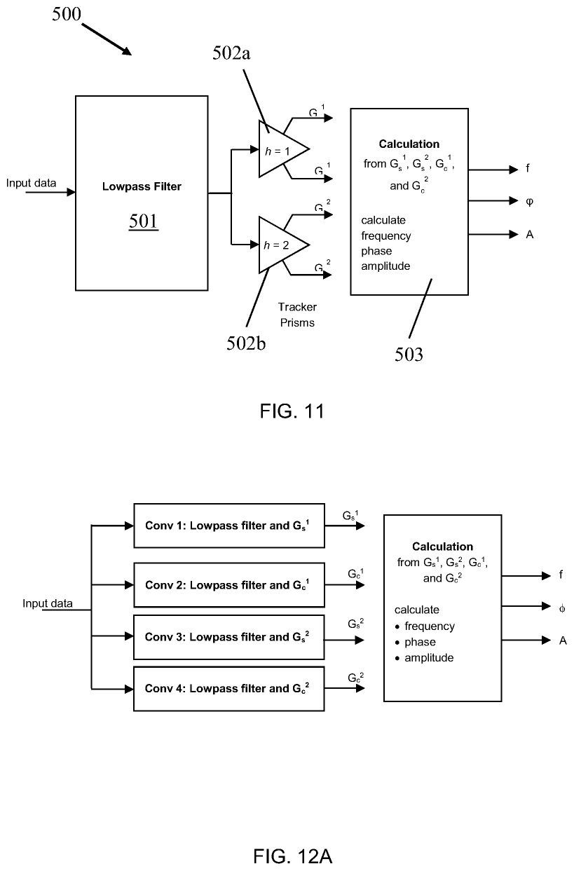

FIG. 11 is an exemplary graph showing a signal processing scheme comprising a low pass filter, two Prisms filtering the output of the low pass filter, and a calculation based on the output of the two Prisms, resulting in estimates of frequency, phase and amplitude.

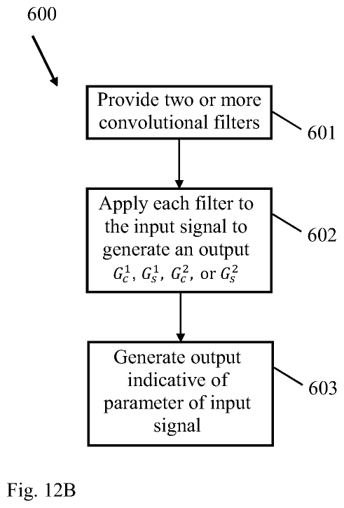

FIG. 12A schematically illustrates a convolutional implementation of a signal processing scheme equivalent to that of FIG. 11, comprising four convolutional filters, and a calculation based on the output of the four convolution filters, resulting in estimates of frequency, phase and amplitude.

FIG. 12B illustrates a method of filtering an input signal using convolutional filters to generate an output indicative of a parameter of the input signal, such as frequency, phase, and/or amplitude.

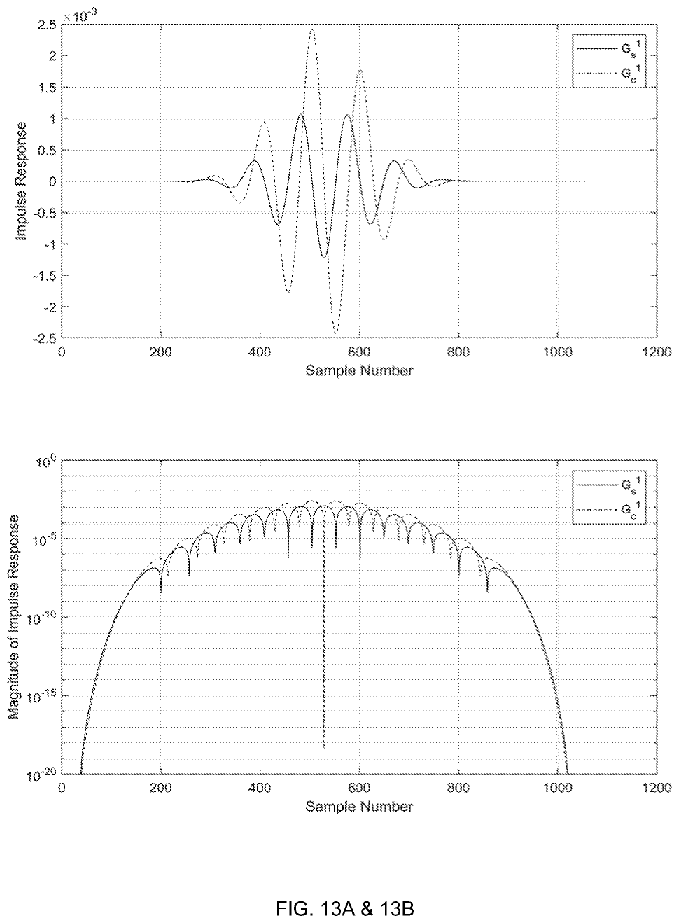

FIG. 13A is an exemplary graph showing two impulse responses from a Prism network consisting of a twelve layer low pass filter followed by a dual output Prism where h=1.

FIG. 13B is an exemplary graph showing the magnitude of the impulse responses of FIG. 13A, on a logarithmic scale.

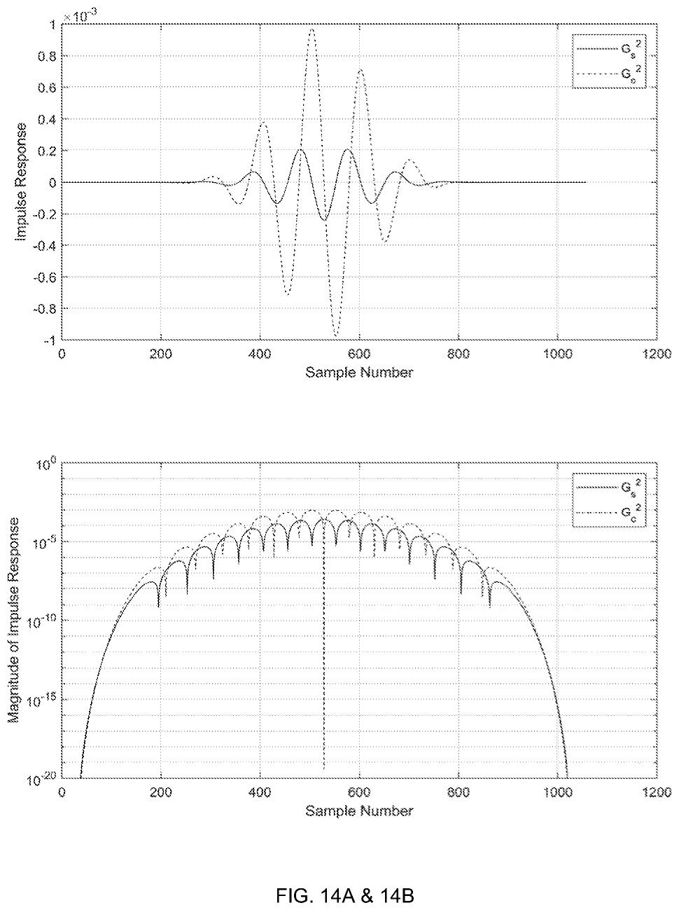

FIG. 14A is an exemplary graph showing two impulse responses from a Prism network consisting of a twelve layer low pass filter followed by a dual output Prism where h=2.

FIG. 14B is an exemplary graph showing the magnitude of the impulse responses of FIG. 14A, on a logarithmic scale.

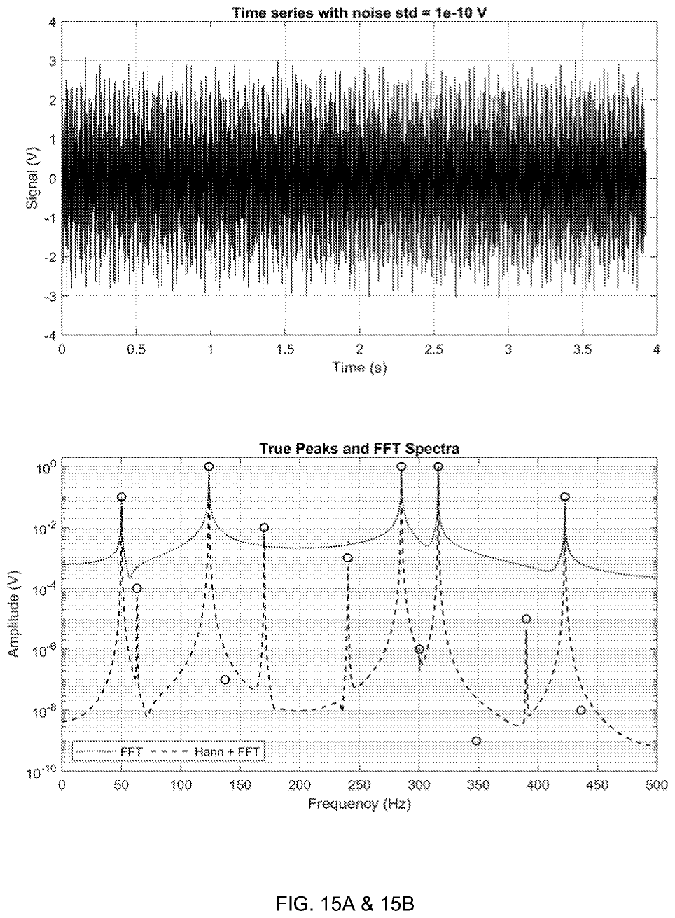

FIG. 15A is an exemplary graph showing a time series of a signal, consisting of 13 sinusoidal components with known frequencies and amplitudes, with a small level of added noise (noise standard deviation is 1e−10 V).

FIG. 15B is an exemplary graph showing two results of Fast Fourier Transform calculations applied to the time series in FIG. 15A, together with the true values of the frequencies and amplitudes within the time series.

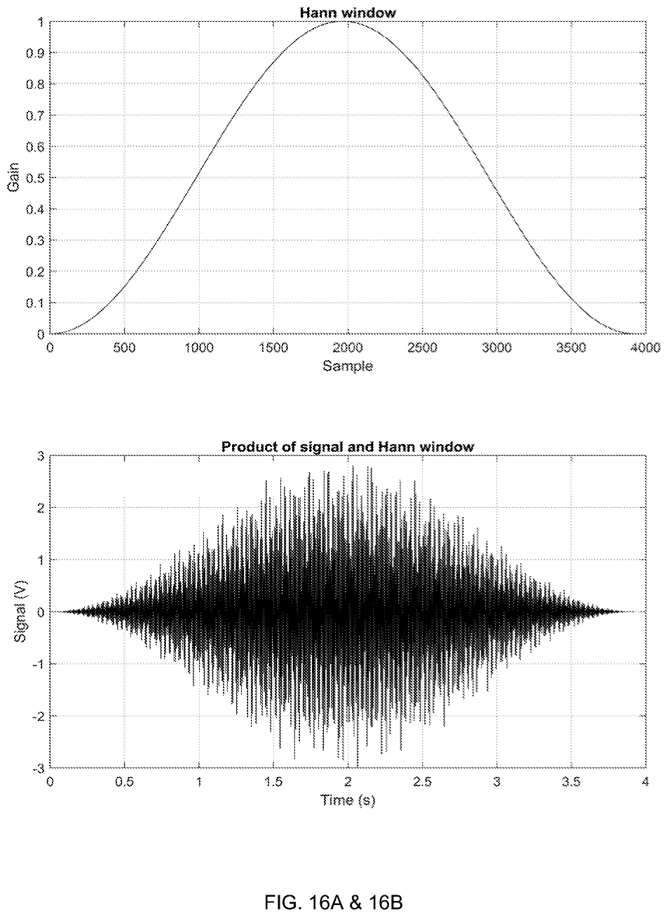

FIG. 16A is an exemplary graph showing a Hann window, with the same sample length as the time series in FIG. 15A.

FIG. 16B is an exemplary graph showing the sample by sample product of the Hann window of FIG. 16A with the time series in FIG. 15A.

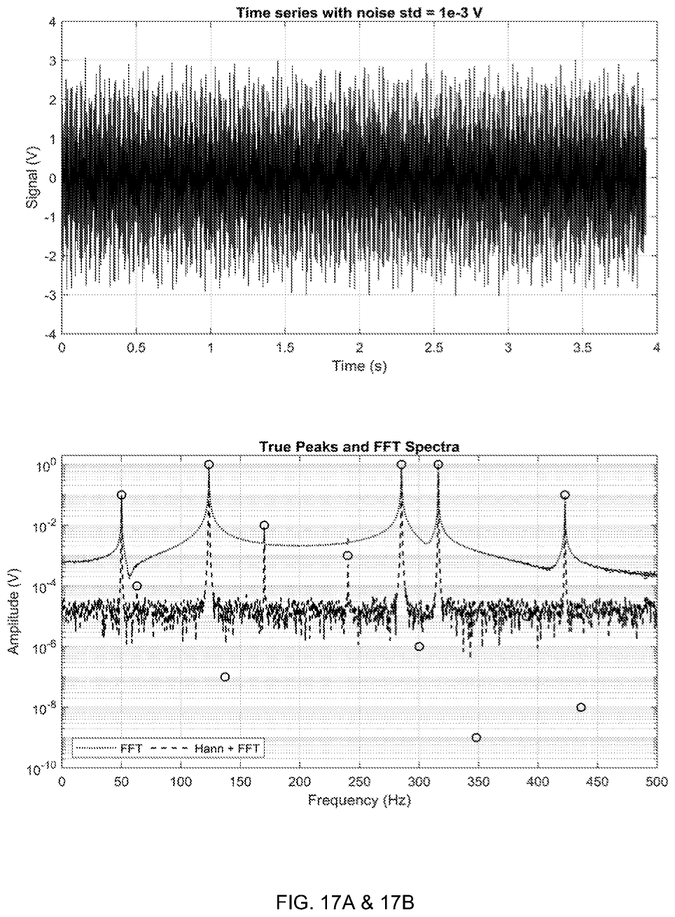

FIG. 17A is an exemplary graph showing another time series of a signal, consisting of the same 13 sinusoidal components with known frequencies and amplitudes from FIG. 15A, with a higher level of added noise (noise standard deviation is 1e−3 V).

FIG. 17B is an exemplary graph showing two results of Fast Fourier Transform calculations applied to the time series in FIG. 17A, together with the true values of the frequencies and amplitudes within the time series.

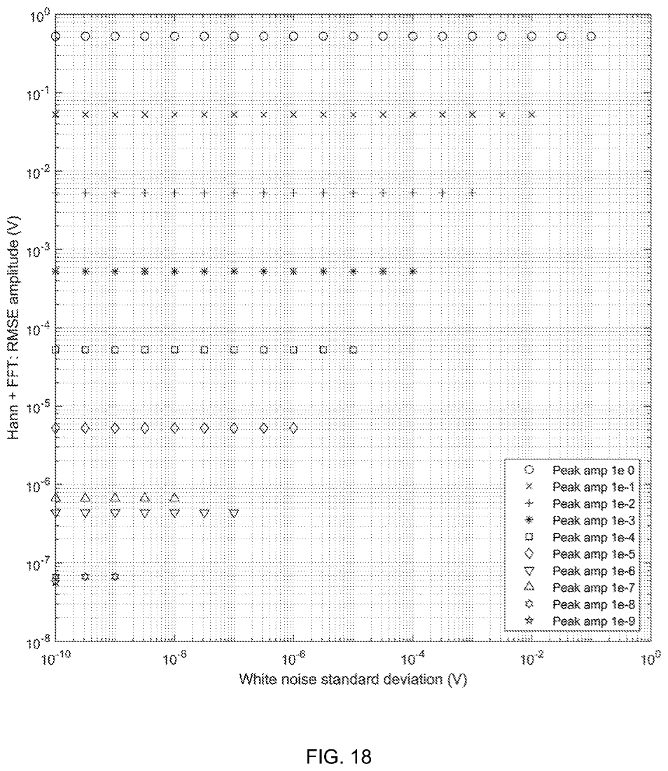

FIG. 18 is an exemplary graph showing the Root Mean Square Error (RMSE) for the amplitude calculated by the Hann+FFT technique for simulated signals as specified in Table 1, as the level of white noise is varied from 1e−10 to 1e−1 V.

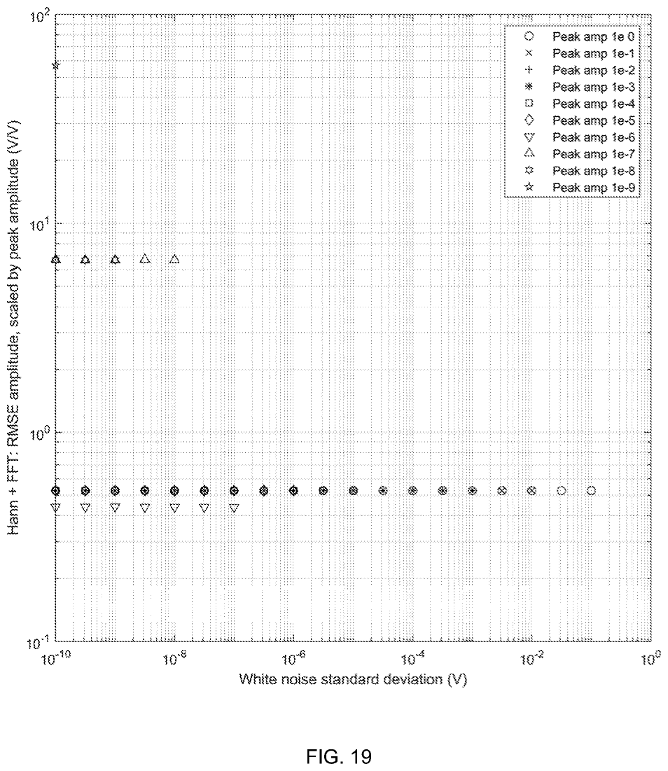

FIG. 19 is an exemplary graph showing the ratio between the Root Mean Square Error (RMSE) of FIG. 18 and peak amplitude.

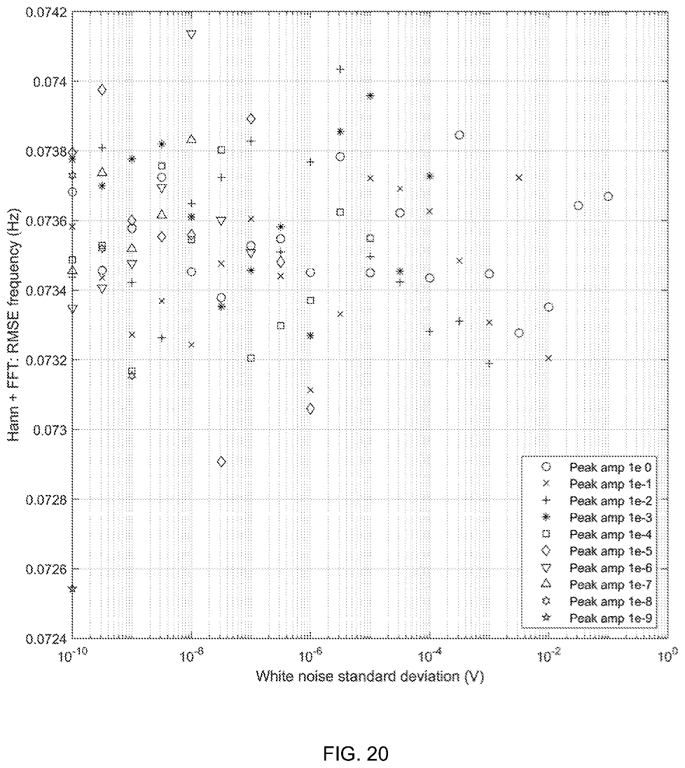

FIG. 20 is an exemplary graph showing the Root Mean Square Error (RMSE) for the frequency calculated by the Hann+FFT technique for simulated signals as specified in Table 1, as the level of white noise is varied from 1e−10 to 1e−1 V.

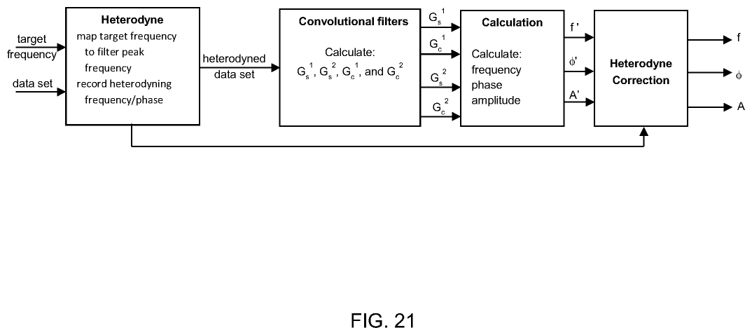

FIG. 21 is a schematic illustration of using heterodyning to perform Prism-based tracking of a signal component that is located outside the passband of the convolutional low pass filters.

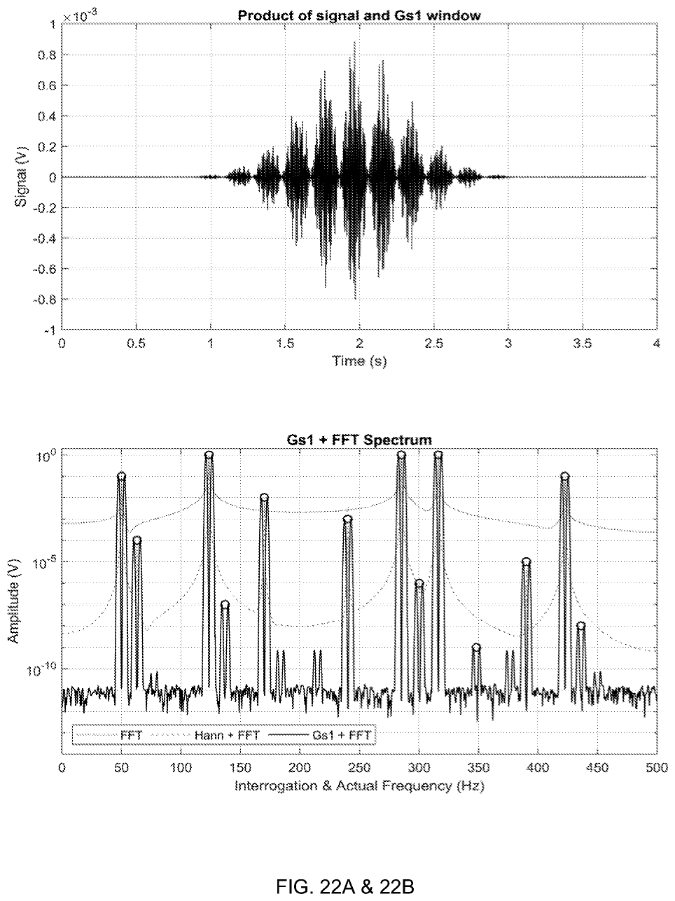

FIGS. 22A and 22B shows results illustrating the application of the scheme of FIG. 21 to the example signal specified in Table 1.

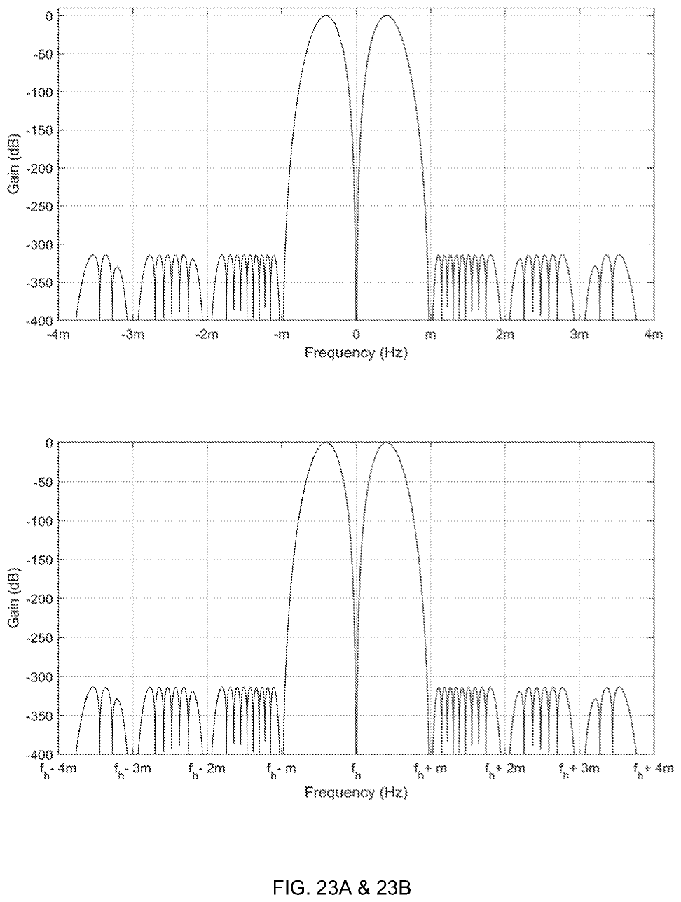

FIGS. 23A and B illustrate how the lowpass filter characteristic of the filter shown in FIG. 7A, when applied using the heterodyning scheme of FIG. 21, results in the double peak characteristic seen in FIG. 22B.

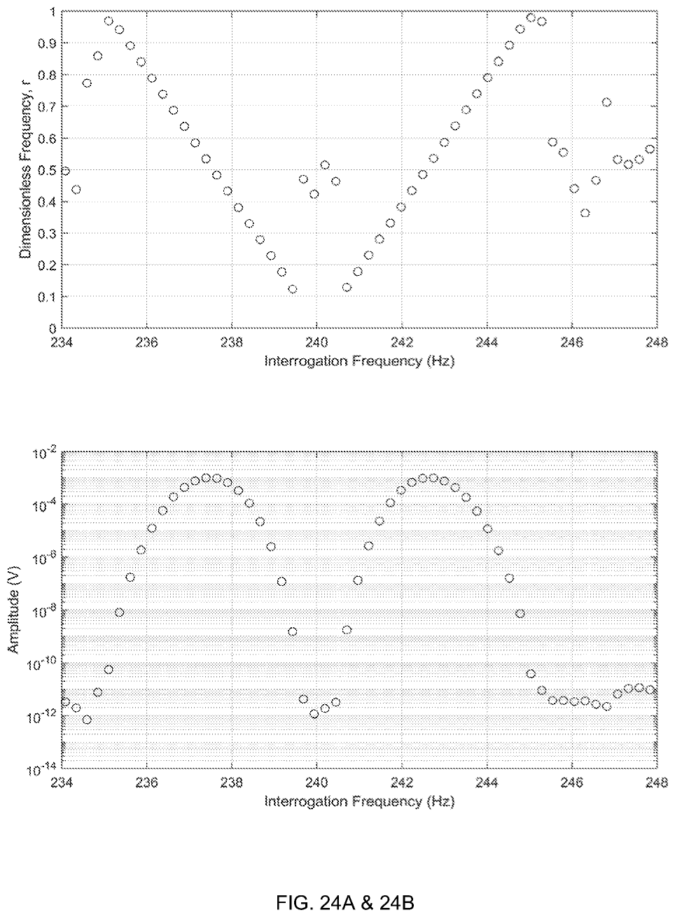

FIGS. 24A and B shows example results generated from application of the four FFT filters.

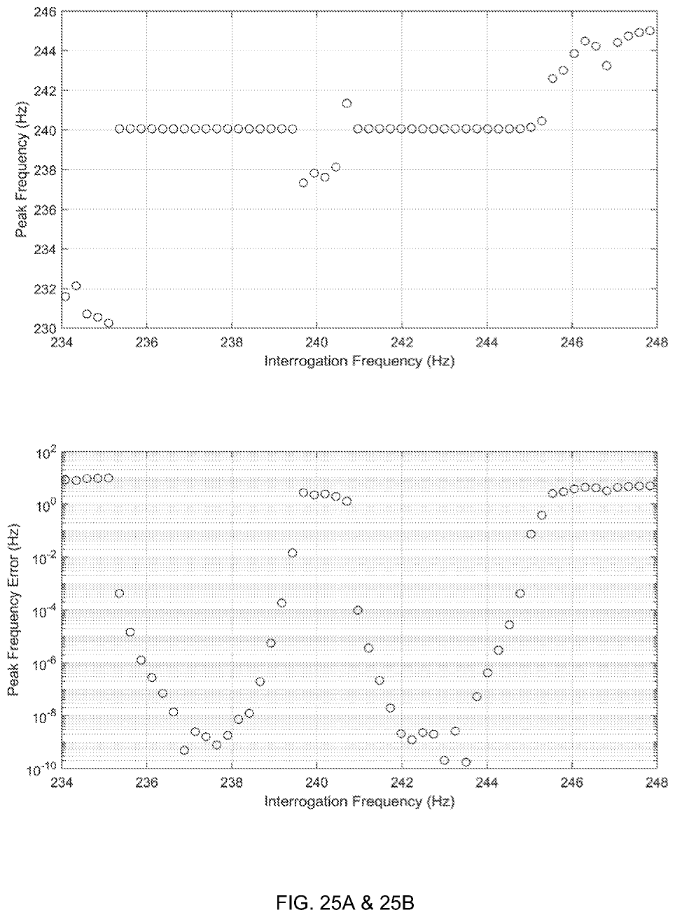

FIGS. 25A and B shows the calculated values of peak frequency and corresponding error for the results in FIG. 24a and B.

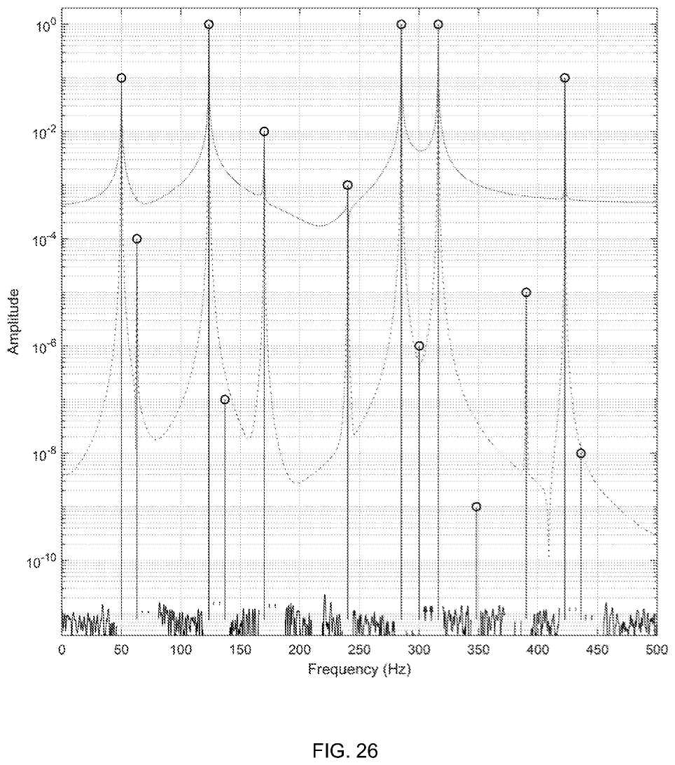

FIG. 26 illustrates the frequency peaks detected by the P4C process, together with the results obtained using conventional FFT and Hann+FFT.

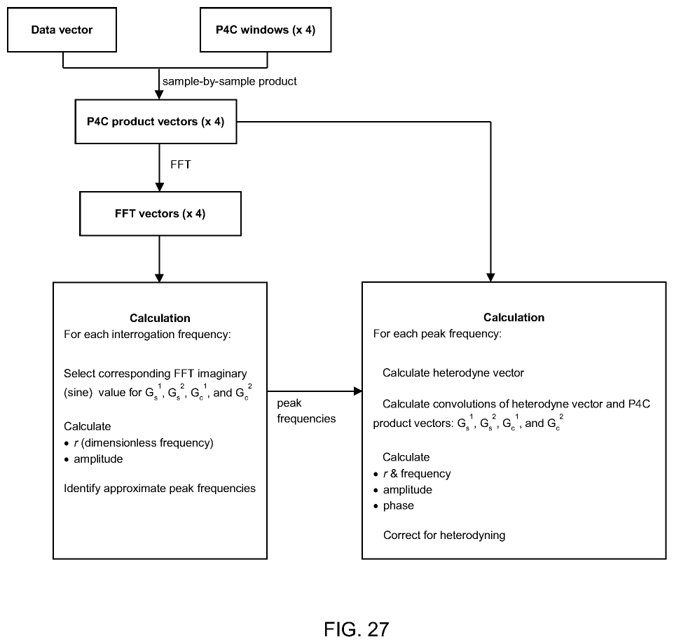

FIG. 27 schematically illustrates an example of the P4C process.

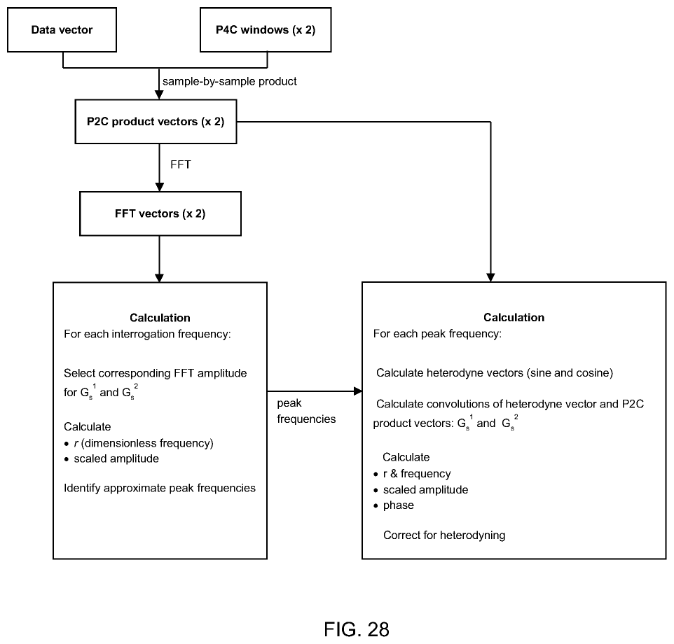

FIG. 28 schematically illustrates an alternative example of the P4C process, termed a P2C process.

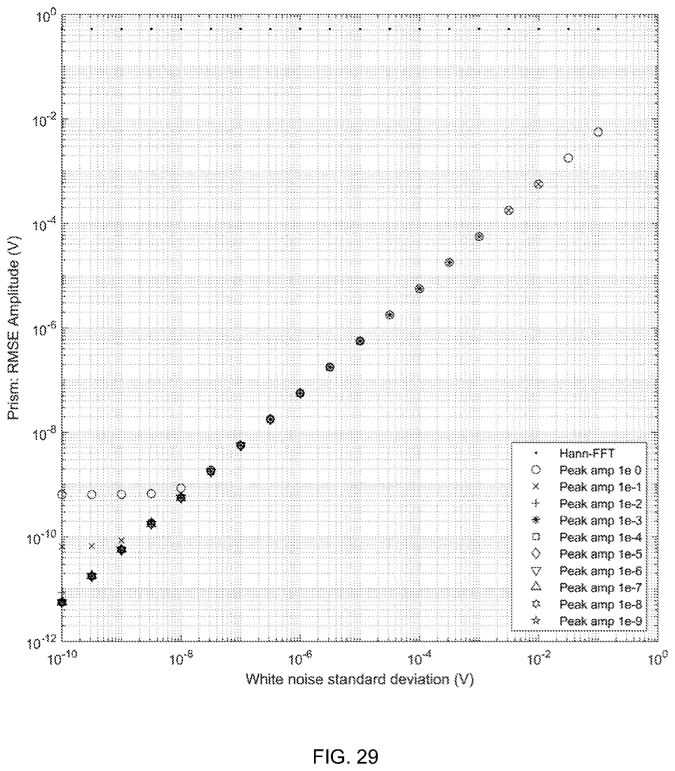

FIG. 29 shows P2C RMSE errors for amplitude.

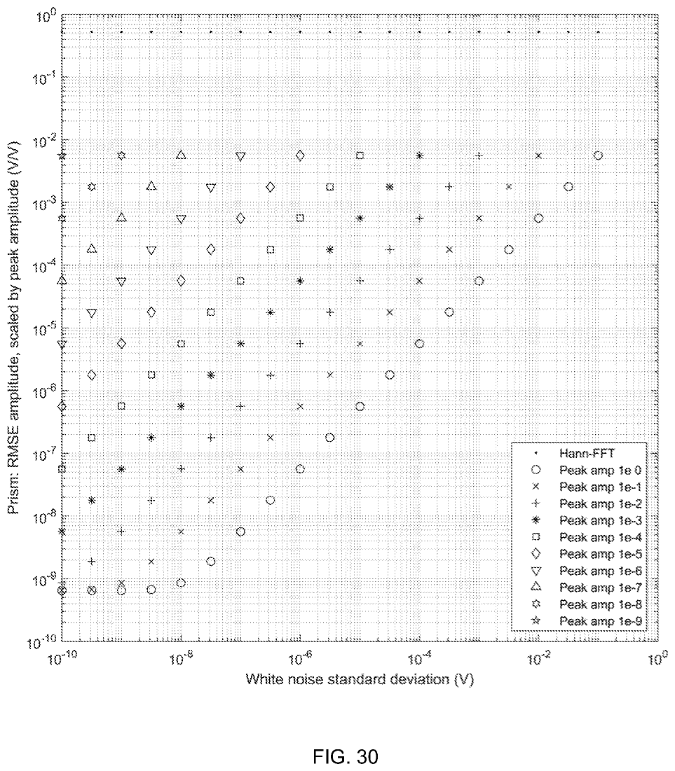

FIG. 30 shows P2C RMSE errors for amplitude, scaled by the amplitude.

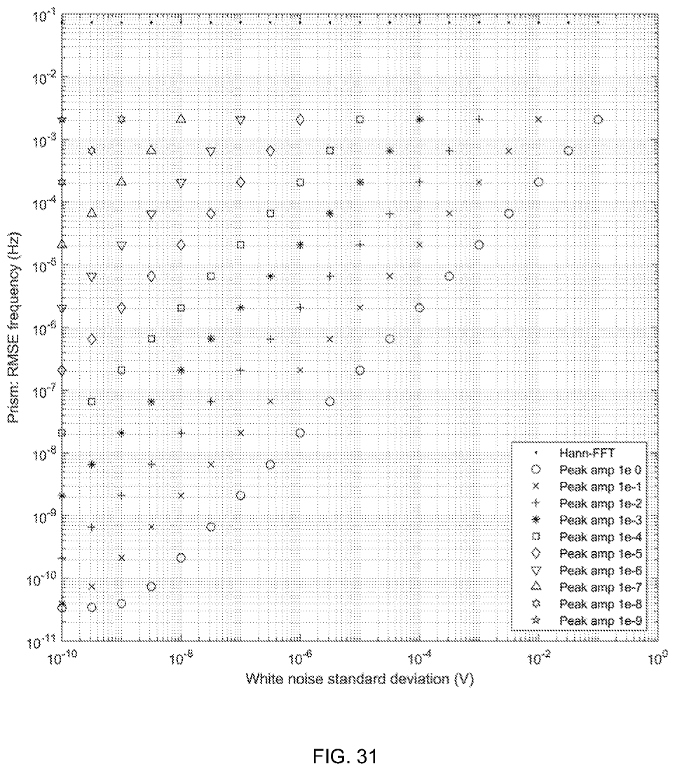

FIG. 31 shows the RMSE frequency error for the P2C technique.

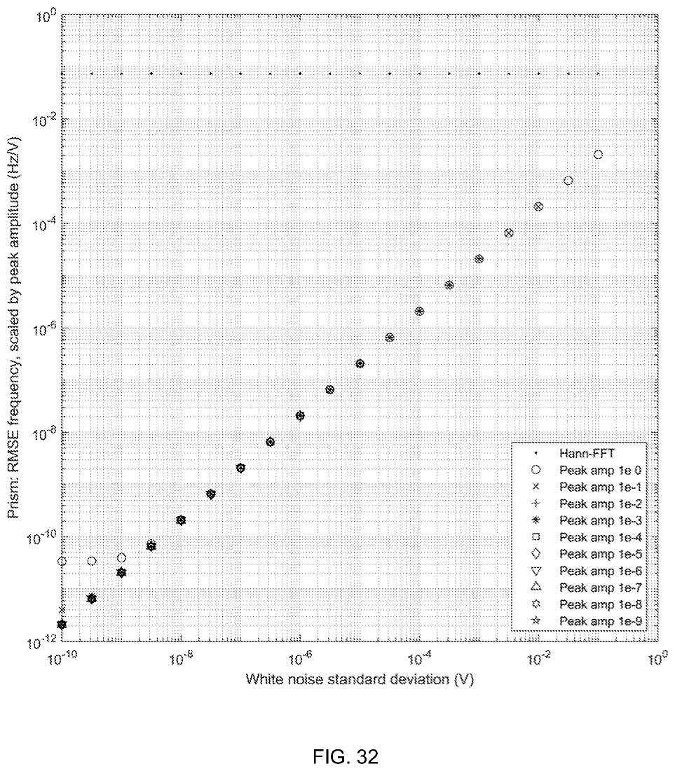

FIG. 32 the RMSE frequency error, scaled by amplitude.

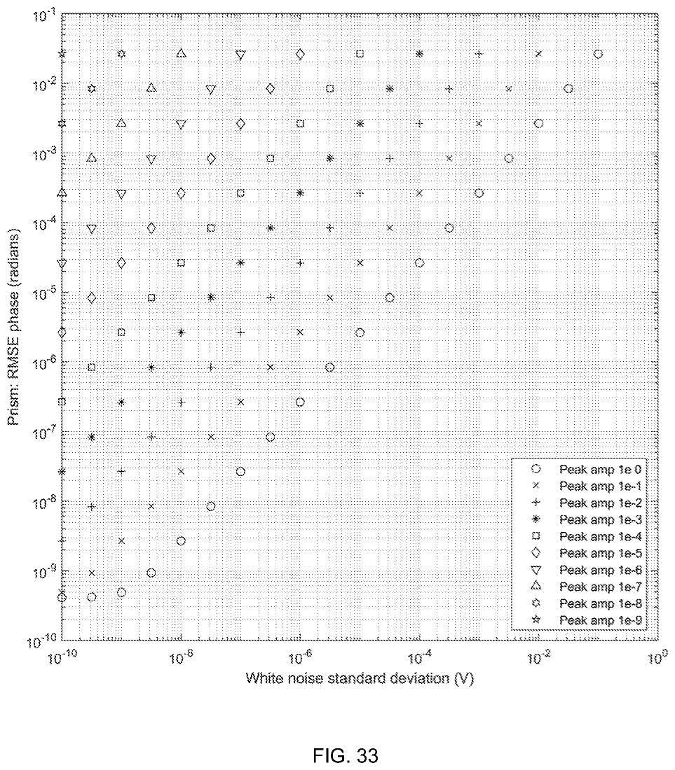

FIG. 33 shows the RMSE phase error.

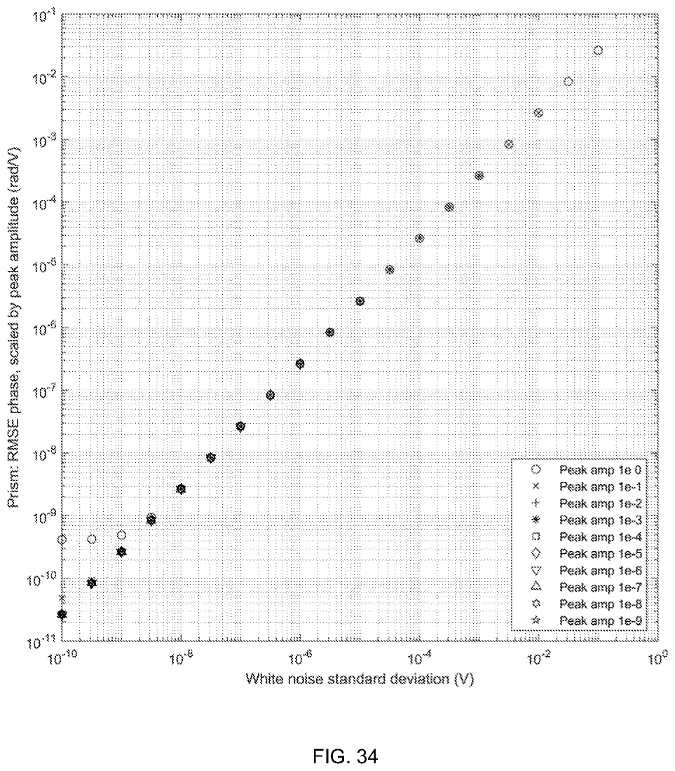

FIG. 34 shows the RMSE phase error, scaled by amplitude.

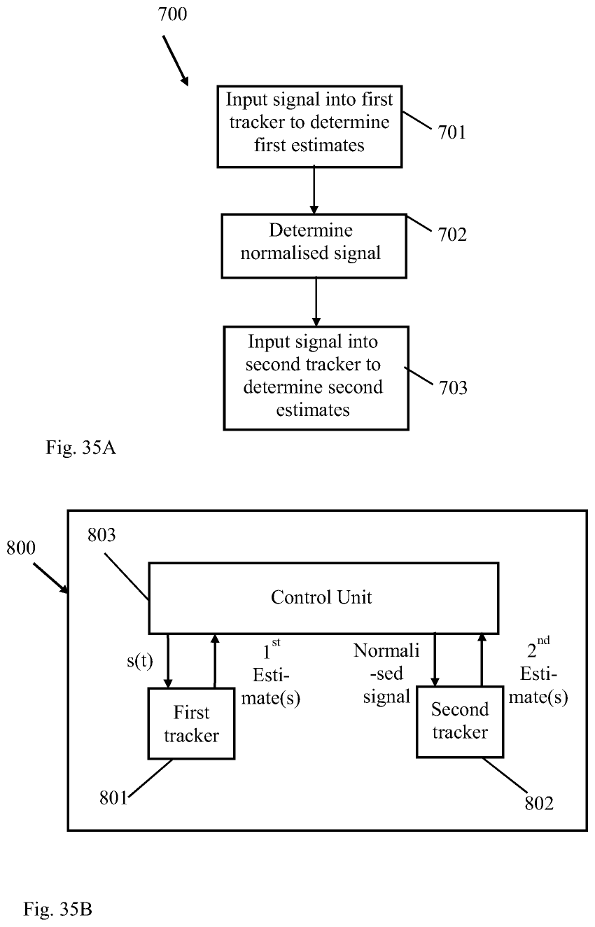

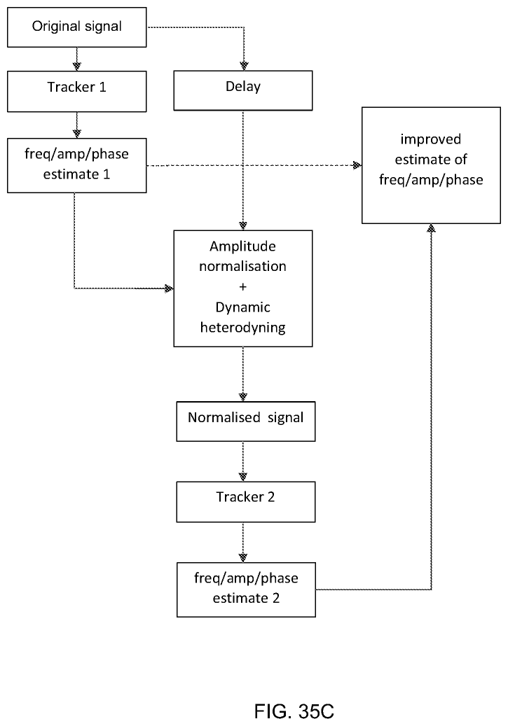

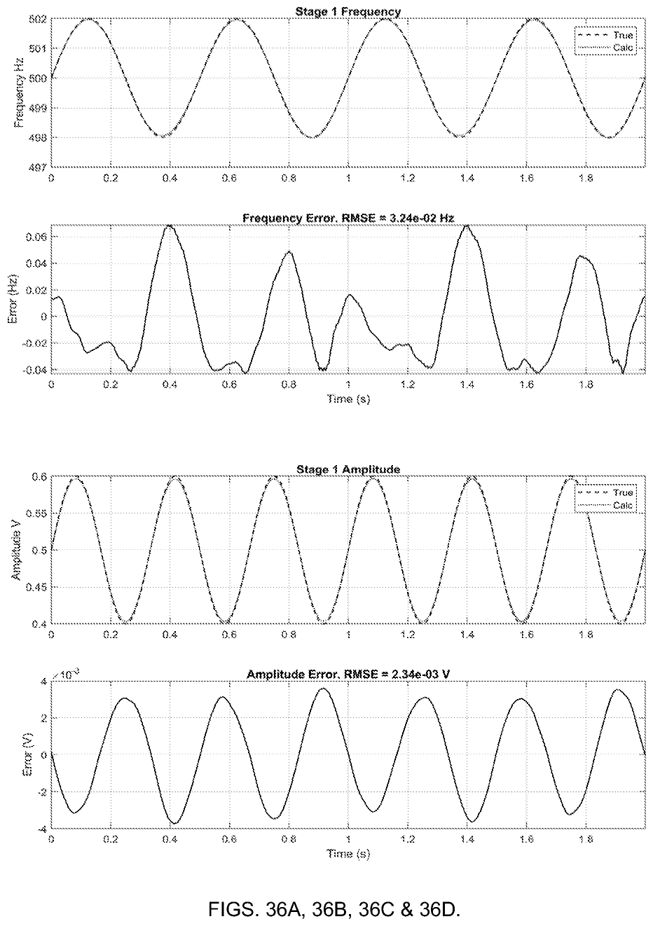

FIG. 35A illustrates a method of estimating characteristics of an input signal.

FIG. 35B schematically illustrates a signal characterization device for performing the method of FIG. 35A.

FIG. 35C schematically illustrates an example implementation of the method of FIG. 35A.

FIGS. 36A-D show estimates of characteristics generated by applying the first tracker of the method of FIG. 35A alone.

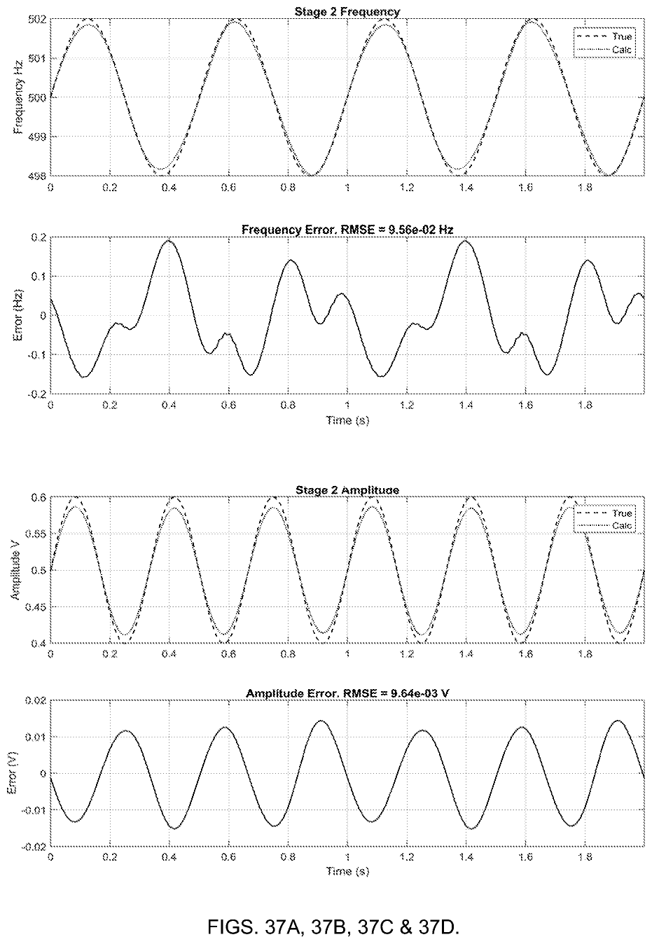

FIGS. 37A-D show estimates of characteristics generated by the second tracker of the method of FIG. 35A alone.

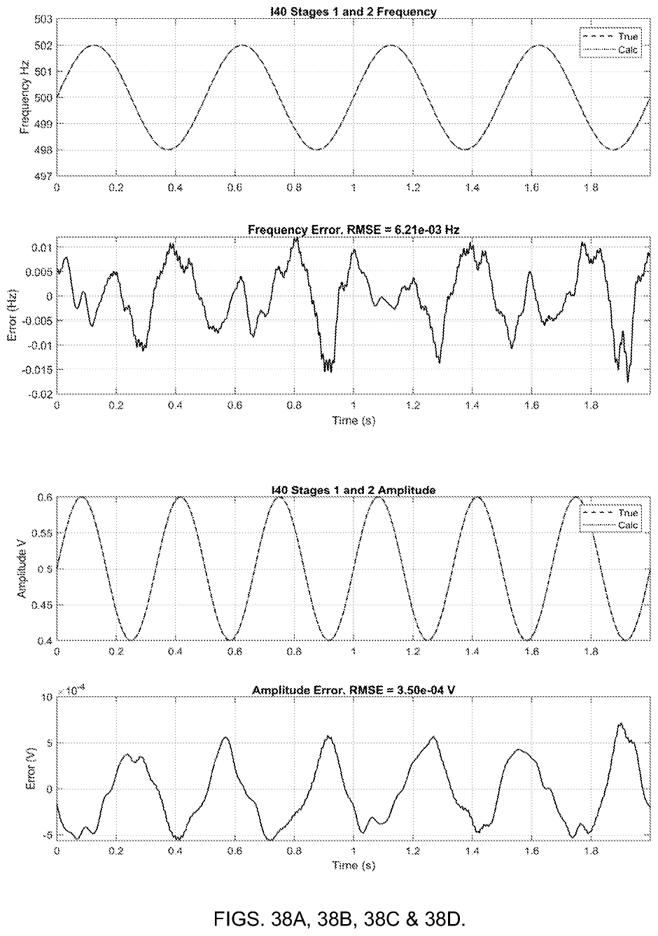

FIGS. 38A-D show estimates of characteristics generated using the full method of FIG. 35A.

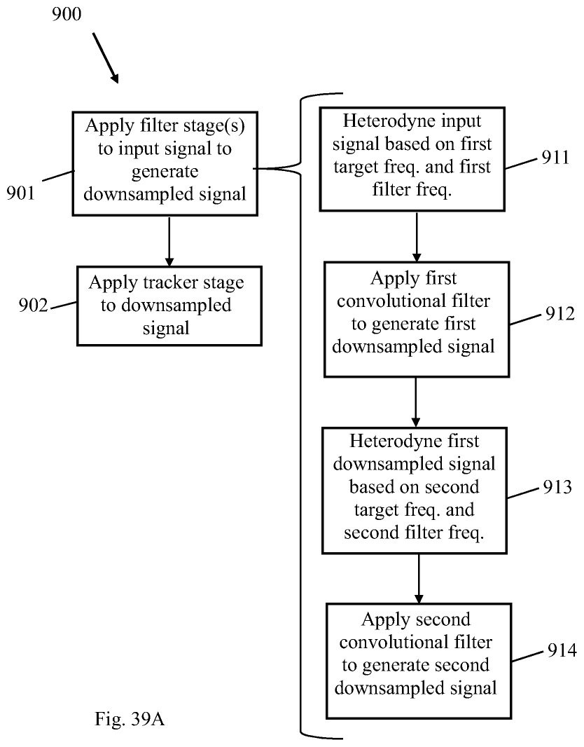

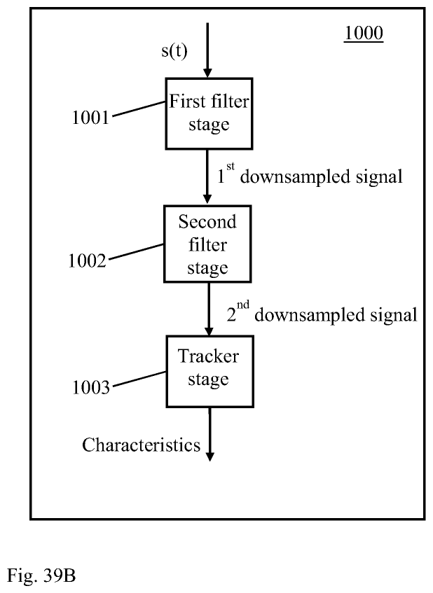

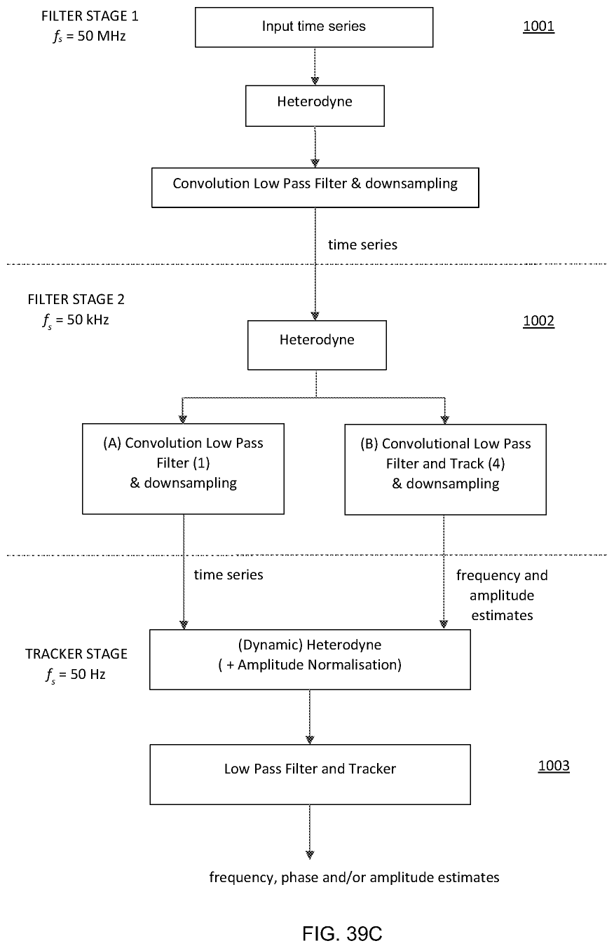

FIG. 39A shows a method of filtering an input signal.

FIG. 39B schematically illustrates a filter system for performing the method of FIG. 39A.

FIG. 39C schematically illustrates an example of the method of FIG. 39A.

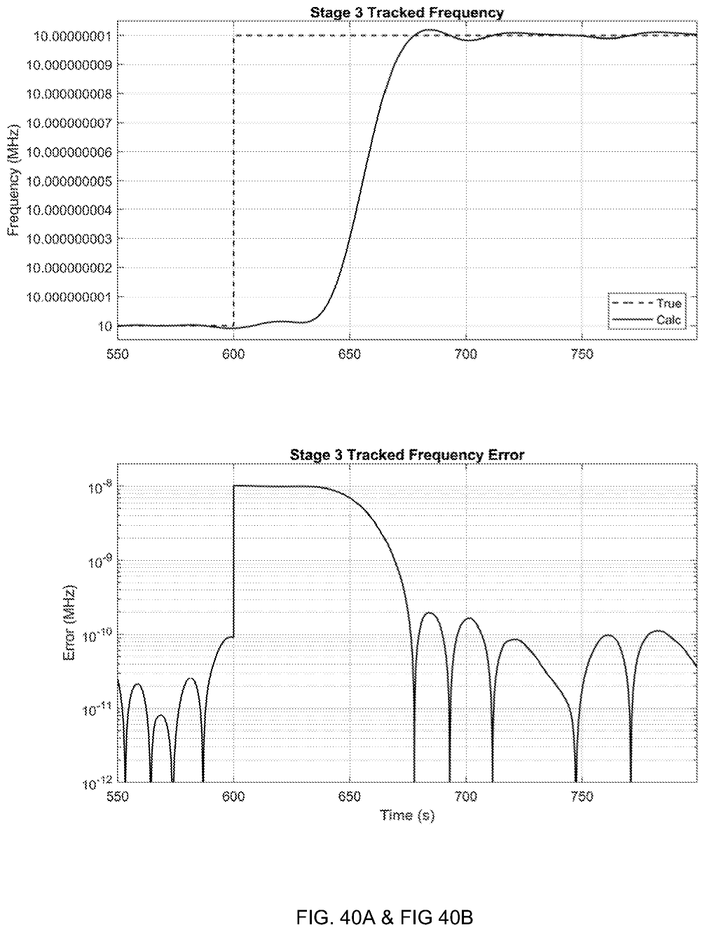

FIGS. 40A-B show results of tracking frequency, and corresponding error, using the implementation of FIG. 39C for a 0.01 Hz step change in frequency.

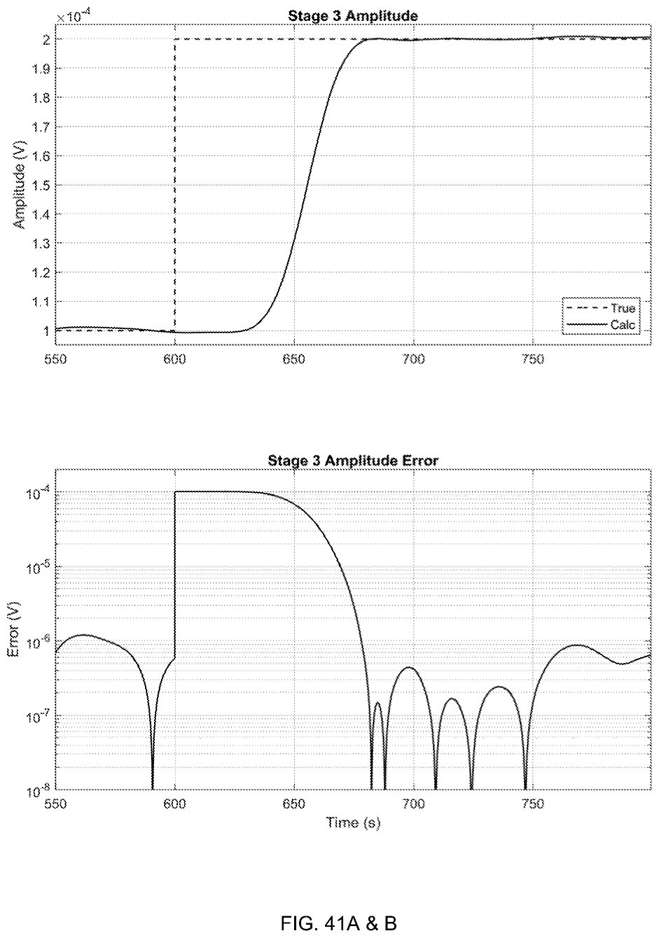

FIG. 41A-B show results of tracking the amplitude, and corresponding error, using the implementation of FIG. 39C for a step change in amplitude.

An example of the Prism constitutes a low pass FIR filter (or a coupled pair of filters) that can use a recursive sliding window technique, so that the computation burden is independent of the window length, with linear phase response and good numerical stability. The properties of the Prism have previously been disclosed in [A, 1] which are incorporated herein by reference in their entirety. Two or more Prisms may be combined into a chain or network to meet more sophisticated signal processing requirements, such as the provision of low pass or band pass filtering to a desired specification. Any single output Prism can be extended to provide a second output, where the two outputs are generally orthogonal (e.g., having a phase difference of π/2 radians). A variety of sinusoid trackers can be constructed to calculate estimates of the frequency, phase and/or amplitude of the monitored signal, each using a Prism network and a detection calculation.

Examples of the Prism filters may be incorporated into systems, utilizing mechanical or electronic sensors and/or microprocessors or other devices capable of computation, or methods using the disclosed techniques. The methods and systems utilizing an example of the Prism perform double integrals of the form:

$$Equation ( 1 )$$

$${I}_{[ S \vert C ] [ S \vert C ]}^{h} = {m}^{2} {\int }_{- \frac{1}{m}}^{0} [ sin \vert cos ] ( 2 π hmt + q ) ( {\int }_{t - \frac{1}{m}}^{t} [ sin \vert cos ] ( 2 π hmt + q ) \cdot s ( t ) dt ) dt ,$$

Here the notation [s|c] is used to indicate the selection of one alternative between s (for sine) and c (for cosine). h is the harmonic number, normally a small positive integer, usually 1, 2, or 3. m may be the characteristic frequency of the Prism.

Although the mathematical analysis described in this disclosure may be stated in terms of continuous notation (for example using integration rather than summation), it will be understood by those familiar with the art that a practical implementation may be based upon digitally sampled signals, and that mathematical results in the continuous domain can, with due care, be mapped onto the discrete time domain. For example, Romberg Integration, (described in J. Dutka, “Richardson Extrapolation and Romberg Integration”, Historia Mathematica, Vol. 11, (1984) pp 3-21), is one technique that may be applied to obtain accurate results from discrete samples of data, which may provide a good approximation to the theoretical value of the continuous integral equivalent.

With regard to the discrete-time implementation of an example of the Prism, given a sampling rate fs, the choice of m is restricted to ensure that f/rm is an integer: this quantity gives the whole number of samples in each of the two data windows used for numerical integration. Where Romberg Integration is used, slightly greater restrictions are placed on the selected value of m, for example that fs/m must be a positive multiple of some power of two (for example 4n, where n is any positive integer).

The integral limits may be selected so that ϕ, the phase of s(t) at t=0, is also the phase of the most recent sample. In other words, calculating ϕ can give the phase at the end of the data window, rather than (for example) the phase at the mid-point of the double integral. Note that the double integral extends in time from −2/m to 0: its duration is 2/m. Accordingly, viewed as an FIR filter, this example can be considered as having an order (i.e., the length of the data window in samples) of 2 fs/m.

The harmonic number can be considered in the following terms. Over each integral window, the modulation function constitutes a sinusoid (either sine or cosine) that is multiplied by the input signal: for the inner integral, the input constitutes the original signal s(t); for the outer integral the input constitutes the value supplied as an output from the inner integral. When the harmonic number is one, one complete cycle of the modulation function can stretch over the window of data associated with each integral: thus the frequency of the modulation function is m. When the harmonic number is two, two cycles exactly cover each data window, and thus the frequency of the modulation function is 2m, and so on.

As developed and explained in previous disclosures, the following useful results may be derived:

$${G}_{{s}_{k}} = {I}_{{s}_{k} {s}_{k}} + {I}_{{c}_{k} {c}_{k}} = A sin {c}^{2} ( r ) \frac{{r}^{2}}{{r}^{2} - {h}^{2}} sin ( ϕ - 2 π r ) \qquad Equation ( 2 )$$

$$and$$

$${G}_{{c}_{k}} = {I}_{{c}_{k} {s}_{k}} - {I}_{{s}_{k} {c}_{k}} = A sin {c}^{2} ( r ) \frac{hr}{{r}^{2} - {h}^{2}} cos ( ϕ - 2 π r ) \qquad Equation ( 3 )$$

Here r is the frequency ratio of the input sinusoid, defined as:

$$r = f / m , \qquad Equation ( 4 )$$

so that r=0 when f=0 Hz and r=1 when f=m Hz. sinc(x) is the normalised sinc function defined as follows:

$$sin c ( x ) = \frac{sin ( π x )}{π x} \qquad Equation ( 5 )$$

Gₛₕ in equation 2 is also referred to as Gₛ^{h} in this disclosure; similarly, G_{ch} in equation 3 is also referred to as G_{c}^{h} in this disclosure.

The simple analytic expressions for the double integral groups given in Equations 2 and 3 are a key advantage of filters based on the Prism technique. The Prism may be defined as a signal processing object that receives a time series signal as an input, and which generates, via numerical integration, one or more time dependent outputs. These time-dependent outputs may correspond to the sample-by-sample values of one or both of Gₛ_{ₖ} and G_{c}_{ₕ} as defined in equations 2 and 3. As discussed above, the Prism may have two primary configuration parameters, m and h. As a signal processing object, the Prism may be incorporated into systems and/or methods of detecting sinusoidal wave components, for example, in static data sets or when monitoring data that is updated over time.

Prism Signal Processing, described above and in “The Prism: Efficient Signal Processing for the Internet of Things,” IEEE Industrial Electronics Magazine, pp 2-10, December 2017. DOI: 10.1109/MIE.2017.2760108 by MP Henry, F Leach, M Davy, O Bushuev, M S Tombs, FB Zhou, and S Karout (ref. [5]), which is incorporated herein by reference in its entirety, constitutes a new FIR technique particularly suited to the requirements of autonomous computing and for intelligent, adaptive components in Cyber-Physical Systems and the Internet of Things (IoT).

### Prism Filter Systems

The present disclosure relates to Prism filter systems comprising a network of filter systems, and to methods of designing and using convolutional filters that are based on Prism filter systems. The basic building block of these filter systems is a Prism filter. An example of a Prism filter 100 is shown in FIG. 1.

Each Prism filter 100 is configured to evaluate combinations of double integrals of the form:

$${I}_{[ S \vert C ] [ S \vert C ]}^{h} = {m}^{2} {\int }_{- \frac{1}{m}}^{0} [ sin \vert cos ] ( 2 π hmt + q ) ( {{\int }_{t - \frac{1}{m}}^{t}}^{} [ sin \vert cos ] ( 2 π hmt + q ) \cdot s ( t ) dt ) dt ,$$

where s(t) is an input to the respective Prism filter, m is a characteristic frequency of the respective Prism filter, [sin|cos] represents a sine or a cosine operation, q is an optional, arbitrary phase offset variable, and h is a harmonic number of the respective Prism filter of the network of Prism filters. As noted above, evaluating the double integrals may comprise performing the integral using continuous data, or performing a discrete time equivalent, for example based on Romberg integration.

The exemplary representation of the Prism filter 100 in FIG. 1, constitutes an FIR filter generating two outputs, a sine output Gₛ^{h} and a cosine output G_{c}^{h}. As such, the exemplary Prism filter 100 of FIG. 1 may be termed a combined Prism filter. Other examples of a Prism filter 100 generate only a single output, a sine output Gₛ^{h} or a cosine output G_{c}^{h}. A Prism filter 100 generating only a sine output may be termed a sine Prism filter. Each sine Prism filter of a filter system is configured to determine a respective sine output Gₛ^{h}, where Gₛ^{h}=Iₛₛ^{h}+I_{cc}^{h}. A Prism filter 100 generating only a cosine output may be termed a cosine Prism filter. Each cosine Prism filter of a filter system is configured to determine a respective cosine output G_{c}^{h}, where G_{c}^{h}=I_{cs}^{h}−I_{sc}^{h}. It is to be noted that a cosine Prism filter or sine Prism filter may comprise integral blocks capable of generating both cosine and sine outputs, but only the respective cosine or sine output is output from the Prism filter.

The properties of a Prism filter 100 are defined by its characteristic frequency m and harmonic number h. Structurally, the Prism comprises at least four and up to six integration blocks, where the input to each is multiplied by a sine or cosine function with frequency h*m Hz and integrated over the period 1/m seconds to generate the corresponding output. Accordingly, each integration block may be considered as analogous to the Discrete Fourier Transform (DFT), well known to those familiar with the art. The Prism integration block calculation can be performed recursively, as the final Prism outputs can be independent of the instantaneous phase of the sinusoidal modulation functions. In examples of the Prism, the equivalent of filter coefficients are linearly spaced sine and cosine values, so that, for desired values of fs, m and h, the design calculation can be straightforward.

Prism signal processing can offer a unique combination of desirable properties: the calculation is FIR, and hence robust; the outputs have linear phase delay; the calculation is fully recursive so that the computational cost per sample is low and fixed, irrespective of the length of the filter, and its design can be straightforward, given desired values offs, m and h, requiring only the evaluation of linearly spaced sine and cosine values.

In some examples, the low pass-filter design uses layers of single output Prisms which calculate either Gₛ^{h} or G_{c}^{h}, and where a layer consists of two or more Prisms operating in parallel. Given m, the characteristic frequency of a Prism, and h its harmonic number, the gain of Gₛ^{h} at frequency f, denoted by Γₛ, is given in equation (6):

$${Γ}_{s} ( f , m , h ) = sin {c}^{2} ( r ) \frac{{r}^{2}}{{r}^{2} - {h}^{2}} , \qquad ( Equation 6 )$$

$$where$$

$$r = f / m$$

while the gain of G_{c}^{h} at frequency f denoted by Γ_{c}, is given by equation (7):

$${Γ}_{c} ( f , m , h ) = sin {c}^{2} ( r ) \frac{rh}{{r}^{2} - {h}^{2}} , \qquad ( Equation 7 )$$

$$where$$

$$r = f / m$$

FIGS. 2A and 2B show how the gain of Gₛ^{h} varies with frequency (relative to m) and h, while FIGS. 3A and 3B show the corresponding gain for G_{c}^{h}. In each case the upper graph (FIGS. 2A and 3A) shows the gain value on a linear scale, while the lower graph (FIG. 2B and 3B) shows the relative gain, compared to the maximum absolute value for each function, on a decibel scale, where the maximum absolute value is indicated by the value 0 dB. These functions share some common features, such as having a gain of zero (equivalent to −∞ dB) at all whole multiples of m, but they also have distinctive properties. The maximum gain values for all G_{c}^{h} functions lie close to m/2 Hz (FIG. 3B) while the maximum gain for Gₛ^{h} lies between (h−1)m and hm Hz (FIG. 2B). While the gains of the Gₛ^{h} functions are all distinct, the phase term of Equation (2) is common for all values of h, so that, for the same input signal, all Gₛ^{h} functions have the same output phase at every frequency; the same common phase property holds for all G_{c}^{h} functions, as shown from Equation (3). Additionally, there is a fixed phase difference of π/2 radians between any one of the Gₛ^{h} functions and any one of the G_{c}^{h} functions, as can be deduced by the respective use of sine and cosine terms in Equations (2) and (3).

FIG. 4A shows an example of a filter system 200 for filtering an input signal s(t) according to the present disclosure. The input signal s(t) is a signal measured from and/or representing a physical entity or physical parameter. The input signal s(t) may be, or may be a representation of, an audio signal, video signal, communications signal, system control signal, seismological signal, biological signal, electrical power signal, radar signal, sonar signal, or signal representing measurements of physical quantities measured by a scientific or industrial instrument. As discussed further below, the filter system 200 may be implemented on a computer system, and/or implemented as a computer program or on a computer readable medium. Alternatively, the filter system 200 may be incorporated into a sensor device comprising a sensor measuring a physical parameter, wherein the input signal s(t) is (or is a representation of) the measurements taken by the sensor.

The filter system 200 comprises a network of Prism filters 201. The network of Prism filters 201 comprises a first branch 210 in parallel with a second branch 220. Each of the first branch 210 and second branch 220 is arranged to receive the input signal s(t) as an input. The first branch 210 comprises at least one cosine Prism filter 211, arranged to generate a cosine output G_{c}^{h} as discussed above. The second branch 220 comprises at least one sine Prism filter 221, arranged to generate a sine output Gₛ^{h} as discussed above. The network of Prism filters 201 is arranged to generate an output signal 230 based on a combination of an output of the first branch 210 with an output of the second branch 220. In preferable examples, the first branch 210 comprises two or more cosine Prism filters 211 connected in series, and the second branch 220 comprises two or more sine Prism filters 221 connected in series, as illustrated further below. By combining cosine and sine Prisms in parallel, the filtering ability of the system 200 may be increased, without increasing the length of the filter, and hence the time delay needed to filter a signal.

In preferred examples, the output 230 is a linear combination (e.g. sum or weighted sum) of the output of the first branch 210 and the output of the second branch 220. As will be appreciated, other combinations are possible, taking into account any phase difference between the output of the cosine first branch 210 and the sine second branch 220.

As shown in the example filter system 200 illustrated in FIG. 4A, the filter system 200 may optionally comprise a tracker 202. The tracker 202 is formed of one or more Prism filters 202-1. The tracker is configured to receive the output signal 230 from the network of Prism filters 201, and to generate an output. The output may be indicative of a parameter of the input signal s(t), such as an amplitude, phase, or frequency of the input signal. Alternatively the tracker 202 may generate one or more outputs selected from the group comprising: G_{c}¹, Gₛ¹, G_{c}², and Gₛ², where G_{c}^{h}=I_{cs}^{h}−I_{sc}^{h}, Gₛ^{h}=Iₛₛ^{h}+I_{cc}^{h}, G_{c}¹=G_{c}^{h} when h=1, G_{c}²=G_{c}^{h} when g=2, Gₛ¹=Gₛ^{h} when h=1, and Gₛ²=Gₛ^{h} when h=2. Such trackers are discussed further below. For example without a tracker 202, the output signal 230 of the network of Prism filters 201 is the output of the filter system 200.

Although the first branch 210 and second branch 220 may comprise only one Prism filter each, in preferred examples each branch 210, 220 comprises multiple Prism filters. Within a branch 210, 220, the multiple Prism filters may be connected in series and/or in parallel with each other. FIG. 4B shows an example of such a filter system 200.

In filter systems 200 such as that of FIG. 4B, the first branch 210 comprises two or more cosine filter sets 211, 212 connected in series such that an output of a respective preceding cosine filter set 211 in the series is input into a respective subsequent cosine filter set 212 of the series. The output of the first branch is an output of a final cosine filter set 212 in the series. Each cosine filter set 211, 212 comprises at least one cosine Prism filter 211a-c, 212a-c. The second branch 220 comprises two or more sine filter sets 221, 222 connected in series such that an output of a respective preceding sine filter set 221 in the series is in input into a respective subsequent sine filter set 222 of the series. The output of the second branch 220 is an output of a final sine filter set 222 in the series. Each sine filter set 221, 222 comprises at least one sine Prism filter 221a-c, 222a-c.

Furthermore, one or more of the cosine filter sets 211, 212 and/or one or more of the sine filter sets 221, 222 may comprise a plurality of cosine (for cosine filter sets)/sine (for sine filter sets) Prism filters 211a-c, 221a-c, 212a-c, 222a-c connected in parallel such that the input to the respective cosine/sine filter set 211, 212, 221, 222 is input into each of the plurality of cosine/sine Prism filters 211a-c, 221a-c, 212a-c, 222a-c of that cosine/sine filter set 211, 212, 221, 222, and the output of the respective cosine/sine filter set is a combination of the outputs of the plurality of cosine/sine Prism filters 211a-c, 221a-c, 212a-c, 222a-c of that cosine/sine filter block set 211, 212, 221, 222.

FIG. 4B shows an exemplary structure of a two layer Prism filter system 200. In this system 200 the number of cosine filter sets 211, 212 in the first branch 210 is equal to the number of sine filter sets 221, 222 in the second branch 220, but this is not necessary. A pair comprising a cosine filter set 211, 212 and a correspondingly positioned sine filter set 221, 222 may be referred to as a layer. Thus the filter system 200 of FIG. 4B is a two layer system. The input signal s(t) is passed through two Prism sets 211, 221 in parallel. In this example each Prism set 211, 221, 212, 222 comprises three Prisms filters 211a-c, 221a-c, 212a-c, 222a-c connected in parallel. Prism filters 211a-c, 221a-c, 212a-c, 222a-c are examples of Prism filter 100, but in this example configured to generate only a single cosine/sine output. Although this is a preferred configuration, the filter sets 211, 221, 212, 222 may comprise any number of Prism filters. Different filter sets 211, 221, 212, 222 may have different numbers of filter systems

The example of FIG. 4B is a two layer system, but any number of filter sets 211, 221, 212, 222 may be used in each branch 210, 220. Preferably, both the first branch 210 and the second branch 220 comprise an even number of filter sets 211, 221, 212, 222. Due to the nature of the cosine and sine calculations, if an even number of filter sets are used the outputs of each branch 210, 220 will be in phase with each other. This allows the outputs to be directly linearly combined into the output 230 without need for any further processing.

In the example illustrated in FIG. 4B, the characteristic frequency, m, of all sine Prism filters and cosine Prism filters 211a-c, 221a-c, 212a-c, 222a-c in the network 201 is the same.

In some examples the second branch 220 comprises a corresponding sine filter set 221, 222 for each cosine filter set 211, 212 of the first branch 210, wherein the harmonic number, h, of a sine Prism filter 221a-c, 222a-c in a sine filter set 221, 222 matches the harmonic number, h, of a cosine Prism filter 211a-c, 212a-c in the corresponding cosine filter set 211, 222.

Further, in some embodiments each cosine/sine filter set 211, 212, 221, 222 may comprises n cosine/sine filters 211a-c, 221a-c, 212a-c, 222a-c. For each cosine/sine filter set 211, 212, 221, 222, each of the plurality of cosine Prism filters 211a-c, 221a-c, 212a-c, 222a-c may comprise a respective harmonic number hᵢ such that a set of harmonic numbers h₁, . . . hₙ is used within the respective cosine filter set 211, 212, 221, 222. The set of harmonic numbers h₁, . . . hₙ of cosine Prism filters 211a-c, 212a-c, of each cosine filter set 211, 212, is the same. Alternatively or additionally, the set of harmonic numbers h₁, . . . hₙ of sine Prism filters 221a-c, 222a-c, of each sine filter set 221, 222, may be the same.

The filter system 200 of FIG. 4B is a particular example of such embodiments, where all the Prism filter sets 211, 212, 221, 222, both cosine and sine, comprise the same set of harmonic numbers. In this particular example, the set of harmonic numbers is 1, 2, and 3.

To provide further tunability to the filter system 200, a respective weight may be applied to the output of each of the plurality of cosine/sine Prism filters 211a-c, 221a-c, 212a-c, 222a-c of a cosine/sine filter set 211, 212, 221, 222 prior to generating the output of that cosine/sine filter set 211, 212, 221, 222. In FIG. 4B the weightings are represented by the circled multiplication signs/operators(?) receiving the outputs of the Prism filters 211a-c, 221a-c, 212a-c, 222a-c. In FIG. 4B, the outputs from the three Prisms filters 211a-c, 221a-c, 212a-c, 222a-c of a set 211, 212, 221, 222 are separately weighted and then linearly combined to form the output of that set. The weight (or multiplication factor) of the Prism output with h=1 is selected to be 1.0 for convenience, while the weights of the Prisms with h=2 and h=3 have respective weightings (w₁ to w₈, in FIG. 4B), which are filter design parameters.

As discussed above, at all frequencies, the three Prism outputs of each set are in phase with one another, so that they can be linearly combined without introducing phase distortion. However, there is a phase difference of π/2 radians between the output of the first sine set 221 and the output of the first cosine set 211 which together constitute the first layer of the filter.

The second layer of the filter in FIG. 4B is similar to the first layer. The second layer consists of two sets 212, 222 of three Prisms 212a-c, 222a-c each, a sine set 222 generating only Gₛ^{h} outputs and a cosine set 212 generating only G_{c}^{h} outputs, where the same common value of m is used as for the first layer, and where h=1, 2, and 3. The input to the second layer sine set 222 is the output of the first layer sine set 221, and the input to the second layer cosine set 212 is the output of the first layer cosine set 211. The outputs of the second layer sine 222 and cosine 212 sets have a relative phase offset of a radians at all frequencies, which is equivalent to a multiplication factor of −1. Accordingly, these outputs can be combined directly without introducing phase distortion. In the illustrated example a final weight w₉ is used to provide a linear combination of the sine and cosine branches 210, 220 to create a single output signal 230 of the filter network 201 (not labelled in FIG. 4B, but comprising the two branches 210, 220) In examples comprising a tracker 202, the output signal 230 is passed to the tracker 202. Otherwise the output signal 230 is used as the output of the filter system 200.

FIG. 4B further serves to highlight the innovation of the current filter design over that taught by reference [4], as the filter structure in [4] consists only of cosine sets. Accordingly, in [4], each Prism layer contains only three Prisms, and only G_{c}^{h} outputs are generated.

FIG. 4B illustrates the preferred example of a filter system 200, which has been developed after substantial experimentation with design detail in order to optimize filter performance against computational requirement and dynamic response. However, other filter structure designs may be considered. In one design variation, the number of Prisms 211a-c, 221a-c, 212a-c, 222a-c in each set may be other than three. For example, 2, 4, or 10 Prisms might be used. Different numbers of Prisms 211a-c, 221a-c, 212a-c, 222a-c may be used in each set 211, 212, 221, 222. The corresponding values of h used for the Prisms 211a-c, 221a-c, 212a-c, 222a-c in each set 211, 212, 221, 222 may also be varied. Similarly, alternative arrangements of sine 221, 222 and cosine 211, 212 sets might be implemented, for example with a first branch 210 providing a cosine set 211 followed by a sine set 221, and a second parallel branch 220 providing a sine set 222 followed by a cosine set 212, where both paths are eventually combined. More than two parallel branches 210, 220 might be implemented, and/or more than two layers may be used between the single input time series s(t) and a single output time series. Data paths should preferably be combined (for example, by the weighted sum technique shown in FIG. 4B) only when they have the same phase, in order to avoid phase distortion. This may require that, for example, a common value of m is used for all Prisms 211a-c, 221a-c, 212a-c, 222a-c, and/or that all branches 210, 220 to be combined contain the same number of Prisms 211a-c, 221a-c, 212a-c, 222a-c, and/or that whenever two signal branches 210, 220 are combined, they both contain the same number of cosine sets 211, 212, modulo two, i.e. either they both contain an even number of cosine sets 211, 212 or they both contain an odd number of C sets 211, 212.

FIG. 4B illustrates a two layer Prism filter system 200; this design may be extended to provide any even number of layers, added in series to the first two layers, where adding additional layers may provide improved filtering performance. In each pair of layers, the corresponding weights (w₁-w₉) may be the same or different, depending upon the filter design criteria selected, as discussed below. Accordingly, a 6 layer filter can be specified using 27 weights and a 12 layer filter can be specified using 54 weights, together with the selected value of the characteristic frequency, m.

In a more computationally efficient instantiation, the network of Prism filters 201 may comprise a combined filter set comprising at least one combined Prism filter 100, similar to the filter 100 shown in FIG. 1. Each combined Prism filter 100 is configured to determine a respective cosine output G_{c}^{h} and a respective sine output Gₛ^{h}. The c combined filter set is arranged to provide a first filter set of both the first branch 210 and the second branch 220 by receiving the input signal s(t) and outputting a cosine output to the first branch 210 and a sine output to the second branch 220. Thus for the preferred example of FIG. 4B, the separate cosine and sine sets 211, 221 of the first Prism layer may be replaced by a single set of three (or any number) combined Prisms filters 100, for example using h=1, 2 and 3 respectively (and further incremental steps of h for larger numbers of combined filters 100). This arrangement generates identical Gₛ^{h} and G_{c}^{h} outputs at reduced computational cost: only 18 Prism integration blocks are needed for three combined Prisms 100 (with six blocks in each Prism—see FIG. 1) as opposed to 24 Prism integrations blocks required for six single output Prisms 211a-c, 221a-c, where each Prism contains four integration blocks. Other aspects of the instantiation may remain unchanged—the Gₛ^{h} and G_{c}^{h} outputs are weighted and combined separately, as in FIG. 4B, and the second layer Prisms remain in separate sets, with each Prism 212a-c, 222a-c generating a single output, as the inputs for the cosine and sine sets 212, 222 are different for the second layer. The number and role of the weights w; may remain unchanged. This more computationally efficient instantiation may also be used in other Prism layer filter designs such as those discussed above, including those with more than two layers. As a general principle, whenever a Prism layer has one common time series as an input s(t), and where both a Gₛ^{h} output and a G_{c}^{h} output are calculated using a common value h, then a dual output Prism can be used to replace two single output Prisms.

Filter design may consist of selecting weights to provide the desired frequency response characteristic of the filter.

In one approach, the weights are selected using optimisation based on gain functions of the Prism filters of the filter network. For example, weight selection may be achieved by defining an optimization problem which may be solved using conventional tools familiar to those practicing the art—for example Matlab®. An example optimization calculation for a two layer filter may be implemented as follows. The weights w₁-w₉ are the unconstrained variables, the values of which are to be optimized according to some cost function to be determined. For a given set of wᵢ, the corresponding frequency response may be calculated analytically over a range of values of r, for example r=f/m=0, 0.01, . . . , 10, using the gain functions given in Equations (6) and (7), along with the specific filter design structure and wᵢ values as exemplified in FIG. 4B. From the calculated frequency response, the cost function can be evaluated. For example, the cost function to be minimized might be the highest magnitude of the gain for the frequency response calculated for all r>1.0 (equivalent to f>m). Assuming the filter structure shown in FIG. 4, selecting values of w₁-w₉ which minimize this cost function will result in a filter design which has maximum stopband attenuation. Other examples of filter design optimization are discussed below. Note that in the preferred instantiation shown in FIG. 4B, the use of fixed weights of value 1.0 for the h=1 Prisms 211-a, 212-a, 221-a, 222-a may help ensure an efficient search for an optimal solution: for example, this fixed weighting prevents a cost function becoming arbitrarily small simply by assigning low values to the weights for all Prisms.

FIGS. 5A and 5B (detail of FIG. 5A) show exemplary filter system 200 designs using 6, 8, 10 and 12 layers respectively (each layer with a set of three cosine prism filters and a set of three sine prism filters, as in FIG. 4B above), where the design criterion in each case is to minimize the maximum gain for frequencies above m Hz, in other words, to maximize the stopband attenuation above m Hz. For the 6 layer filter (labelled LP6), the stopband attenuation is −154.3 dB, which is a significant improvement over the −138 dB achieved in [4] using a 6 layer filter consisting of cosine sets only. For the 8, 10 and 12 layer filters, labelled respectively LP8, LP10 and LP12, the corresponding stopband attenuations are −199.3 dB, −251.8 dB and −293.6 dB.

These filter system 200 designs are independent of any particular selection of the characteristic frequency m. Once a filter design is complete, it may be instantiated with any desired value of m (and hence the desired filter cutoff frequency) as required for a particular application, subject to the previously noted constraints that, due to sampling discretization, the ratio m/fs must be an integer. As described in [4], such low pass Prism filter system designs may be used in conjunction with the technique of heterodyning, well known to those familiar with the art, in order to apply band pass filtering. As also described in [4], such a filter may be used together with a Prism tracker 202 [1], to generate frequency, amplitude and/or phase estimates of the resulting filtered signal.

FIGS. 6A and 6B (detail of FIG. 6A) show results from an alternative series of filter system 200 designs based on the template of FIG. 4B, where a different optimization criterion is used for the selection of the weights wᵢ. Here the requirement for a low stopband gain is combined with a requirement to generate a flat passband. Comparing FIGS. 5A and 6A, it can be seen that, for a given number of filter layers, the stopband attenuation is generally lower in FIG. 6A then in FIG. 5A. For example, for the 8 layer filter (labelled LP8 in both graphs), the stopband attenuation is −199.3 dB in FIG. 5A, but only −120.2 dB in FIG. 6A. FIGS. 5B and 6B show in detail the peak gains for each of the displayed filters. In FIG. 5B, the peak gains occur as simple maxima, and the passband region is narrow. For example, for the LP12 filter, the range of (dimensionless) frequencies for which the gain exceeds −0.06 dB is approximately r=0.4 to r=0.42, a range of 0.02. By contrast, FIG. 6B show wider passbands where the variation in gain near the peak may be minimized (or ‘flattened’). For example, for the LP12 filter, the range of (dimensionless) frequencies for which the gain exceeds −0.06 dB is approximately r=0.39 to r=0.48, a range of approximately 0.09, more than four times wider than the corresponding range in FIG. 5A. Additionally, for the LP12 filter in FIG. 6B, between approximately r=0.42 and r=0.45 the gain is ‘flat’, varying between −0.003 dB and 0.0 dB.

Filter designs such as those shown in FIG. 5A may be useful for example in instrumentation applications where the signal to be filtered has narrowband characteristics. Filter designs such as those shown in FIG. 6A may be useful for example in communications or audio processing applications where the signal to be filtered has broadband characteristics, and where a flat passband gain is useful, even at the expense of less effective stopband attenuation. Accordingly, these two filter design types may be designated as ‘sharp’ and ‘flat’ respectively. Those familiar with the art will recognize that other filter design criteria may be developed for multilayer Prism filters according to the requirements of any particular application.

The filter system 200 described above may be used in a method of filtering an input signal. Such a method 300 is illustrated in FIG. 6C. In a first step 301, the filter system 200 is instantiated. This may be a temporary instantiation, for example where the filter system 200 is regularly changed. Alternatively the filter system 200 may be instantiated as a permanent filter block, for example of a sensor device. At a second step 302, the input signal is input into the instantiated filter system to filter the input signal.

### Designing Convolutional Filters

One of the original motivations for the development of the Prism was the desire to improve computational efficiency for FIR filtering by the introduction of a recursive calculation, which advantageously has a fixed computational cost irrespective of filter length. As described in [2], for long filters (say in excess of 1 billion samples), the computational cost of Prism filter operation may be reduced by a factor of more than ten million compared with that of an equivalent convolutional FIR filter. A further benefit is the low cost and simplicity of Prism filter design and instantiation compared with the various techniques for designing convolutional filters [A, 1]. However, the memory storage requirements for such Prism filters may be significantly higher than for a convolutional filter.

The computational advantage of the Prism technique over the convolutional FIR filter may be lower for shorter filter lengths. Furthermore, where large numbers of Prisms are used to instantiate a particular filter system design (for example 72 Prisms are used to instantiate a 12 layer filter design based on the structure shown in FIG. 4B), the computational advantage may be correspondingly reduced while the Prism data storage requirement may be increased. Accordingly, there may be applications where it is advantageous to use Prism methods for filter design, but to then convert the resulting Prism-based design into a convolutional form for filter calculation. This may result in reduced computational load and/or memory storage requirements.

Further potential benefits of a convolutional implementation of a Prim-based filter design include the following. The Prism's recursive form of filter update calculation is designed for real-time operation, and assumes that an update is performed every sample. There are applications where parameter estimates, for example of frequency, phase and/or amplitude, may be required less frequently than once per sample. There may also be data analysis applications, for example in spectral analysis, where a data set may be static, rather than changing dynamically in time. In such cases, it may be computationally advantageous to apply a single convolution calculation to the entire data set, rather than treat the data set as a time series to be processed on a sample-by-sample basis.

FIG. 7A shows the frequency response of a particular Prism-based filter design. Here a 12 layer filter has been created by concatenating two 6 layer Prisms of the LP6 design shown in FIGS. 5A and 5B, which in turn is based on the layer design shown in FIG. 4B. The stop band attenuation for the 12 layer, 72 Prism filter is −313.66 dB. It has been instantiated to use a sampling rate fs of 40 Hz; the value of m is 1 Hz, and the total filter length is 960 samples. Accordingly, filter notches occur at 1 Hz and every whole multiple of 1 Hz.

FIG. 7B compares the theoretical response of the filter in FIG. 7A to the actual response obtained when random white noise is passed through a Prism-based instantiation of the filter. It can be seen that the actual numerical performance matches the theoretical response well. For example, the detailed variation of sidelobe height between 1 Hz and 4 Hz predicted by the theoretical frequency response is well matched by the numerical filtering of the white noise time sequence. Note however, that the noise floor remains constant at around 1e−21 rather than reducing with increasing frequency, as predicted by the theoretical gain of the filter. This reported noise floor behavior may reflect the limitations of the Fast Fourier Transform (FFT) algorithm used to calculate the frequency spectrum, rather than a limitation on the Prism filter numerical performance. Besides, for many applications, an observed reduction of 16 orders of magnitude in frequency response gain from its peak (˜e−5 at around 0.5 Hz) to the noise floor in the stop band (˜1e−21 at around for example 7 Hz), would be considered an acceptable filter performance.

As noted above, there may be situations where it is preferable to instantiate the filter system as a convolutional filter, rather than as a Prism instantiation. To achieve the beneficial filtering characteristics of the Prism network, methods according to the present disclosure first construct a filter system, and then generate a convolutional filter using the Prism filter system. FIG. 8 illustrates an example of such a method.

FIG. 8 illustrates a method 400 of designing a convolutional filter for filtering an input signal. The method starts at step 401, at which a filter system arranged to receive the input signal is generated. The filter system comprises at least one Prism filter. The Prism filter is a Prism filter as described above, i.e. that is configured to evaluate double integrals as for Prism filter 100. Evaluating the double integrals may include directly performing the integrals, as in the case of continuous data, or performing numerical equivalents, as in the case of discrete data.

The generated filter system may be a filter system according to the examples described above in relation to FIGS. 4A to 6C. Alternatively any other filter system comprising one or more Prism filters may be used. For example, filter system may comprise a plurality of Prism filters connected in series such that an output of a respective preceding Prism filter in the series is in input into a respective subsequent filter of the series. The filter system may comprise a plurality of Prism filters connected in parallel such that each Prism filter of the plurality of parallel-connected Prism filters receives a common input. The filter system may comprise combinations of Prisms connected in series and Prisms connected in parallel. The filter system may be a filter system as disclosed in any of the documents cited in the reference section below, each of which is incorporated by reference herein.

In some examples, the filter system is or comprises a tracker (i.e. a tracker Prism as described above) configured to generate an output indicative of a parameter of the input signal, such that the generated convolutional filter acts as a tracker configured to generate an output indicative of the parameter of the input signal. The parameter of the input signal may comprise at least one of: amplitude, phase, and frequency. Alternatively, the ultimately generated convolutional filter, described further below, may be combined with a tracker Prism to generate the output indicative of the parameter of the input signal.

In general, generating the filter system may comprises selecting, based on the input signal or a physical system represented by the input signal, at least one of: a number of Prism filters within the filter system; an arrangement of Prism filters within the filter system; a harmonic number of one or more of the Prism filters within the filter system; a characteristic frequency of one or more Prism filters within the filter system. For example one or more of these parameters may be selected based on a maximum desired time delay introduced by the filter. Additionally or alternatively, one or more of these parameters may be selected based on a maximum desired length of the filter (e.g. due to computational constraints). Additionally or alternatively, one or more of these parameters may be selected based on desired passband characteristics, such as shape across the pass band (e.g. approximately flat gain for all frequencies in the pass band), and/or amount of attenuation after the passband. The filter system, and its parameters, may be selected based on a particular use intended for the filter.

Having generated the filter system, method 400 proceeds to step 402, at which a test signal is input into the filter system to generate a test/impulse response of the filter system. In other words, the test signal is used as an input signal for a Prism-instantiated filter system; and the resulting output of the filter system is the impulse response. In preferred examples the test signal is an impulse signal, but other appropriate signal forms may be used that generate a test/impulse response from which a convolutional filter can be generated.

Method 400 then proceeds to step 403, at which a convolutional filter for filtering the input signal is generated based on the impulse response of the filter system. In the simplest examples, where the test signal is an impulse signal, the impulse response of the Prism filter system is output as the convolutional filter. In other examples, further processing steps may be applied to generate the desired convolutional filter. For example, the impulse response may be truncated to form the convolutional filter.

FIGS. 9A and 9B show the impulse response of the Prism-based filter illustrated in FIGS. 7A and 7B. The calculation of the impulse response of a filter design is a well-established means of generating the coefficients of a convolution filter. An input signal is created consisting of a single sample with value 1.0, followed by a sequence of samples with value 0.0. As the Prism-based filter in this example has a length of 960 samples, an input sequence (i.e. test signal) of 960 samples, the first of value 1.0 and all others with value 0.0, are applied as an input time series to the filter, and the corresponding 960 samples of output are recorded as the impulse response. FIG. 9A shows the values of the impulse response against sample number on a linear scale, while FIG. 9B shows the absolute value or magnitude of the impulse response on a logarithmic scale. It can be seen that the peak value is approximately 0.01, while at the start and end of the impulse response the magnitude drops below 1e−20. As will be well known to those familiar with the art, these 960 values forming the impulse response sequence can be used as the coefficients of a convolutional FIR filter, which may provide the same filtering performance as the Prism-based filter of FIGS. 7A and 7B.

For example, given the convolutional filter values cᵢ (i=1, 2, . . . , 960) and data series xᵢ (i=1, 2, . . . , 960), the output value yₜ can be calculated using the convolution of x and c as shown in Equation (8):

$${γ}_{out} = {\sum }_{i = 1}^{960} {c}_{i} \cdot {x}_{i} \qquad Equation ( 8 )$$

This equivalent filtering performance is demonstrated in FIG. 10. FIG. 10A shows a section of the random sequence used as the input time sequence for the generation of FIG. 7B. FIG. 10B shows the corresponding output of the Prism based filter. It can be seen that this output is considerably more smooth than FIG. 10A, having an approximately sinusoidal form with varying amplitude, and with a cycle period of approximately 2s, corresponding to the peak frequency of approximately 0.5 Hz in FIGS. 7A and 7B. FIG. 10C shows the corresponding output from the convolution form of the filter, created from the impulse response sequence shown in FIG. 9A and calculated using Equation (8). Visually, this appears very similar to the output of the Prism implementation of the filter shown in FIG. 10B. This is confirmed in FIG. 10D, which shows the difference in output values between FIG. 10B and FIG. 10C, which is of the order of 1e−17. This example demonstrates the principle that an FIR filter designed using Prism structures, such as those of FIGS. 4-7B, may be converted into a convolutional form of Equation (8) via the technique of generating the impulse response, where the resulting filtering performance of the Prism and convolution forms of the filter are very similar.

The computational load associated with evaluating the convolutional filter of Equation (8) consists of one multiply and accumulate operation for each filter coefficient [A, 1]. Here, with 960 coefficients, the resulting computation is 1920 floating point operations. By contrast, as discussed in reference 1, the computational load for updating a single output Prism is 18 multiplications and 33 additions (assuming only one stage of Romberg Integration is applied). For the 72 Prism design of FIG. 8, this corresponds to 3672 floating point operations per sample, approximately double that of the convolution calculation. However, the Prism filter's recursive form of calculation requires that this computational load must be expended every sample, while the convolutional filter may be applied to any consecutive set of 960 samples, without the requirement for continuous updating every sample.

For example, the convolution calculation may be applied on an occasional basis, say, only after another ten or one hundred new samples have been received, as long as the calculation is based on the most recent 960 consecutive samples in each case. By contrast, the output of the Prism design is only valid if updates have taken place for all of the previous 960 samples.

A further advantage of this convolutional form of filtering is the reduced memory storage requirement: the calculation of Equation (8) requires only the set of coefficients, the values of the most recent samples, and an accumulator. By contrast, there are larger storage requirements for the 72 Prism filter implementation, given, for example, the need to store vectors of product values in each Prism.

In the example given above, the full impulse response of 960 samples was used to create the convolutional filter. Given the small magnitude of the impulse response at its beginning and end, shorter convolutional filters may be created by truncating those values at the beginning and end of the impulse response below a certain magnitude threshold, for example 1e−20. Reducing the filter length in this way will result in a faster dynamic response, while having only a limited impact on other aspects of filter performance.

Convolution Designs which Combine Filtering and Tracking

As disclosed in the prior art [A, B, 1-4], while single output Prisms may be advantageously employed for the instantiation of various types of filtering, dual output Prisms, generating both Gₛ and G_{c} outputs (FIG. 1), may further be used to create trackers, where parameters such as frequency, amplitude and/or phase may be calculated for an assumed sinusoidal input signal, and where such calculation is made possible by the π/2 phase offset between Gₛ and G_{c}. so that the two outputs may be considered analogous to the analytic form of signal [1].

Commonly, a tracker is preceded in the signal processing chain by a filter, which may be used to restrict the frequency range of the input signal to match that of the signal component to be tracked. FIG. 11 shows an example of a filter system 500 for filtering and tracking an input signal. The filter system 500 comprises a low pass filter 501, for example of the types illustrated in FIGS. 4-10 and discussed above. The output of the low pass filter 501 is passed to one or more tracker Prisms 502. In the illustrated example, the output is passed to two dual-output tracker Prisms 502a, 502b. A first tracker Prism 501a has parameter value h=1 generating outputs Gₛ¹ and G_{c}¹. A second tracker Prism 502 has parameter value h=2 generating outputs Gₛ² and G_{c}². A calculation block 503, which may be implemented for example on a processor of a computer, or processor of a dedicated filter hardware block, uses the Prism outputs to calculate estimates of frequency, phase and amplitude, based on the results given in Equations (2) and (3). The filter system 500 may be implemented using Prism filters. Alternatively the filter system 500 may be converted to a convolutional filter using method 400, such that the convolutional filter also outputs the corresponding Gs and Gc outputs (collectively referred to as ‘G’ outputs). Further alternatively, the low pass filter 501 may be a convolutional filter generated by method 400, with the trackers 502 implemented by Prism instantiations. Although shown as a low pass filter 501, in other examples filter 501 may be a band-pass filter.

Parameters of the input signal can be calculated as follows. Firstly, the dimensionless frequency, r, may be calculated from the values of the two Prism outputs as follows. Firstly, a ratio x is calculated, where

$$x = \sqrt{\frac{4 {G}_{s}^{2} * {G}_{s}^{2} + {G}_{c}^{2} * {G}_{c}^{2}}{{G}_{s}^{1} * {G}_{s}^{1} + {G}_{c}^{1} * {G}_{c}^{1}}} \qquad Equation ( 9 )$$

The estimated value of r, may then be derived using:

$$r = \sqrt{\frac{4 x - 2}{x - 2}} \qquad Equation ( 10 )$$

The corresponding estimate of the tracked frequency f is simply:

f=r*m Equation (11)

Once the value of r has been calculated, it is straightforward to calculate the amplitude A and phase ϕ of the tracked signal, as follows:

$$A = {[ \frac{π}{sin ( π r )} ]}^{2} [ 1 - {r}^{2} ] \sqrt{{G}_{s}^{1} * {G}_{s}^{1} + {r}^{2} * {G}_{c}^{1} * {G}_{c}^{1}} \qquad Equation ( 12 )$$

$$and$$

$$ϕ = a tan ( - {G}_{s}^{1} , r * {G}_{c}^{1} ) \qquad Equation ( 13 )$$

where atan is the inverse tangent function. Note that the above calculations may be subject to potential numerical instability, for example if the signal-to-noise ratio of the input signal is low, or the calculated value of r is close to a whole number. Those familiar with the art will appreciate that standard checking techniques can be applied to ensure numerical stability is preserved, with sensible default values (e.g. A=0) provided where a stable calculation is not possible with the current set of data values.

Further corrections to the calculated values of A and ϕ may be applied to compensate for the influence of the low pass filter 501 shown in FIG. 11. For example, corrections to A may be applied, based upon the calculated gain of the low pass filter at the calculated input frequency f, while corrections to ϕ may be based upon the sample length of the low pass (and linear phase) filter and f Where the combined filter and tracking system of FIG. 11 is combined with a heterodyning calculation, as discussed below, then additional corrections may be applied to the value of f, A, and ϕ to compensate for the effects of heterodyning.

As noted above, the filtering and tracking scheme/filter system 500 of FIG. 11 can be implemented using a variety of Prism and convolutional forms. In one instantiation, both the low pass filter 501 and tracker 502 are implemented using Prism implementations, for example where the low pass filter has a narrow passband, the Prism filters contain many samples, and so the Prism implementation is computationally advantageous over the equivalent convolutional form. In another instantiation, the low pass filter 501 may be implemented as a convolution, as described above, while the tracker 502 uses one or more Prisms. Such an arrangement might be advantageous where a relatively short low pass filter 501 is used (for example the case described above and illustrated in FIG. 9), so that the convolutional form of filter is more computationally efficient, but where updates of f, A, and ϕ are required every sample, so it is remains efficient to use a tracker stage implemented using one or more Prisms.

In a third implementation, both the low pass filter 501 and the tracker Prisms 502 may be implemented as a set of four convolutions, as described below. For example, tracker 502 may be arranged to generate only one of the ‘G’ outputs. The equivalent convolutional filter generated by using such a filter system 500 in the method of 400 will thus also generate one of the ‘G’ outputs. This can be computationally advantageous where updates are required on an occasional basis, rather than with every new sample. This implementation may be particularly advantageous where a static data set is to be analysed, and where a single estimate of frequency, amplitude and/or phase is to be determined, for example in spectral analysis of a fixed data set, as discussed below. In such applications, a convolutional form of calculation, combining both low pass filtering and tracking aspects into a single set of coefficients, may result in a significantly reduced computation load, compared with a Prism instantiation requiring repeated computation on the data propagated through Prisms as a time series.

FIG. 12A shows an alternative means of performing the same calculation as shown in FIG. 11 using convolutional filters only. In FIG. 12, four convolutional filters calculate the values Gₛ¹, G_{c}¹, Gₛ² and G_{c}². In each case, the convolutional filter combines the low pass filter 501 common to all four Prism outputs channels in FIG. 11 together with the additional calculation associated with one of the tracker Prism 502 outputs. The results of these four convolution calculations may be used to estimate frequency, phase and amplitude values of the input data using the same methods and equations (9)-(13) as discussed above.

Thus some examples of the present disclosure provide a method of filtering an input signal using convolutional filters to generate an output indicative of a parameter of the input signal, such as amplitude, frequency, and/or phase of the input signal. FIG. 12B illustrates such a method 600.

FIG. 12B shows a method 600 of filtering an input signal. Method 600 starts at step 601, at which two or more convolutional filters are provided. Each convolutional filter of the two or more convolution filters is generated using the method 400, and is arranged to generate a respective one of the outputs G_{c}¹, Gₛ²G_{c}² and Gₛ². For example, the filter system used in method 400 may be the filter system 500, with the tracker 502 arranged to generate the respective one of the of the outputs G_{c}¹, Gₛ¹, G_{c}², and Gₛ². Preferably the same low-pass (or band-pass) filter 501 is used in the filter system 500 used to generate each of the two or more convolutional filters. In general any filter system arranged to generate one of the outputs G_{c}¹, Gₛ¹, G_{c}², and Gₛ² may be used to generate the convolutional filters. It is noted that only two convolutional filters generating two of the respective outputs are required, as in some examples two similar outputs may be generated from the initial two, for example in the FFT process described further below. Thus in some examples two convolutional filters are provided. In other examples, four convolutional filters, one for each of the outputs G_{c}¹, Gₛ¹, G_{c}², and Gₛ² are provided. Providing the convolutional filters may comprise generating the filters using method 600 (e.g. dynamically) or retrieving filters (or coefficients thereof) previously generated by method 400. Providing the convolutional filters may comprise providing a memory storing the convolutional filters (or coefficients thereof). The memory may be a memory of a dedicated filter device comprising dedicated hardware, configured to receive and filter an input signal. The memory may be a memory of a computing device. Method 600 then proceeds to step 602, at which each of the two or more convolutional filters is applied to the input signal to generate the outputs G_{c}¹, Gₛ¹, G_{c}², and Gₛ².

Method 600 then proceeds to step 603, at which an output indicative of a parameter of the input signal is generated. In particular, at least one of the amplitude, frequency and phase of the input signal may be generated based on the outputs G_{c}¹, Gₛ¹, G_{c}², and Gₛ². Step 603 may use one or more of the equations (9)-(13) (and/or (23) and (24) discussed below) to generate the at least one of amplitude, frequency, and phase. It is noted that in some examples, the outputs from step 602 may be stored and/or output to an external system. The step 603 may then be performed later as a post-processing step using the stored/transmitted outputs G_{c}¹, Gₛ¹, G_{c}², and Gₛ².

FIGS. 13 and 14 show examples of impulse responses for Prism networks consisting of the low pass filter 501 of FIGS. 7A-9B followed by the tracker Prisms 502 shown in FIG. 11. FIGS. 13A and 13B show the impulse responses to generate Gₛ¹ and G_{c}¹, while FIGS. 14A and 14B show the impulse responses to generate Gₛ² and G_{c}². As illustrated in FIG. 7A, the peak gain of the low pass filters occurs at around 0.4 Hz; as discussed in the herein referenced documents, the optimal value of r for a tracker is 0.5, and so accordingly the value of m selected is 0.8333 Hz corresponding to a total tracker Prism length of 96 samples. Including the 960 samples used in the low pass filter, the combined Prism networks have a total length of 1056 samples, which corresponds to the length of the impulse responses shown in FIGS. 13 and 14. It is to be noted that in any filter or filter system of this disclosure, the filter/filter system may be designed with a value of m selected to provide a desired value of the dimensionless ratio r, where r=f/m. In particular, the desired value of r may be in the range 0.4 to 0.6, or may be (approximately) 0.5.

It may appear inefficient to implement four separate convolutional filters, given that the low pass filter is common to all. However, if the filtering and tracking stages are implemented as separate convolutions, for the current design where the tracker Prisms are of length 96 samples, it would require 96 separate evaluations of the low pass filter to generate a time series sufficiently long to generate a single set of tracker outputs. Accordingly, unless tracker outputs are to be generated every sample, a four convolution filter instantiation may be more computationally efficient.

### Prism Spectral Analysis

Reference [4] describes some of the technical challenges associated with the spectral analysis of a fixed data set, in particular using the well-known Fast Fourier Transform (FFT), together with a potentially improved analysis made possible through the use of the Prism bandpass filtering technique previously described [B,2]. The low pass filter invention disclosed here, particularly as instantiated in the convolutional form described above, offers a simple, low cost and precise means of performing spectral analysis, which may provide substantial improvements over prior art FFT methods as well as the previously described Prism-based band pass technique. A brief review of the limitations of prior art FFT analysis is followed by the introduction of a problem example. The new Prism technique is then explained, and its performance compared with that of conventional FFT for the problem example.

Reference [4] introduces the FFT and its associated challenges as follows: “The Fast Fourier Transform (FFT) is one of the most widely used techniques in signal processing . . . , generating a set of Discrete Fourier Transform (DFT) results, linearly spaced in the frequency domain. Its key advantage is an o(n log(n)) computational cost, for a time series of length n samples. However, the extraction of frequency, amplitude and/or phase information for the spectral peaks obtained from FFT/DFT calculations remains an active research topic . . . In short, unless a peak happens to coincide exactly with a DFT/FFT frequency, interpolation and/or other techniques are required to estimate the true peak frequency and amplitude. Additional challenges include spectral leakage, where DFT/FFT processing of a peak at one frequency may result in the apparent transfer of energy to adjacent frequencies, which have negligible energy in the original signal. This in turn may result in ‘hidden tones’ whereby a true peak of low magnitude, in the near vicinity of a higher peak, is obscured.”

The conventional FFT calculation may provide, for each frequency step, a complex value with corresponding real (cosine) and imaginary (sine) parts, from which corresponding amplitude and phase terms are readily calculated; these provides estimates of the amplitude and phase of the corresponding frequency component of the original time series. Note that in this disclosure, the terms “magnitude” and “amplitude” are used interchangeably.

Reference [4] provides a working example, using two spectral peaks with amplitudes of 0.5 V and 1e−9V respectively, to explain and demonstrate the limitations of FFT, particularly with regard to hidden tones. A Prism-based spectral analysis using the band pass filtering technique is introduced, which demonstrates improved performance compared with a conventional FFT calculation. In the current disclosure the art is advanced in several important respects: the new filter structure of FIGS. 4A & 4B significantly reduces the impact of spectral leakage, while the four convolution implementation provides a simple, flexible, efficient and accurate analysis of spectral data. A further instantiation, requiring only two convolutions, is also disclosed below.

A numerical example, which includes random variations, is used to illustrate the new technique and its advantages over well-established FFT methods. FIG. 15A shows a time series consisting of 3926 values, sampled at 1000 Hz. The time series has been created by summing 13 pure sinewaves (termed here ‘signal components’ or just ‘components’; in the context of spectral analysis they may also be referred to as ‘peaks’) of various frequencies and amplitudes, together with additive white noise from a normal distribution with standard deviation 1e−10 V. The exact frequency and the initial phase of each component, along with the random noise sequence and its standard deviation, may vary for each simulation result as set out below. However, the amplitude of each component is fixed, varying from 1 V down to 1e−9 V. Approximate frequencies and exact amplitudes for the thirteen components are listed in Table 1.

TABLE 1
Approximate Frequencies and Exact
Amplitudes of Signal Components

| | Approx. | |
|---|---|---|
| Component | Frequency (Hz) | Amplitude (V) |
| 1 | 50 | 1.00E−01 |
| 2 | 63 | 1.00E−04 |
| 3 | 123.5 | 1.00E+00 |
| 4 | 137 | 1.00E−07 |
| 5 | 170 | 1.00E−02 |
| 6 | 240 | 1.00E−03 |
| 7 | 285 | 1.00E+00 |
| 8 | 300 | 1.00E−06 |
| 9 | 316 | 1.00E+00 |
| 10 | 348 | 1.00E−09 |
| 11 | 390 | 1.00E−05 |
| 12 | 422.5 | 1.00E−01 |
| 13 | 436 | 1.00E−08 |

As understood by those familiar with the art, a variety of techniques can be used in conjunction with the basic FFT calculation to improve the accuracy of the results obtained, for example by reducing spectral leakage. These techniques include the application of various windowing functions, as discussed below. The potential for improved results is illustrated in FIG. 15B which shows two results when applying different FFT calculations to the time series of FIG. 15A. The true peak values of Table 1 are marked as circles at the appropriate frequency and amplitude co-ordinates. The dotted line labelled ‘FFT’ is calculated using FFT alone. The dashed line labelled ‘Hann’ results from using the Hann windowing function before performing the FFT calculation. Note that both these techniques are well understood by those familiar with the art, and the calculations have been carried out using standard function calls in the MATLAB® library. Accordingly, these results represent conventional FFT performance, without exploiting any additional problem-specific knowledge that might yield further improvement. Alternative windowing functions and further adaptations of the FFT technique are well established in the prior art, and the results in FIG. 15B are presented as representative of current practice, rather than optimally selected for the specific data set.

The results in FIG. 15B illustrate the phenomenon of spectral leakage, and the improvements that can be obtained by applying windowing techniques to the basic FFT calculation. Both FFT methods are able to identify the peaks with amplitudes above 1e−2 V, but high levels of spectral leakage are generated by the plain FFT method, with an apparent noise ‘floor’ of approximately 1e−3, so that all the peaks with amplitudes of less than 1e−3 become ‘hidden tones’ [4]. By contrast, the Hann+FFT technique exhibits significantly reduced spectral leakage, so that only peaks with an amplitude of 1e−6 or less become ‘hidden’. As previously disclosed, such hidden tones are not readily identified and quantified based on the data generated by the FFT calculation [4].

FIGS. 16A and 16B illustrate the Hann window and its application to the data set of FIG. 15A. In FIG. 16A, the Hann window function is shown. It consists of a sinusoid offset by a value 0.5 so that all values are non-negative, and where its period matches the length of the data set of FIG. 15A. FIG. 16B shows the result of applying the Hann window to the data set of FIG. 15A. Each point in the original data set is multiplied by the value of the corresponding point in the Hann window. The conventional FFT calculation is then applied to the resulting set of product values show in FIG. 16B, in order to obtain the results with reduced frequency leakage shown in FIG. 15B. As is well known to those familiar with the art, the application of Hann windowing reduces frequency leakage by minimizing the discontinuity between the start and end of the data set [see, for example, Richard G. Lyons, “Understanding Signal Processing”, Third Edition, Prentice Hall, 2011, p89-96, “Section 3.9: Windows” ], which for the Hann window is achieved by reducing the data values to zero at each end.

FIGS. 17A and 17B show the equivalent results to FIGS. 15A and 15B, obtained for another simulation where the random noise standard deviation is increased to 1e−3 V. As the noise floor for the plain FFT technique is already high, the additional noise has little impact. For the Hann+FFT results the noise floor rises to approximately 1e−4 V, and several more signal components are hidden by noise, but peaks with amplitudes of 1e−3 or higher appear to be correctly identified.

To evaluate the FFT performance in more detail, a series of simulations have been carried out. In these simulations, the results obtained for the Hann+FFT variant technique have reduced errors compared with the plain FFT, and so only the Hann+FFT results are described. These are taken to be representative of a conventional modern FFT calculation, to be compared with the novel Prism-based technique described below.

The characteristics of the simulation trials reflect the key sources of error associated with the FFT, which are well known to those familiar to the art, and are discussed in [4]. In general, the FFT calculation does not identify peak frequencies or amplitudes, such as those associated with the signal components listed in Table 1, but instead it generates estimates of signal amplitude at regularly spaced intervals of frequency. The accuracy with which a signal component's amplitude is calculated by the FFT is a function of how far the component's true frequency lies from the nearest FFT frequency value. This distance is often referend to as S [4], where the frequency difference is scaled by the FFT frequency step length, and lies in the range [−0.5, 0.5]. When δ=0, the error in the FFT estimate of component amplitude is small, while for larger magnitudes of S the amplitude error can be much greater. In some applications, the true frequency of a signal component may be known, so it may be possible to select for example the sampling rate to ensure that δ=0. More generally, however, the exact frequencies of the one or more components may not be known, and/or it is not possible with multiple components to select a single sampling rate resulting in favourable values of S close to zero. Accordingly, in the simulations presented here, and as detailed below, random small variations in the frequency of each of the signal components are generated, matching the complete range δ ∈ [−0.5, 0.5], in order to evaluate the resulting distribution of amplitude error arising from the FFT calculation.

A further source of error, as previously described, is spectral leakage: commonly, the FFT calculation ‘spreads’ the influence of a high amplitude component beyond its immediate frequency, so that in its near vicinity relatively high amplitudes are reported even though there may be no local component. A ‘hidden peak’ occurs when a real but low amplitude component is not visible in an FFT spectrum because of higher amplitude spectral leakage from one or more large neighbouring peaks. This effect is illustrated in FIG. 15B, where the Plain FFT calculation reports no amplitude lower than approximately 5e−3 V. The Hann+FFT results have reduced frequency leakage, with the noise floor dropping as low as for example 1e−9 around 200 Hz. However, there are frequency ranges, for example between 110 and 140 Hz, where the reported amplitude exceeds 1e−6V, arising from frequency leakage of large local components, for example at 123.5 Hz. The effect of spectral leakage is explored in this set of simulations via the relative amplitudes and (approximate) frequencies selected. For example, in FIG. 15B the component at 137.0 Hz, with amplitude of 1e−7 Hz, is ‘hidden’ by the spectral leakage from the 123.5 Hz component whichever of the two conventional FFT techniques is used. In the simulation, amplitudes vary from 1e0 down to 1e−9 in powers of 10, so that the impact of spectral leakage, along with the noise level, discussed next, can be assessed over a range of values.

A final source of error explored in the simulations is the standard deviation of white noise added to the pure sinusoidal components listed in Table 1. For example, in FIG. 17B, where the noise level is higher than for FIG. 15B, several of the signal components are lower than the FFT calculated noise floor and are therefore unlikely to be identified and calculated correctly. The relative importance of spectral leakage is also reduced with a higher noise floor. In order to explore the influence of noise on FFT and Prism spectral analysis, noise amplitudes are simulated with standard deviations ranging from 1e−10 up to 1e−1.

Given these various sources of error, a demonstration of the frequency and amplitude error properties of the FFT, and the comparable performance from the new Prism-based technique, is provided as follows: Nineteen different standard deviations of additive noise are considered, ranging from 1e−10 to 1e−1, where the noise is increased by a factor of \sqrt{10} at each step: thus 1e−10, 3.16e−10, 1e−9, . . . , 1e−1;

For each selected noise level, 20,000 simulations are carried out, where random variations are introduced to each simulation (as described below), in order to assess the distribution of frequency, amplitude and, where calculated, phase errors for each method. The well-known Root Mean Square Error (RMSE), calculated across all 20,000 simulations, is used to evaluate the measurement performance of each parameter for the given noise level.

For each individual simulation, certain parameters values are chosen from random distributions. Firstly, the particular frequency of each signal component is selected using the following procedure. Given the approximate frequency of each component listed in Table 1, the nearest exact frequency is calculated such that δ=0. Centred on that frequency, a range of frequencies is defined such that δ is in the range [−0.5, 0.5]. In this case, with the sampling rate fs=1000 Hz, and the data set length 3926 samples, this corresponds to a frequency range of i 0.127 Hz. For each simulation, the exact frequency of each component is selected from a uniform random distribution with this range, so that the corresponding value of 6 is randomly selected within the range [−0.5, 0.5]. As this procedure constitutes only a minor variation from each of the frequencies listed in Table 1, these approximate values remain convenient labels for discussing the local distribution of frequencies used across all simulations. Secondly, the initial phase of each signal component is randomly selected from the range [−π, +π], to ensure that results are not affected by any fixed phase relations between components. Finally, random white noise is generated independently for each simulation and added to the signal components to form the time series for analysis.

As stated above, the FFT does not identify spectral peaks, but calculates magnitudes/amplitudes along with other parameter values at regularly space frequency intervals. As cited in [4], a variety of techniques have been developed for improving peak estimation based on FFT data, however, there may be no generally accepted solution that is widely practiced across all applications. Here, in order to evaluate the performance of the FFT calculation itself, the FFT frequency value closest to the true component frequency (which varies randomly so that δ e [−0.5, 0.5]) is selected as the ‘peak’ value, together with its reported amplitude.

FIG. 18 shows the RMSE results obtained for amplitude using the Hann window+FFT technique, plotted against the white noise standard deviation, on a log-log scale. Different symbols are used to indicate the true component amplitudes which range from 1e0 to 1e−9; where more than one peak has the same amplitude (in Table 1, three peaks have amplitude 1e0 and two peaks have amplitude 1e−1) results are averaged across all such peaks. Results are only shown where the peak amplitude exceeds the noise amplitude by at least one order of magnitude. Accordingly, there is only one result for peak amplitude 1e−9 (where the noise amplitude is 1e−10), three results for peak amplitude 1e−8, and so on, up to the full complement of nineteen results for the maximum peak amplitude of 1e0.

The main characteristic of FIG. 18 is that the RMSE values are essentially constant for all levels of white noise, despite the noise amplitude ranging over ten orders of magnitude.

FIG. 19 provides further insight into the FFT amplitude results, by showing the amplitude RMSE scaled by the peak amplitude, i.e. the relative RMSE. All results with an amplitude greater than 1e−6 fall on the same line, with an approximate value of 0.5 (i.e. 50%) of amplitude, irrespective of the noise level. The particular scaling factor 0.5 found in these results is a function of various parameters, in particular the sample length of the FFT, and the particular windowing technique used in this case. As well understood by those familiar with the art, improved results may be obtained using more sophisticated FFT-related methods. However, the pattern of the results in FIG. 19 illustrates the over-riding influence of δ on the amplitude error of FFT [4]. Even with very low levels of white noise, the amplitude RMSE remains constant, as the main contribution to amplitude error arises from the randomly varying value of δ.

The results for the smaller amplitudes illustrate the problem of hidden peaks. It can be seen in FIG. 15B that even with a low level of white noise, the smaller peaks are hidden by spectral leakage from adjacent higher peaks, so that the reported peak amplitude is that of the local spectral leakage rather than of the true peak. Accordingly, in FIG. 19, the relative RMSEs for signal components with an amplitude less than 1e−6 are higher than 1 i.e. the average error is larger than the true value.

FIG. 20 shows the frequency RMSE for all experiments. It can be seen that this value is approximately constant, at around 0.0735 Hz, irrespective of noise and other factors. This value reflects the randomly selected value of δ, corresponding to a frequency range variation of ±0.127 Hz.

In summary, the application of the Hann window and FFT to determine peak frequency and amplitude values for sets of signals based around the components of Table 1 has demonstrated the significant influence of the (by default unknown) 6 parameter on the resulting error, along with, for smaller peak amplitudes, the impact of spectral leakage.

There follows a description and demonstration of how the Prism-based four convolution (P4C) technique, i.e. using the method 600, may be applied to the same simulation examples. This typically results in substantially reduced frequency and amplitude errors. There are at least two significant advantages of the new technique over current state-of-the-art FFT calculations. The first advantage is the suppression of spectral leakage by the stopband attenuation of a multi-layer Prism low pass filter. The second advantage is that the use of four convolutions together with the calculations of equations (9)-(13), result in a direct calculation of the frequency of a local peak, so that the true peak frequency and amplitude can be calculated, thus significantly reducing the errors associated with δ. Furthermore, in another instantiation, it is possible to combine P4C with the basic FFT procedure in order to advantageously obtain both the accuracy of P4C and the computational efficiency of FFT. In preferred examples, the FFT technique can be used in combination with only two of the four convolution functions.

In order to demonstrate application of the P4C technique of method 600 to the example specified in Table 1, the following example Prism characteristics are employed. Given the sample rate fc=1000 Hz, the selected value of m for the low pass filter is m=fc/160=6.25 Hz. The low pass filter peak is at approximately 0.4 m=2.5 Hz. With 160 samples per Prism integral length, (and recalling that each Prism consists of two consecutive integral stages), the 12 layer low pass filter has a nominal length of 3840 samples. The tracker Prisms employ m=5 Hz, so that r=0.5 at 2.5 Hz, close to the low pass filter peak frequency. Accordingly, the parallel Prism trackers have a length of 2×200 samples, so that the total length of the signal processing network formed from the concatenation of low pass filter and tracker (as illustrated in FIG. 12) is in this case 4240 samples. It will be appreciated that in general the Prism characteristics will be selected based on the intended application of the filter, as discussed above in relation to designing the filter systems. After generating the impulse response for the four filters (i.e. using method 400), values at the start and end with a magnitude below 1e−20 are truncated for a selected filter, resulting in a filter length of 3,926 samples. An identical truncation (in terms of sample start and end positions) is applied to the other three filters, so that all four filters have the same adjusted length. This filter length is the same as the data set length used in this example, so that convolutional calculations can be applied directly to the same data sets as used for the conventional FFT analysis.

As described above, the P4C calculation, absent any additional pre-processing, has the following effect on data sets generated to the specification of Table 1. All frequency components falling outside the range 0-m Hz will be attenuated by at least −313 dB, while the peak frequency occurring within this range will be calculated, along with its phase and amplitude. Given the peak frequencies listed in Table 1, all of these components fall outside of the passband range 0-m Hz and so will be attenuated, while the reported values of frequency phase and amplitude will be based on the noise characteristics falling within the passband. Accordingly, further processing steps are required to apply the P4C technique to provide a form of spectral analysis whereby all frequency components are detected. As outlined in [4], one means of achieving this is to use heterodyning to ‘shift’ a target frequency into the passband region of the P4C calculation. The systematic application of heterodyning over a range of frequencies, followed by the application of P4C to each heterodyned data set, may therefore be used to provide a useful spectral analysis of a data set, as outlined below.

Thus, in some examples of method 600, four convolutional filters are provided in step 601, each convolutional filter of the four convolutional filters generated using examples of method 400 which result in the convolutional filters providing a respective one of the outputs G_{c}¹, Gₛ¹, G_{c}² and Gₛ². Step 602 of applying each of the four convolutional filters then comprises heterodyning the input signal using a plurality of heterodyne frequencies selected based on a pass-band of the low-pass or band-pass Prism filter. In other words, multiple heterodyne steps are used to move all frequency components of the input signal into the pass-band of the convolutional filters. Each of the four convolutional filters is applied to the heterodyned input signal for each heterodyne frequency to generate the outputs G_{c}¹, Gₛ¹, G_{c}², and Gₛ² for each heterodyne frequency. Step 603 of generating an output indicative of a parameter of the input signal (e.g. amplitude, phase, and/or frequency) then comprises generating the indicative output of the heterodyned input signal for each heterodyne frequency based on the outputs G_{c}¹, Gₛ¹, G_{c}², and Gₛ² generated for that heterodyne frequency.

As noted further below, further advantages can be achieved by using the FFT calculation itself as a means of providing systematic heterodyning, when suitably combined with P4C or a subset thereof.

Heterodyning is a technique, well known to those familiar with the art, used as a means of applying a frequency shift to a signal. In one instantiation, heterodyning is applied to a sinusoid of frequency f₁ in order to effect a shift to frequency f₂ by means of multiplication by a sinusoid of frequency fₕ=f₁−f₂. Given the original signal, s(t):

$$s ( t ) = A sin ( 2 π {f}_{1} t ) \qquad Equation ( 14 )$$

A heterodyning signal h(t) may be constructed:

$$h ( t ) = sin ( 2 π {f}_{h} t ) \qquad Equation ( 15 )$$

such that the product term p(t) has a component at the desired frequency f₂:

$$p ( t ) = s ( t ) \cdot h ( t ) = \frac{A}{2} [ cos ( 2 π {f}_{2} t ) - cos ( 2 π [ {f}_{h} + {f}_{1} ] t ) ] \qquad Equation ( 16 )$$

Heterodyning introduces a number of additional signal properties, which may be taken into account during subsequent signal processing, for example the following. A second sinusoidal term is generated with frequency (fₕ+f₁). In some examples, this term may be filtered out, for example by the application of a filter with low stopband attenuation. The amplitude of the signal at the desired frequency, f₂, is only half that of the original signal, which is readily compensated. A further change is that a π/2 phase shift is introduced, indicated by the substitution of sine with cosine between Equations (14) and (16). More detailed consideration of the phase relationships between the original [s(t)], heterodyning [h(t)], and product signal [p(t)], are well understood by those familiar with the art, so that, for example, it is possible to recover the phase of the original signal if the phase of the heterodyning signal and that of the desired f₂ term in the product signal are known or calculated.

FIG. 21 provides a schematic illustration of how heterodyning may be applied to enable the P4C method to be applied to target an arbitrary frequency, i.e. how to apply the P4C filtering and tracking to be centred on the target frequency, say fₜ, instead of at the designed filter peak frequency (fₚ, in this example 2.5 Hz). Given the original data set and fₜ, a heterodyning time series is constructed with frequency fₕ=fₜ−fₚ. The sample-by-sample product of the heterodyning signal and the original data set create a frequency-shifted (“heterodyned”) data set where a signal component originally in the near vicinity of f₁ is shifted to be close to fₚ. The heterodyned data set is passed to the P4C method, where any component close to fₚ will be tracked by the P4C technique. Finally, heterodyne corrections to amplitude, frequency and phase may be applied to recover the characteristics of the original component fₜ. For example, heterodyne correction may comprise mapping values of frequency based on the heterodyne frequency to retrieve values corresponding to the original input signal, and similar for amplitude and phase corrections. For example, for the case of 100 Hz target frequency described above, the heterodyne frequency is 97.5 Hz, so that any component around 100 Hz is shifted to be in the vicinity of the filter peak around 2.5 Hz. If the tracked frequency is 2.45 Hz, then heterodyning compensation means adding back the 97.5 Hz to get an estimated peak of 99.95 Hz in the original signal.

The procedure of FIG. 21 (and method 600 in heterodyning examples) may be applied on an ad-hoc basis for specific frequencies, and/or applied systematically across a range of target frequencies in order to provide a spectral analysis. For example, for this simulation, target frequencies of 0 to 500 Hz might be applied in steps of 0.254 Hz (thus matching the steps of the corresponding FFT). For each target frequency, heterodyning may be applied to the data set to map the target frequency to the filter peak frequency. For example, for a target frequency of 100 Hz, and with the passband peak frequency at 2.5 Hz, a heterodyning signal of 97.5 Hz may be applied to the data set before applying the P4C method as described above. A second heterodyning component is created at 197.5 Hz, but this is readily attenuated by the low pass filtering centred on the peak frequency of 2.5 Hz. The calculated values of peak frequency, amplitude and phase may then be corrected for the effects of heterodyning and recorded for each target frequency. As discussed below, further processing may be required to identify true spectral peaks.

However, an alternative and more efficient instantiation of P4C spectral analysis reformulates the calculation to take advantage of the computational efficiency of the FFT. As stated above in the quotation from [4], for a data set of length N samples, the FFT calculation has computational cost of order N log(N). By contrast the procedure of FIG. 21 is of order N for a single target frequency; to replicate FFT's results for N frequency values would require a computational load of order N². Accordingly, it is computationally advantageous if the procedure of FIG. 21 can be reformulated, assuming N equally spaced target frequencies, to apply some version of the FFT calculation itself. This can be carried out in the following manner.

Given the earlier descriptions of convolution (e.g. Eqn. 8), and of heterodyning (Eqn. 16), it is readily seen that, in FIG. 21, the value of Gₛ¹ for the j^{th} target frequency is calculated as follows:

$${G}_{s}^{1} ( i ) = {\sum }_{i = 1}^{N} {x}_{i} \cdot {h}_{ij} \cdot {c}_{i} \qquad Equation ( 17 )$$

where xᵢ is the i^{th} value in the data set, hᵢⱼ is the e^{th} value of the heterodyning signal for the j^{th} target frequency, and cᵢ is the i^{th} value in the convolutional filter value for Gₛ¹. Equivalent calculations are used for G_{c}¹, Gₛ², and G_{c}², where the only change is the convolution filter applied. Note that the product xᵢ. cᵢ is unchanged for all target frequencies. This suggests an alternative formulation, where the convolutional filters for Gₛ¹ and the other functions are treated as window functions for the data set. Thus:

$$for i = 1 , N {prod}_{i} = {x}_{i} \cdot {c}_{i} \qquad Equation ( 18 )$$

$$then$$

$${G}_{s}^{1} ( j ) = {\sum }_{i = 1}^{N} {prod}_{i} \cdot {h}_{ij} \qquad Equation ( 19 )$$

where Equation 18 is equivalent to applying the Gₛ¹ convolutional filter as a windowing function to the data set, and equation 19 describes a set of regularly spaced DFT calculations applied to the product set, which can be implemented efficiently using the FFT algorithm, provided as the imaginary components (the “sine” terms) of the FFT result.

Accordingly, in some examples of method 600, step 602 further comprises applying a Fourier transform algorithm (e.g. FFT algorithm) to the output of each convolutional filter of the two or more convolutional filters to generate the outputs G_{c}¹, Gₛ¹, G_{c}², and Gₛ². This process can use all four of the G4C convolutional filters. Advantageously, however, the properties of the Fourier transform can be used to generate the functional equivalent of all four outputs G_{c}¹, Gₛ¹, G_{c}², and Gₛ² from just two convolutional filters. In particular, only two sine convolutional filters may be used; or only the two cosine convolutional filters may be used.

This concept is illustrated in FIGS. 22A and 22B. FIG. 22A shows the result of multiplying each point in the Gₛ¹ window (i.e. the Gₛ¹ impulse response, plotted in FIG. 13A), by the corresponding point in a simulated data set, with white noise standard deviation 1e−10V (FIG. 15A). The equivalent plots for the Hann window are FIG. 16A (compare FIG. 13A), and FIG. 16B (compare with FIG. 22A). FIG. 22B shows the result of applying the standard FFT calculation to the Gₛ¹ windowed data of FIG. 22A, along with the previously described FFT and Hann+FFT windows. Circles mark the true frequency and amplitude of each signal component.

The Gₛ¹ spectrum in FIG. 22B consists of a series of double peaks with a low noise floor. Each peak in the spectrum has approximately the same narrow width (compare with the much broader and varying widths of the FFT and Hann+FFT spectra), and outside of peak regions the noise floor is fairly constant and, at approximately 1e−11, is significantly lower than those of the other two spectra. Each true peak (circle) has two adjacent Gₛ¹+FFT peaks, equally spaced on either side. Some additional, spurious peak pairs with low amplitude occur, for example around 220 Hz. The x-axis is labelled “Interrogation and Actual Frequency” for the following reasons. The true peaks and the peaks for the FFT and Hann+FFT spectra are plotted at their actual frequencies along the x-axis. However, as the Gₛ¹+FFT spectrum is calculated using a heterodyning frequency (h; in Equation 19), there is an offset between the nominal frequency used in the FFT calculation and the ‘true’ frequency of any observed peak. This may be termed the interrogation frequency, as the Gₛ¹ product data set (Equation 18) can be considered as being “interrogated” at a series of frequencies (Equation 19) while producing amplitude and other parameter data at a frequency offset from the interrogation frequency, due to the heterodyning effect.

This frequency offset also explains the double peak characteristic in FIG. 22B, as illustrated in FIGS. 23A and 23B. Those familiar with the art will be aware of the concept of “negative frequency”, and its impact when combined with heterodyning. FIG. 23A shows the frequency response of a 12 layer low pass filter, similar to that of FIG. 7A, except that the frequency scale has been generalized in two ways. Firstly, while in FIG. 7A, the characteristic frequency m is set to 1 Hz, by contrast in FIG. 23A, the characteristic frequency remains unspecified and is labelled as m on the x (frequency) axis. Secondly, in FIG. 23A, the x axis has been extended into the negative frequency domain, where, as is well understood by those familiar with the art, the frequency response of the filter is equal to that of the equivalent positive frequency. Thus a filter with pass band of [0, m] Hz, also has a negative pass band of [−m, 0] Hz, where, for example, the 0 dB maximum gain at 0.4m Hz is reflected at −0.4m Hz. As is also well known to those familiar with the art, there are no practical consequences arising from a nominal negative frequency response which is symmetric about zero Hz. However, FIG. 23B illustrates the effect of applying a heterodyne of frequency fₕ to the frequency response of FIG. 23A: this results in two effective pass bands of [fₕ,fₕ+m] and [h−m,fₕ]. Accordingly, using FFT as a means of generating regularly spaced heterodynes after applying this windowing function, may result in a single true frequency component appearing twice, once corresponding to the positive pass band, and once corresponding to the negative pass band. Neither double peaks nor frequency offsets occur for conventional FFT windowing functions such as the Hann window of FIG. 16A, because the peak frequency response gain is at 0 Hz. This property arises because the Hann and other conventional FFT windowing functions have a non-zero mean value—the mean value of the Hann window in FIG. 16A is 0.5, whereas the mean value of the Gs1 window of FIG. 13A is zero. Accordingly, if the conventional FFT process is viewed as a sequence of heterodynes and summations (equivalent to Equation 19), heterodyning the Hann window will create only a single peak centred on the heterodyne frequency, so that the double peak and frequency offset phenomena shown in FIG. 23 do not occur. Methods for identifying and managing the double peaks and frequency offsets are described below.

After the four FFT results have been calculated for each of the windowing functions Gs1, Gc1, Gs2, Gc2, the values of amplitude and r may be calculated for each interrogation frequency value, using equations 9-12.

FIG. 24 shows the results obtained for the dimensionless frequency r (FIG. 24A), and the amplitude (FIG. 24B, previously shown in FIG. 22B), for a reduced range of interrogation frequencies between 234 Hz and 248 Hz, where a single true frequency component occurs close to 240.0 Hz with an amplitude of 1e−3 V (Table 1). Considering first the amplitude behavior in FIG. 24B, as the interrogation frequency increases from 234 Hz, the amplitude remains low until the true peak at 240 Hz, after heterodyning, enters the positive passband of the P4C filter. The amplitude reached a maximum of approximately 1e−3 V as the interrogation frequency reached 237.5 Hz (i.e. the difference between the true peak 240 Hz and the P4C window peak of 2.5 Hz). As the interrogation frequency continues to rise, the peak at 240 Hz, after heterodyning, enters the negative passband of the P4C filter, reaching a maximum of approximately 1e−3 V as the interrogation peak is at 242.5 Hz.

FIG. 24A shows the corresponding values of the dimensionless frequency r. In the absence of any true peak within the passband, (which is clearly signified by a low amplitude at the corresponding interrogation frequency in FIG. 24B), the r value exhibits random variation. Once a true peak is within the positive passband, r exhibits linear variation with negative slope as the interrogation frequency increases; with a peak in the negative passband region, r exhibits linear variation with positive slope as the interrogation frequency increases. The value of r allows an estimate of the local peak value to be calculated, while its slope behaviour—negative or positive—indicates whether the peak arises from the positive or negative passband region.

FIGS. 25A and 25B show the calculated values of the peak frequency, and the corresponding error, respectively, for the same range of interrogation frequencies, based on the value of r and its sloping behavior, as follows:

$${f}_{est} = {f}_{h} + 0.8 rm for positive passband peaks \qquad Equation ( 20 )$$

$${f}_{est} = {f}_{h} - 0.8 rm , for negative passband peaks \qquad Equation ( 21 )$$

where fₑₛₜ is the estimated true peak frequency, and fₕ is the heterodyning frequency used for the current interrogation frequency.

It can be seen that for any interrogation frequency where the 240 Hz peak, after heterodyning, falls within the passband of the P4C method, the peak frequency is estimated well (errors<1e−3 Hz), with very low errors (˜1e−10 Hz) where the interrogation frequency is very close to the true peak, which is also associated with an r value close to 0.5 (FIG. 25A).

The capability of the P4C method to accurately estimate the true peak frequency over a reasonably wide range of interrogation frequencies, provides a significant advantage over state-of-the-art FFT techniques. This is coupled with the high attenuation of all signal components not within the heterodyned passband, to minimize spectral leakage and its associated errors.

In the second stage of the P4C method, candidate peak frequencies may be identified, based on the sweep values obtained in the first stage. Selection criteria may include an amplitude threshold, whether a peak has been identified as positive or negative (to avoiding duplicating peaks), and whether it has an r value close to 0.5 (where the filter has been designed to provide the optimal value of r=0.5, as described above). For example, in FIGS. 25A, several consecutive interrogation frequencies estimate a peak close to 240 Hz, but the lowest error is associated with r close to 0.5. Note also that although many of the frequency estimates may be considered reasonably accurate, the corresponding values of amplitude (FIG. 25B) vary by many orders of magnitude, arising from the frequency response characteristic of the low pass filter as it moves away from the peak value (FIG. 7), so that values with r close to 0.5 are preferred. As FIG. 25A illustrates, values of r close to 0.5 may be randomly generated away from true peaks, and so a combination of an amplitude threshold, r value, and negative peak removal, may be required to identify candidate peak frequencies, as will be appreciated by the skilled person.

Where there is very low noise, it is possible for false peak pairs to arise, from ‘echoes’ of large peaks. This is illustrated in FIG. 22B, where a total of 18 peak pairs may be identified as rising above the noise floor, while Table 1 lists only 13 peaks. False peak pairs may occur at the complement of the Nyquist frequency of major peaks. Here, the Nyqusit frequency is fs/2=500 Hz. The very low peak pair occurring at around 450 Hz in FIG. 22B, arises as a reflection of the high amplitude peak pair occurring at 50 Hz (450=500-50). Such false peak pairs can be identified and removed by checking complementary frequencies of the identified peaks in amplitude order.

Having identified a set of estimated peak frequencies, a third stage may obtain refined results by repeating the P4C process, targeting only the estimated frequencies. This should ensure accurate estimates of amplitude and phase are obtained.

Accordingly, method 400 may further comprise the steps following steps (i) to (iii).
(i) Estimating frequencies of peaks in the generated amplitude, frequency and/or phase (i.e. using either the pure heterodyne approach, or the FFT approach described above). Estimating frequencies of peaks may comprise applying a selection criteria to the output of the heterodyne/FFT process. For example, the selection criteria may comprise one or more of: an amplitude threshold (i.e. identifying components with an amplitude above the threshold as a peak); a threshold proximity to a selected value of r, e.g. r=0.5; and a frequency threshold (i.e. selecting only frequencies below the frequency threshold).
(ii) Reapplying each of the two or more convolutional filters to the input signal based on the estimated peak frequencies to generate updated values for the output indicative of the parameter/s of the input signal (e.g. amplitude, frequency and/or phase). This step comprises first heterodyning the input signal using heterodyne frequencies corresponding to each of the estimated peak frequencies. Second, each of the two or more convolutional filters is applied to the heterodyned input signal for each heterodyne frequency corresponding to an estimated peak frequency to generate the outputs G_{c}¹, Gₛ¹, G_{c}², and Gₛ² for each heterodyne frequency.
(iii) Generating updated values for the output indicative of the parameter/s (e.g. amplitude, frequency and/or phase) of the heterodyned input signal for each heterodyne frequency corresponding to an estimated peak frequency based on the outputs G_{c}¹, Gₛ¹, G_{c}², and Gₛ² generated for that heterodyne frequency.

The final output of the P4C process may therefore be a list of peak frequencies (i.e. frequencies of peaks in the input signal), amplitudes and/or phases, together with other parameters extracted from the calculation, for example an estimate of the noise floor based on amplitude values remote from any peak. The final result may be represented graphically as shown in FIG. 26. Vertical lines indicate the frequency and amplitude of each identified peak. The noise floor is shown for frequency regions which are sufficiently remote from any identified peak that an unbiased estimate is possible. Other representations of the noise floor, for example a horizontal line at the average noise floor level, might also be used. As will be seen in the reported example results which follow, the resulting peak frequency and amplitude estimates have low errors. The true peak values are identified by circles, while the FFT and Hann+FFT results are reproduced in FIG. 26 for comparison purposes. As illustrated by these results, the present method is able to identify peaks that were obscured by frequency leakage in the FFT and Hann+FFT results.

FIG. 27 schematically summarises an example implementation of the P4C+FFT technique for spectral analysis as follows. The data vector (i.e. input signal) to be analysed is multiplied sample by sample by each of the P4C windows (Gs1, Gc1, Gs2, Gc2, e.g. as illustrated in FIGS. 13A and 14A). The FFT procedure is applied to each of the four product vectors, which calculated the imaginary (sine component) value at each frequency step. From these four sets of results, for each interrogation frequency, the values of amplitude and r are calculated (equations 9-12). Based on these values, for example by using a minimum threshold for amplitude and selecting r values within a limited range around a central value of 0.5, together with the application of equations (20) and (21), approximate peak frequencies are identified. For these peak frequency values only, the calculation is repeated using the same P4C product vectors where for each target frequency and appropriate heterodyning vector is calculated.

Yet simpler and preferred examples, which have reduced computational requirements but may generate equivalent numerical results to P4C+FFT, are as follows. As is well known to those familiar to the art, a typical FFT computation will generate both real and imaginary components, corresponding to cosine and sine Discrete Fourier Transforms respectively, from which, for example amplitude and phase estimates can be derived. In the method of FIG. 27, only the imaginary component from the FFT calculation is used. By reformulating the PC4-FFT calculation, both the real and imaginary components of the FFT can be used via the resulting FFT derived calculations of phase and amplitude. As a consequence, the requirement for using Gc1 and Gc2 can be removed, so that only two Prism-based windowing functions, Gs1 and Gs2, are required (or vice versa). The resulting calculation (denoted here P2C+FFT) is more efficient, requiring only two FFT calculations, and leads to a simplification of the mathematical formulation. The simplified calculation is as follows:
Step 1: Apply the two convolutional filters to the input data. This calculates product vectors for Gs1 and Gs2 only (Equation 18).
Step 2: Calculate FFTs for Gs1 and Gs2 data vectors.
Step 3: Calculate the FFT amplitude for Gs1 and Gs2 data vectors, denoted as A1 and A2 respectively.
Step 4: For each FFT frequency calculate the amplitude ratio:

$$x = \frac{A 1}{A 2} \qquad Equation ( 22 )$$

Step 5: The estimated value of r, may then be derived using:

$$r = \sqrt{\frac{4 x - 1}{x - 1}} \qquad Equation ( 23 )$$

Step 6: The estimated value of the component amplitude is given by

$$A = K * A 1 \qquad Equation ( 24 )$$

$$where K = {[ \frac{π}{sin ( π r )} ]}^{2} [ 1 - {r}^{2} ] , \qquad Equation ( 25 )$$

Step 7: the component phase is given by the conventional FFT phase of the Gs1 product vector.
Step 8: identify peak frequencies; and rework calculations targeting these peak frequencies.

FIG. 28 shows a revised version of FIG. 27 that applies the P2C calculation. Note that when heterodyning vectors are calculated for selected peak frequencies, both sine and cosine vectors are used, as follows. Given estimated data peak frequency fₜ, and the low pass filter peak frequency fₚ, the desired heterodyning frequency may be fₕ=fₜ−fₜₚ, (alternatively, fₕ=fₜ+fₜₚ, may be used). Two orthogonal heterodyning signals hₛ(t) and h_{c}(t) are constructed:

$${h}_{s} ( {t}_{i} ) = sin ( 2 π {f}_{h} {t}_{i} ) \qquad Equation ( 26 )$$

$$and$$

$${h}_{c} ( {t}_{i} ) = cos ( 2 π {f}_{h} {t}_{i} ) \qquad Equation ( 27 )$$

for discrete timesteps tᵢ corresponding to the sample points in the data window.

These heterodyne signals are convoluted with the Gs1 product window:

$${z}_{s} = {\sum }_{i = 1}^{N} {prod}_{i} \cdot {h}_{s} ( {t}_{i} ) \qquad Equation ( 28 )$$

$${z}_{c} = {\sum }_{i = 1}^{N} {prod}_{i} \cdot {h}_{c} ( {t}_{i} ) \qquad Equation ( 29 )$$

The amplitude A1 is given by the root-sum-square of z, and zc while the phase is calculated from the arctangent of their ratio. A similar calculation using the Gs2 product window yields the value of A2.

The simulation study generating the FFT results shown in FIGS. 18-20 was extended to evaluate the corresponding performance of the P4C and PC2 techniques. Note that exactly the same data were used in each case, whereby each randomly generated data set (as specified above) was analysed first with FFT and then with P2C. Note also that the results for P4C and P2C are essentially identical, and all results shown are for the preferred technique of P2C.

The performance of the P2C method for this example can be summarized as follows: unlike the conventional FFT methods, the technique shows little or no error sensitivity to small variations in frequency. The primary source of error is the signal to noise ratio, as measured for example by the ratio between the true peak amplitude and the white noise standard deviation. For high signal-to-noise ratios, very low RMSEs are achieved for frequency, phase and amplitude estimates. In some cases, for the same simulated conditions, the Han-FFT RMSE for amplitude and/or frequency is more than one billion times larger than the corresponding P2C-FFT RMSE.

FIG. 29 shows the P2C RMSE errors for amplitude. For comparison purposes, included in the plot are the Hann-FFT results for peak amplitude IV only. The P2C results exhibit a clear linear relationship between the white noise standard deviation and the resulting amplitude RMSE. Note that this relationship is almost entirely independent of the peak amplitude itself. The only variations from linearity occur for the highest peak amplitudes (1e0, 1e−1) combined with the lowest levels of white noise, where there appears to be an absolute precision floor of approximately 1 part per 1 billion i.e. there is an accuracy limit of approximately 9 significant digits. By contrast, the Han-FFT RMSE is constant at around 0.5 for all noise levels, and is several orders larger than all the P2C results.

FIG. 30 shows the P2C RMSE errors for amplitude, scaled by amplitude i.e. the relative RMSE. The Hann-FFT results, shown in full in FIG. 19, exhibit a relative RMSE of approximately 0.5 VN. By contrast the minimum relative RMSE for P2C is approximately 7e−10 VN.

FIG. 31 shows the RMSE frequency error for the P2C technique. The Hann-FFT value is approximately constant at around 0.07 Hz, while for the P2C technique the frequency RMSE never exceeds 2e−3 Hz, and for highest amplitude and lowest noise simulations drops to approximately 3e−11 Hz.

FIG. 32 demonstrates that the signal/noise ratio (i.e. peak amplitude/noise standard deviation) is the main determining factor for the frequency RMSE, which is shown scaled by peak amplitude. This shows a linear relationship against the noise level for all peak amplitudes, with once again a precision limit reached for the highest amplitude and lowest noise.

A very similar pattern is observed for the RMSE for phase, shown in FIGS. 33 and 34. Here, the initial phase for the corresponding frequency component (generated at random in each simulation), is calculated, based on the P2C phase result and the heterodyning phase record. The results are linear with the signal/noise ratio, and exhibit a precision limit.

Accordingly the P2C method has demonstrated substantial error reduction compared to the conventional Hann-FFT technique, for limited additional computation: principally two windowed FFT calculations are performed with P2C instead of one for Hann-FFT.

### Dynamic Heterodyning and Amplitude Normalisation

As well understood by those familiar with the art, there is a general tradeoff, in the design and implementation of filtering and tracking systems, between achieving good noise suppression, for example through narrowband filtering, and successfully tracking dynamic change in the signal component of interest, for example a rapid step in amplitude or frequency. The issue may arise, for example, when monitoring a resonant sensor, such as a Coriolis mass flow meter, which generally produces signals with stable amplitude and frequency characteristics, but which during transitions (for example draining or filling of the sensor with liquid) may exhibit rapid changes in both amplitude and frequency. A filter which is strong enough to suppress noise may generate significant errors in frequency, amplitude or phase calculations during fast dynamic change of the true signal. Accordingly, a new technique is disclosed which uses the simple and robust FIR Prism structure to track rapid dynamic change using means that are model free, which avoid feedback, and which are generally numerically stable. The assumption here is that there is a single signal component, typically with a known and limited range of frequency and/or amplitude variation, which is to be tracked.

FIG. 35A illustrates a method 700 of estimating characteristics of an input signal that can be used to provide good noise suppression in combination with tracking of dynamic changes. Method 700 can be used to determine (e.g. estimate) one or more of amplitude, frequency, and phase of the input signal, or at selected time steps (e.g. all time steps/samples, or a sub-set of time steps/samples) within the input signal. Method 700 may be performed using a signal characterisation device 800 for estimating characteristics of an input signal, such as that shown in FIG. 35B. Signal characterisation device 800 comprises a first tracker 801, and a second tracker 802, as described further below. Signal characterisation device 800 further comprises a control unit 803. The control unit 801 is configured to perform the method 700. It is to be appreciated that although the first and second trackers 801, 802 are described as generating the respective estimates, in some examples the first/second trackers may generate the ‘G’ values discussed above. These ‘G’ values can then be processed by the control unit 803, or other component, to derive the estimate of the characteristics using the calculations described above.

Method 700 starts at step 701, at which the input signal the input signal s(t) is input into the first tracker 801. The first tracker 801 is configured to determine a first estimate of the characteristics of the input signal s(t). The first estimate comprises a first amplitude estimate and/or a first frequency estimate. The first tracker 801 is a Prism-based tracker. That is, the tracker 801 may comprise and/or be derived from one or more Prism filters, such as Prism 100. The first tracker 801 may include a filtering component, such as a low pass filter, in combination with a tracking component. As such, first tracker 801 may comprise any of the examples of filter system 500. Alternatively tracker 801 may consist only of a tracker component, without a separate filtering stage. In general tracker 801 may comprise or be derived from any of the filters described herein. In particular, tracker 801 (or a filtering component thereof) may be or be derived from any example of the filter system 200. Tracker 801 (or a filtering component thereof) may be convolutional filter derived from a Prism filter or Prism filter network. The convolutional filter may be generated using any example of method 400. Where the tracker 801 is a convolutional filter, the convolutional filter outputs the first estimate (or the ‘G’ values that can be used to calculate estimates of the characteristics using the equations discussed above). As such, inputting the input signal into the first tracker 801 may comprise performing any example of method 600 discussed above. In alternative examples only a filtering component of tracker 801 is a convolutional filter. In such cases the tracker component is an instantiation of one or more Prism filters 100 arranged to generate the ‘G’ outputs discussed above.

In general, the first tracker 801 has relatively fast dynamics (i.e it is a wide pass band). The first tracker 801 establishes an approximate amplitude and/or frequency of the desired component within the input signal.

Once the first estimate of characteristics has been determined, the method 700 moves on to step 702. At step 702, a normalised signal is determined from the input signal. The aim of step 702 is to reduce the dynamic variation of the component in the original input signal.

In some examples, the normalised signal is determined by normalising the amplitude of the input signal using the first amplitude estimate. For example, each sample of the original signal is divided by the estimated component amplitude for that sample from the first stage tracker (allowing for fixed delay, avoiding division by zero, and applying other safeguards as well known to those familiar with the art). This may result in significantly reduced amplitude variation for the signal component supplied to the second tracker 802, as the nominal amplitude is 1.0, so that deviations from 1.0 in the amplitude estimated by the second tracker 802 (discussed below) may acts as corrections to the first stage amplitude estimate, arising from improved noise filtering and/or reduced amplitude dynamics. Where convenient, an alternative value to 1.0 may be used as the nominal amplitude.

Alternatively or additionally, determining the normalised signal may comprise heterodyning the input signal s(t) using a heterodyne frequency determined based on a sum and/or difference between the first frequency estimate and a filter frequency. The filter frequency is a frequency in the passband of the second tracker 802. For example the filter frequency may be the centre of the passband, or the frequency at which the signal attenuation induced by the second tracker 802 is a minimum. Here, the original input signal is heterodyned to match a desired frequency. The heterodyning frequency can be varied sample by sample based on the frequency estimate from the first stage (assuming a respective first frequency estimate is determined for each sample in the input signal, after an initial delay due to the length of the first tracker 801). As such, the heterodyning may be considered a dynamic heterodyning. As a consequence, the second tracker 802 may receive a signal where the component to be tracked has reduced frequency variation. Once the normalised signal is determined, the method 700 proceeds step 703. At step 703, the normalised signal is input into the second tracker 802 to determine a second estimate of characteristics of the input signal. The second tracker 802 is configured to pass a narrower range of frequencies than the first tracker 801. As such, the second tracker 802 rejects more noise than the first tracker 801.

The second tracker 802 is a Prism-based tracker, similarly to first tracker 801. Any of the examples of Prism filter discussed above with respect to first tracker 801 may be used as the second tracker 802. In particular examples, the form of the network of Prism filters of which the second tracker 802 comprises or is derived is the same as that of the first tracker 801. Thus, for example, both trackers 801, 802 may comprise or be derived from networks of Prism filters with the same number of cosine sets and sine sets, and/or the same number of cosine/sine Prisms in the cosine/sine sets. As will be appreciated from the discussion of Prism filter 100 above, the different passband widths of the first tracker 801 and second tracker 802 can be set by the their respective values of characteristic frequency, m. The characteristic frequency m₁ of the first tracker 801 is larger than the characteristic frequency m₂ of the second tracker 802. In particular examples, the value of m is at least 1.5 times, or at least 10 times, or at least 20 times, or at least 50 times, or at least 100 times smaller than the value of m₁. The absolute value of m₁ and m₂ (or generally the characteristic frequency used in any example) will depend on the nature of the input signal. In some examples herein, the value of the characteristic frequency or frequencies may be in the range 0.01 Hz to 200 MHz.

The outputs of the second tracker 802, providing characteristic information of the normalised signal, can be used to generate the second estimates of the characteristics of the input signal. For example, the second estimates may be derived from the outputs of the second tracker 802 based on the amplitudes and/or heterodyne frequencies used to generate the normalised signal. Alternatively, the outputs of the second tracker 802 can be combined with the first estimates to derive the second estimates. Accordingly, the second tracker 802 amplitude estimate may be combined with the first amplitude estimate to give a best estimate for the original input signal, for example by calculating the product of the amplitude estimates from the first and second trackers 801, 802, while accounting for the respective digital delays in each tracker 801, 802. The frequency and phase estimated by the second tracker 802 may be combined with the recorded heterodyning frequency and phases (compensated for time delay) to generate improved estimates of the phase and frequency of the original signal.

The amplitude and/or frequency normalisation at step 702 are preferably performed on each of a plurality of samples in the input signal. In particular, the normalisations are preferably performed on each and every sample in the input signal, except for an initial set of samples for which no first estimates are generated due to the length of the first tracker. In other words, there is a delay between the start of the input signal, and the time at which normalised signals begin to be generated. In general two sorts of delay are possible: the calculation delay; and the response delay. Assume that the compute engine is powerful enough for the arithmetic to cause negligible additional delay compared to the time between each received sample. Then, the calculation delay for any Prism structure is simply its total length times the period between each sample, i.e. the total duration of the (entire) data window. If the Prism structure include a tracker as the final stage, then freq/amp/phase values are calculated. These values correspond in time to the midpoint of the data window, as they are linear time averages. Accordingly, in the arrangement shown in FIG. 35A, there is an initial delay for the duration corresponding to the length of the first tracker to obtain the first estimates of frequency and amplitude, but thereafter amplitude and/or frequency normalisations are applied to the original raw data, at the time point corresponding to the mid-point of the first stage data window. To illustrate this principle, consider the following example. A first tracker 801 (consisting of both low pass filter and tracker) has length 200 samples, and a second tracker 802 has 400 samples. A raw data stream is processed. After 200 samples, the first tracker 801 produces its first output. These correspond to estimates of amplitude and frequency for sample no. 100 (i.e. half way through the first tracker data set). So, sample no 100 becomes the first sample used in the normalised signal input to the second tracker 802, with associated amplitude and frequency estimates produced by the first tracker 801 after it has finished with sample 200.

Thereafter, the first tracker 801 produces a new estimate every sample, and the second tracker 802 receives a new sample, whereby the first amplitude/frequency estimates used in the normalised signal provided to the second tracker 802 are the latest outputs from the first tracker 801, but the corresponding raw data is 100 samples behind.

The combination of amplitude normalisation and dynamic frequency heterodyning can be termed “I40”, referencing Isaiah Chapter 40-“Every valley shall be lifted up, and every mountain shall be made low”—as this describes the transformations applied between the first tracker 801 the second tracker 802 in order to facilitate improved signal tracking. This technique is simple, requires no modelling or feedback, and may deliver good tracking of dynamically varying signals.

FIG. 35C schematically illustrates an example implementation of the method 700. FIGS. 36-38 shows the results of a simulation which demonstrate the merits of the method 700. In this simulation, a signal is sampled using fs=10 kHz, where the signal consists of a single component plus additive noise. The signal component frequency has a mean value of 500 Hz, but this frequency changes over time, oscillating between 498 Hz and 502 Hz twice every second, as illustrated by the true frequency plot in FIGS. 36A, 37A, and 38A. Similarly, the amplitude of the component varies sinusoidally between 0.4 V and 0.6 V three times every second, as illustrated by the true amplitude plot in FIGS. 36C, 37C, and 38C. White noise is added to the signal component with a standard deviation of 1 mV.

Two Prism based trackers are used to generate results, each consisting of a 6 layer low-pass filtering component of the type illustrated in FIG. 4B, followed by a tracking component, in an arrangement corresponding to FIG. 11. A first tracker 801 uses m=50 Hz, while a second tracker 802 uses m=25 Hz. Accordingly, the first tracker 801 has a faster dynamic response, but the second tracker 802 has improved noise suppression via a more narrow passband.

Results for three different tracking strategies are illustrated in FIGS. 36-38, as discussed below in more detail. FIG. 36 shows the results of applying the first tracker 801 alone, while FIG. 37 shows the results of applying the second tracker 802 alone to the original signal. Note that for both of these cases fixed frequency heterodyning is used to map the average input frequency 500 Hz to the peak frequency of the corresponding low pass filter (50 Hz for first tracker 801, and 25 Hz for second tracker 802). FIG. 38 shows the results of applying method 700 in the arrangement of FIG. 35C, where the outputs of the first tracker 801 are used to improve the performance of the second tracker 802 via amplitude normalization and dynamic heterodyning.

FIGS. 36A, 36B, 36C and 36D show the tracking results obtained when applying the first tracker 801 to the input signal. FIG. 36A shows the true and tracked frequency, while FIG. 36B shows the corresponding frequency error, which has a root mean square error (RMSE) of 3.24e−2 Hz. Note that these plots include compensation for the fixed time delay associated with the tracking and filtering process, which corresponds to 680 samples, or 68 ms. Note also that for convenience the nominal start time is set to zero, and the filter warmup results are not shown. FIG. 36C shows the true and calculated value of the component amplitude, while FIG. 36D shows the corresponding amplitude error with RMSE=2.34e−3 V.

FIGS. 37A, 37B, 37C and 37D show the tracking results obtained when applying the second tracker 802 directly to the original input signal. FIG. 37A shows the true and tracked frequency, while FIG. 37B shows the corresponding frequency error, which has a root mean square error (RMSE) of 9.56e−2 Hz, approximately three times larger than the first tracker 801 result shown in FIG. 36B. FIG. 37C shows the true and calculated value of the component amplitude. FIG. 37D shows the corresponding amplitude error with RMSE=9.64e−3 V, approximately four times larger than the first tracker 801 result shown in FIG. 36D. These plots include compensation for the fixed time delay associated with the tracking and filtering process, which for the second tracker 802 corresponds to 1423 samples, or 142.3 ms.

FIGS. 38A, 38B, 38C and 38D show the tracking results obtained when applying the method 700, in the arrangement of FIG. 35C, using the same structures for the trackers 801, 802. In this approach, the amplitude and frequency results from the first tracker 801 (as illustrated in FIG. 36) are used as the basis for the application of dynamic heterodyning and amplitude normalization, to generate the normalized signal. The smoothed data of the normalized signal is presented to the second tracker 802, and the estimates combine the results from the two trackers 801, 802. FIG. 38A shows the true and tracked frequency, while FIG. 38B shows the corresponding frequency error, which has a root mean square error (RMSE) of 6.21e−3 Hz, approximately five times smaller than the first tracker 801 result shown in FIG. 36B, and approximately fifteen times smaller than the second tracker 802 result shown in FIG. 37B. FIG. 38C shows the true and calculated value of the component amplitude. FIG. 38D shows the corresponding amplitude error with RMSE=3.50e−4 V, which is approximately seven times smaller than the first tracker 801 result shown in FIG. 36D, and approximately twenty-eight times smaller than the second tracker 802 result shown in FIG. 37D. These plots include compensation for the fixed time delay associated with the tracking and filtering process, which for the example implementation of method 700 discussed here corresponds to 2003 samples, or 200.3 ms. Thus the significant tracking improvement is achieved at the cost of additional delay.

The method 700 may be implemented in a variety of ways. As noted above tracker 801, 802 may simply be a tracking Prism or Prism pair, (which may provide a measure of lowpass filtering) with associated frequency, amplitude, and/or phase calculations; or it may include a pre-filter (i.e. a filtering component) taking the form of any of the several Prism techniques and implementations previously described, or prior art conventional FIR filters, whether in Prism or convolutional instantiation. Although described above as comprising a first tracking stage and a second tracking stage, with corresponding first and second trackers 801, 802, other examples of method 700 may use additional tracking stages/trackers. In such examples, the processes of dynamic heterodyning and/or amplitude normalization are applied to after each tracking step, based upon the most recent amplitude and frequency estimates for the original input signal, and where each tracking step provides a narrower passband to facilitate improved noise reduction.

Ultra-Narrowband Filtering with Downsampling

The prior art [B, 2] has described the instantiation of ultra-narrowband Prism-based filters, for example using a six-Prism bandpass filter design. This potentially very long filter design using a small number of Prisms may deliver powerful narrowband filtering performance for significantly lower computational cost than would be possible for the equivalent conventional convolutional filter design. For example, reference [2] describes the implementation of a bandpass filter with 20 MHz sampling and a passband of only 0.01 Hz, resulting in a filter length of approximately 3.9 billion samples, which yet requires only 300 flops per sample to update the filter, a speed-up over an equivalent conventional convolutional filter by a factor of approximately 25 million. Nevertheless, this approach retains certain disadvantages, including the requirement for a large computer memory to store the Prism filter coefficients and data windows. Given that this filter has a step response time of approximately 190 s, the provision of filter outputs at the full sample rate of 20 MHz may be considered excessive, as it will require computational overhead to deal with each new tracker result.

The novel techniques described in this disclosure provide alternative means of achieving ultra-narrowband filtering which may provide one or more of the following benefits over the prior art: improved filtering performance (e.g. lower stopband attenuation), significantly reduced computer memory requirements, reduced update rates (e.g. appropriately matching the response time of the filter), and real-time adjustment to track the desired signal component.

The novel techniques enabling these advantageous features arise in part from the previously described properties of a convolutional implementation of a Prism filter. Firstly, the convolutional calculation may be applied to any contiguous set of samples of appropriate length, without the requirement that it be applied each time the input time series is updated with a new sample. Secondly, the memory storage requirement may be significantly reduced, as only the filter coefficients and one or a small number of accumulators may be needed. Accordingly, the convolutional form of Prism filter is readily combined with the well-established technique of downsampling, to create multi-staged, ultra-narrowband filtering which may provide some or all of the additional benefits described above.

FIG. 39A illustrates a method 900 of filtering an input signal s(t) implementing such a process. Method 900 can be used to determine (e.g. estimate) one or more characteristics of the input signal s(t), such as amplitude, frequency, and/or phase. Method 900 may be performed using a filter system 1000 for filtering an input signal, such as that shown in FIG. 39B. The illustrated filter system 1000 comprises a first filter stage 1001 and a second filter stage 1002, described further below. In general, however, filter system 1000 may comprise any number of filter stages 1001, 1002, including only one filter stage 1001. The output of each respective filter stage 1001, 1002, apart from the final filter stage 1001, 1002 in the sequence, is input into a subsequent filter stage 1001, 1002. Filter system 1000 further comprises a tracker stage 1003. The tracker stage 1003 receives the output of the final filter stage in the sequence of filter stages 1001, 1002. Thus in the illustrated two-filter stage example, tracker stage 1003 receives the output of the second filter stage 1002. The filter stages 1001, 1002 and/or tracker stage 1003 may be implemented as computer-readable instructions. Thus filter system 1000 may be instantiated on a processor configured to perform the computer-readable instructions. As such, the elements of the filter system 1000 shown in FIG. 39B may be considered as logical blocks. Alternatively, any of the filter stages 1001, 1002, and/or tracker stage 1003 may be implemented via circuitry.

The method 900, as illustrated in FIG. 39A, starts at step 901. At step 901, a sequence of one or more filter stages 1001, 1002 are applied. For example, two filter stages may be applied, as in the filter system 1000 of FIG. 39B. Each filter stage 1001, 1002 of the one or more filter stages comprises a respective convolutional filter. The convolutional filter is derived from one or more Prism filters, such as Prism filter 100. The convolutional filter of each filter stage 1001, 1002 is preferably generated using any example of method 400. The convolutional filter(s) may be derived from filter networks according to any example of filter system 200 discussed above, in particular the network shown in FIG. 4B and similar arrangements.

Applying each respective filter stage 1001, 1002 in step 901 comprises firstly heterodyning the input for the respective filter stage 1001, 1002 based on a respective target frequency and a respective filter frequency for that filter stage 1001, 1002; and secondly applying a respective convolutional filter to the respective heterodyned signal. The process of applying the filter stage(s) 1001, 1002 to the input signal in step 901 is illustrated in FIG. 39A for an example of two filter stages 1001, 1002.

The illustrated example of step 901 starts with steps 911 and 912. These steps correspond to applying the first filter stage 1001. At step 911, the input signal (which is the respective input of the first stage 1001) is heterodyned based on a first target frequency and a first filter frequency. The first filter frequency is a frequency that a first convolutional filter of the first filter stage 1001 is configured to pass. For example it may be a peak frequency of the first convolution filter. The first target frequency is a target frequency of the input signal. The target frequency of the input signal is an expected or estimated frequency of a component in the input signal. The aim of the heterodyning step is to shift the respective target frequency towards the peak of the respective convolutional filter of that filter stage 1001, 1002.

The method then proceeds to step 912, at which the heterodyned input signal is input into the first convolutional filter of the first filter stage 1001. The first convolutional filter is applied to a subset of the samples of the heterodyned input signal. The subset of samples is based on a first downsampling factor of the first filter stage 1001. For example, if the downsampling factor is 1000, the first filter is applied to every 1000′ sample of the heterodyned input signal. The outputs of the applications of the first filter form a first downsampled signal. The sampling rate of the downsampled signal will be the sample rate of the input signal divided by the downsampling factor. The first downsampled signal is the output of the first filter stage 1001.

In examples of method 900 comprising only one filter stage 1001, method immediately proceeds to step 902. In step 902 of such examples, the first downsampled signal is passed to the tracker stage 1003. Step 902 is described in further detail below.

In the illustrated example of method 900, however, there are two filter stages 1001, 1002. In such cases, the method 900 comprises applying a second filter stage 1002 before proceeding to step 902. Thus in the illustrated example, the method proceeds from step 912 to steps 913 and 914. Steps 913 and 914 correspond to applying the second filter stage 1002.

The second filter stage 1002 receives the first downsampled signal as an input. In step 913, the first downsampled signal (i.e. the respective input of the second filter stage 1002) is heterodyned based on a second target frequency and a second filter frequency. The second filter frequency is a frequency which a second convolutional filter of the second filter stage 1002 is configured to pass. For example it may be the peak frequency of the second convolutional filter. The second target frequency is the equivalent of the first target frequency (i.e. the actual target frequency of the input signal), as frequency shifted by the first heterodyning step 911. The second convolutional filter may take any of the forms discussed above in relation to the first convolutional filter, but configured to filter lower frequencies. In preferred examples, the respective convolutional filters of the first and second filter stages 1001, 1002 (and any other filter stages) are derived from respective networks of Prism filters having the same form but different characteristic frequencies, m.

The heterodyned signal generated by step 913 is then used in step 914. In step 914, the second convolutional filter is applied to a subset of the samples of the output of step 913. The subset of samples is based on a second downsampling factor of the second filter stage 1002. For example, if the second downsampling factor is 1000, the second filter is applied to every 1000^{th} sample of the heterodyned respective input signal of the second filter stage 1002. The outputs of the applications of the second filter form a second downsampled signal.

In examples of method 900 comprising only two filter stages 1001, 1002, the method then proceeds to step 902. In step 902 of such examples, the second downsampled signal is passed to the tracker stage 1003. Step 902 is described in further detail below.

In general, however, any number of filter stages 1001, 1002 may be applied. Where more than two filter stages 1001, 1002 are used, step 901 of method 900 further comprises applying each additional filter stage in turn after step 914. Each additional application of a filter stage 1001, 1002 is similar to the application of the second filter stage 1002 discussed above, but with respective parameters. Each additional filter stages receives as an input the output of the preceding stage in the sequence of filter stages 1001, 1002. Thus a third filter stage would receive as an input the second downsampled signal generated in step 914, and would perform heterodyning and filtering steps on that respective input. Each additional filter stage may apply a respective heterodyning step to the respective input it receives. The respective heterodyning step is based on a respective filter frequency and respective target frequency. The respective filter frequency is a filter frequency which a respective convolutional filter of that filter stage is configured to pass. The respective target frequency will be the equivalent of the target frequency of the input for the heterodyned frequency range received by that respective filter stage. This will be more apparent with the example discussed below in relation to FIG. 39C.

Once all the filter steps 1001, 1002 have been applied, the method 900 proceeds to step 902. At step 902, a tracker stage 1003 is applied to the output of the final filter stage 1001, 1002. That is, downsampled signal generated by the final filter stage 1001, 1002 is used as the input to the tracker stage 1003. In the example illustrated in FIG. 39A, the output of the second filter stage 1002, i.e. the second heterodyned signal, is input into the tracker stage 1003. Tracker stage 1003 comprises a tracker filter arranged to generate estimates of characteristics of the input signal. It is to be appreciated that although the tracker filter is described as generating the respective estimates, in some examples tracker may generate the ‘G’ values discussed above. These ‘G’ values can then be processed by a control unit 803, or other component, to derive the estimate of the characteristics using the calculations described above. The tracker filter may comprise and/or be derived from one or more Prism filters, such as Prism 100. The tracker filter may include a filtering component, such as a low pass filter, in combination with a tracking component. As such, tracker filter may comprise any of the examples of filter system 500. Alternatively the tracker filter may consist only of a tracker component, without a separate filtering stage. In general the tracker filter may comprise or be derived from any of the filters described herein. In particular, tracker filter (or a filtering component thereof) may be derived from any example of the filter system 200. The tracker filter (or a filtering component thereof) may be convolutional filter derived from a Prism filter or Prism filter network. The convolutional filter may be generated using any example of method 400. Where the tracker filter is a convolutional filter, the convolutional filter outputs the characteristics (or the ‘G’ values that can be used to calculate estimates of the characteristics using the equations discussed above). As such, inputting a signal into the tracker filter may comprise or be equivalent to performing any example of method 600 discussed above. In alternative examples only a filtering component of the tracker filter is a convolutional filter. In such cases the tracker component is an instantiation of one or more Prism filters 100 arranged to generate the ‘G’ outputs discussed above.

Applying the tracker stage in step 902 comprises firstly heterodyning the downsampled signal generated by the final filter stage based on a tracker target frequency and a tracker filter frequency. The tracker filter frequency is a frequency which the tracker filter is configured to pass, such as a peak of the tracker filter. The tracker target frequency is an estimated frequency of the component of the input signal to be tracked, as shifted into the frequency range of the final convolutional filter in the sequence of filter stages 1001, 1002. As discussed further below, the tracker target frequency may be estimated based on the original estimated component frequency of the input signal. Advantageously, however, the tracker target frequency in some examples is estimated using the method 700.

Once the input to the tracker stage 1003 has been heterodyned, the tracker filter is applied to the heterodyned signal to determine one or more characteristics of the input signal. The tracker filter may directly output the characteristics, such as frequency, amplitude, and/or phase, or it may generate the ‘G’ values discussed above from which the characteristics can be calculated. In the filter system 1000 illustrated in FIG. 39B, the heterodyning steps discussed may be performed by respective heterodyning blocks associated with each respective filter stage 1001, 1002 and tracker stage 1003. Alternatively, the filter system 1000 may comprise a common heterodyne block which performs heterodyning for each filter stage 1001, 1002 and tracker stage 1003, before passing a respective heterodyned signal to the respective filter of that stage 1001, 1002, 1003. An exemplary instantiation of method 900 is illustrated in FIG. 39C, which shows a two filter stage (plus one tracker stage) process, where each stage uses a different sampling rate. This design might be applied, for example, to track an input signal with a frequency of approximately 10 MHz, as part of a measurement or communication system. Thus 10 MHz is the estimate of the frequency of the component to be tracked in the input signal. Such a system could be used to track actual change, including very small change, in the input frequency. Alternatively, this arrangement could be used to calibrate a local clock frequency, where the input is known to be an accurate and stable reference signal, in order to ensure the local clock is accurate.

In the implementation of FIG. 39C, the downsampling factor of each filter stage 1001, 1002 is 1000. It is noted that the downsampling factor does not have to be the same for all filter stages 1001, 1002. Thus, for an example input signal sampled at 50 MHz, the first filter stage 1001 operates at 50 MHz, the second filter stage 1002 at 50 kHz, and the tracker stage 1003 at 50 Hz. In other examples the respective downsampling factor of each filter stage is at least 5, or at least 100, or at least 200, or at least 500, or at least 1000, or at least 2000, or at least 5000.

In outline this multistage filter behaves as follows. The first filter stage 1001 applies heterodyning to shift the target frequency of the input signal (10 MHz in this example) towards the peak of a first convolutional low pass Prism filter. The filter is applied to the time series at the downsampling rate (i.e. 1000 in this example). As the downsampling rate between the first filter stage 1001 and the second filter stage 1002 is 1000 (50 MHz to 50 kHz), the convolutional filter is applied to the 50 MHz input signal time series once every 1000 samples, generating a downsampled and filtered result which forms a value in the time series input to the second filter stage 1002. The second filter stage 1002 repeats the calculation of the first filter stage 1001, thereby downsampling from 50 kHz to 50 Hz. In the illustrated example, the second filter stage 1002 also performs in parallel a convolutional version of the filter and tracking calculation of method 700, described above, to provide an estimate of the current amplitude and frequency for each value in the second filter stage 1002 output time series. This may facilitate the use in the tracker stage 1003 of dynamic heterodyning and/or amplitude normalization, as utilized in the ‘I40’ process of method 700 described above. In the tracker stage 1003, a conventional Prism instantiation of a final stage of filtering and tracking is used to provide estimates of frequency, amplitude and/or phase of every sample at the rate of 50 Hz. Compensation for the higher level heterodyning may be used to calculate the corresponding parameter values for the original 50 MHz input signal.

To further illustrate this filter design, exemplary parameter values and operational details are provided, including results from example calculations. Assuming the input signal has a target frequency of 10 MHz, the following design might be applied in the first filter stage 1001. Thus the first target frequency of the first filter stage 1001 is 10 MHz. As will be demonstrated, a 5:1 ratio between a respective target frequency and sampling rate of a respective output may be sufficient to deliver good tracking performance. Thus with a first filter stage 1001 output sample rate of 50 kHz, a suitable first convolutional filter design may use a peak frequency of 10 kHz. This is the first filter frequency of the first filter stage 1001. Accordingly, a heterodyning frequency of 9.99 MHz may be applied to shift the first target frequency of 10 MHz to the first filter frequency of 10 kHz. In general, for any respective filter stage, a ratio of a sample rate of the respective downsampled signal generated in the filter stage and the respective filter frequency may be between 2:1 and 10:1, or between 3:1 and 7:1, or between 4:1 and 6:1, or is (or is approximately) 5:1. Conventional tracking techniques tend to use larger ratios. Using the smaller ratios presented here reduces the computational requirement of the tracking.

A six layer low pass Prism filter, as illustrated in FIG. 4B and FIG. 5, may be used in the first filter stage 1001. For a first filter peak at 10 kHz, the value of m selected is 25 kHz, providing a peak at approximately 0.4m (i.e. at 10 kHz), a passband width of approximately 4.6 kHz centred at 10 kHz, and stop-band attenuation (for frequencies above m i.e. 25 kHz) of −156 dB. Note that this passband range allows for some variation of the true input frequency without impairing the tracking capability in the later stages. For a 50 MHz sampling rate, the first convolutional filter length with these characteristics is 23742 samples.

The first filter stage 1001 operation in this example is as follows. Heterodyning is applied at 9.99 MHz to the input signal. Once in every thousand samples, the first convolution filter is applied to a data window consisting of the most recent 23742 samples in order to generate the next single value in the output time series. The resulting hetrerodyned, filtered and downsampled signal will have the original peak of approximately 10 MHz shifted to approximately 10 kHz, and a sample rate of 50 kHz.

Given the length of the filter compared to the downsampling rate, each 50 MHz sample will be used in either 23 or 24 convolutional calculations of a 50 kHz Stage 1 output value. The corresponding computational cost per sample (allowing for one multiply and accumulate per convolution) is therefore less than 50 flops per 50 MHz sample. Those familiar with the art will be aware that fixed frequency heterodyning can be achieved efficiently through a variety of means, including for example a pre-computed table of heterodyne values that are recycled, so that the overall cost of the first filter stage 1001 calculation may be of the order of 50 flops per sample, compared with the 300 flops per sample cost of the prior art Prism bandpass design [2]. The second filter stage 1002 and tracker stage 1003 computational costs, described in detail below, are significantly smaller, as their sample rates are reduced by factors of 1,000 and 1,000,000 respectively, so that overall the computational requirement for this design is approximately six times less than that for the prior art Prism-based bandpass design, which itself is substantially reduced ([2]) compared with conventional FIR techniques. In addition, the storage requirement for the first filter stage 1001 is significantly reduced compared to the Prism design in [2]; in the first filter stage 1001, the ˜24k filter coefficients and 24 accumulators must be stored, together with the storage associated with the heterodyning calculation, whereas the bandpass filter design described in [2] may require several Gbytes of memory.

As shown in FIG. 39C, the second filter stage 1002 may consist of two paths in parallel: path (A), which essentially repeats the first filter stage 1001 calculation, operating at the lower sample rate of 50 kHz, and path (B) which performs a filter and track calculation. Once again a 5:1 ratio between target frequency and output sampling rate may be used, so that with a second filter stage 1002 output sample rate of 50 Hz, a suitable second convolutional filter design may use a peak frequency of 10 Hz. Accordingly, a heterodyning frequency of 9.99 kHz will shift the second target frequency of 10 kHz to the second convolutional filter peak of 10 Hz. Note that depending on the technique applied, the means used in first filter stage 1001 to generate a 9.99 MHz heterodyning signal at a 50 MHz sampling rate may efficiently be re-used in the second filter stage 1002 to generate a 9.99 kHz heterodyning signal at a 50 kHz sampling rate.

The six layer low pass Prism filter design applied in the first filter stage 1002 may also be used in path (A) of second filter stage 1002, in this case applied to a time series with sample rate of 50 kHz and a filter peak frequency of 10 Hz. The value of m selected is 25 Hz, providing a peak at 0.4m (i.e. at 10 Hz), a passband width of approximately 4.6 Hz centred at 10 Hz, and stop-band attenuation (for frequencies above m i.e. 25 Hz) of −156 dB. If the convolutional filter designs used in first and second filter stages 1001, 1002 are the same, other than the reduced sample rate in the second filter stage 1002, then the filter coefficients may be identical, enabling further memory efficiency.

In path (B) of the second filter stage 1002, and in parallel with path (A), a filtering and tracking calculation, as illustrated for example in FIGS. 12A and 12B, may be performed, providing estimates of frequency and amplitude corresponding to each downsampled value. Thus in some examples the second filter stage 1002 comprises performing any of the examples of method 600 discussed above to estimate/determine one or more characteristics of the signal input into the second filter stage 1002. In general, applying the final filter stage of the sequence of filter stages (i.e. the second filter stage 1002 in the illustrated example) may comprise determining an estimate of characteristics of the respective input to the second filter stage 1002 by applying an estimator tracker. In other examples, a tracking step may be used in multiple of the filter stages 1001, 1002 to generate respective characteristic estimates. The estimator tracker may comprise any of the trackers discussed above. In particular, the estimator tracker may comprise two or more convolutional filters, each configured to generate a respective ‘G’ value from which frequency and/or amplitude can be determined, as described above. The estimator tracker (or each convolutional filter thereof) may comprise/be derived from a low-pass component and a tracker component. The low-pass component may be derived from the same network of Prism filters as the respective convolutional filter of the second/final filter stage 1002.

In a preferred example, the low pass filter design in path B of the second filter stage 1002 is identical to that used in path (A), so that the amplitude and frequency estimates in path (B) correspond exactly to the filter outputs from path (A). However with the additional tracker components included in the convolutional filters, as illustrated in FIG. 12A, the four filter and track convolutions will be longer than the filter-only convolution in path (A). For example, if path (A) uses the same 23742 sample convolutional filter applied in the first filter stage 1001, then the corresponding four path (B) filters, which include the tracking Prism elements, may be of length 28418 samples. Preferably, therefore, the single convolution calculation of path (A) used to generate the next filtered output, and the four convolution calculations of path B used to calculate the values of Gₛ¹, G_{c}¹, Gₛ² and G_{c}² and hence amplitude and frequency, are performed on time series data sets of lengths 23742 and 28418 samples respectively, centred on the same point in time (marked by a common central sample or pair of samples in the input time series), so that the filter output and parameter estimates are synchronous.

The data storage requirements for the illustrated second filter stage 1002 are larger than for the first filter stage 1001. Even if the low pass filter used in path (A) of the second filter stage 1002 is identical of that of the first filter stage 1001, the filter coefficients of the 4 convolutions in path (B) must also be stored, so that including the first and second filter stage 1001, 1002 the total storage requirements may be approximately one hundred and forty thousand values. The computational requirement for the second filter stage 1002 may be larger per sample than for the first filter stage 1001, but with the sampling rate reduced by a factor of 1000, the second filter stage 1002 may not significantly increase the overall computational burden.

After the filtering stages 1001, 1002, the method moves to applying the tracker stage 1003. In the illustrated example, samples are supplied to the tracker stage 1003 at a reduced sample rate of only 50 Hz whereby final frequency, amplitude and/or phase estimates may be calculated every sample. Accordingly, a conventional recursive Prism calculation may be instantiated to provide the final level of low pass filtering and tracking. According to application requirements and the signal properties, it may be advantageous to apply dynamic heterodyning and/or amplitude normalization to the input received by the tracker stage 1003, based on the amplitude and frequency estimates received from the second (or more generally final) filter stage 1002, as previously described in relation to method 700. Alternatively, the amplitude and/or frequency estimates generated by the illustrated second filter stage 1002 may be used to perform basic quality assurance and range checking before the final application of heterodyning, low pass filtering and tracking. This facilitates the ability to check that the input signal falls inside the range of the narrowest filter band, and/or to adjust the heterodyning frequency accordingly.

Without further downsampling to consider, the choice of tracker stage 1003 parameters is primarily a tradeoff between dynamic response and noise reduction. For example, the tracker stage 1003 processing may use the same 6 layer low pass filter structure as the first and second filter stages 1001, 1002, but using m=0.15625 Hz, resulting in a peak frequency of 0.0625 Hz and a heterodyning frequency of 9.9375 Hz. The resulting low pass filter+tracking structure may have a total length of 5557 samples, which, operating at 50 Hz, corresponds to a total duration of approximately 112 seconds.

Frequency, amplitude and/or phase values generated as outputs to the tracker stage 1003 may have compensation applied for each of the earlier stages of heterodyning, so that estimates of the parameters of the original 50 MHz time series may be calculated.

As tracker stage 1003 operates at only 50 Hz, its contribution to the overall computational burden is negligible. However, the storage requirements for the full Prism instantiation of tracker Stage 1003 may be high, for example approximately 300,000 values. Overall, therefore the computational requirements of the FIG. 39C design may be approximately 50 floating point operations per sample, and the storage requirement may be approximately 500k double precision values. Both of these performance metrics suggest a significant improvement over the prior art bandpass filter Prism design.

FIGS. 40 and 41 give simulated examples of the tracking capability of the ultra-narrowband filter and tracking scheme shown in FIG. 39C, where the filter implementation is as described above. In both figures, the input signal consists of a single component with a frequency close to 10 MHz, and an amplitude of approximately 1e−4 V, and includes additive white noise so that the signal-to-noise ratio is low, at −40 dB. Despite this poor signal quality, the ultra-narrowband tracking system is able to track changes in frequency and amplitude, as described below.

FIG. 40A shows the tracking performance in response to a step change in input frequency from exactly 10 Mz to 10 MHz+0.01 Hz (i.e. a step change of 1 part per billion in the input frequency). The input step change occurs at t=600s, and this is successfully tracked in the output frequency over the subsequent approximately 10s. The corresponding frequency errors are shown in FIG. 40B, demonstrating that before and after the step change, the magnitude of the frequency error remains below 1e−10 MHz, i.e. a relative error of approximately 1e−11 of the input frequency and 2e−12 of the input sample rate (50 MHz). This performance is achieved with a signal-to-noise ratio of −40 dB.

FIG. 41A shows, in a separate simulation, the tracking arising from a step change in input amplitude from 1e−4 V to 2e−4 V. The step change in input occurs at t=600s, and the step change is successfully tracked over the course of the next approximately 100s. The corresponding amplitude errors are shown in FIG. 41B, demonstrating that before and after the step change, the magnitude of the amplitude error remains below 1e−6 V, i.e. a relative error of approximately 1%, with a signal-to-noise ratio of −40 dB.

### Applications and Implementations

Any of the filters and filter systems used herein, the filters generated by the methods disclosed herein, and the methods of using filters disclosed herein are configured and/or used to filter input signals representing physical quantities or entities. This includes any example of filter system 200; any example of method 300; any example of method 400; any example of filter system 500; and any example of method 600. For example the input signal may be (or represent) a signal measured by a physical sensor or other physical instrument measuring a physical parameter.

In any of these examples, the input signal may be, or may be a representation of, an audio signal, video signal, communications signal, system control signal, seismological signal, biological signal, electrical power signal, radar signal, sonar signal, or signal representing measurements (or directly may be measurements) of physical quantities measured by a scientific or industrial instrument. The input signal may represent measurements of a mechanical or electrical system. The input signal may be the output of a measurement device configured to measure a mechanical or electrical system. The methods/filters discussed above may be incorporated into such a measurement device.

In particular examples, any of the filter/filter systems/methods may be for filtering signals from a Coriolis meter. A Coriolis meter may comprise a filter/filter system according to any of the examples here, for example as a dedicated hardware filter block arranged to receive and filter an input signal. The Coriolis meter may be configured to perform any of the methods disclosed herein.

In particular examples, any of the filter/filter systems/methods may be for filtering for filtering signals representative of medical images.

In particular examples, any of the filter/filter systems/methods may be for filtering for filtering biological signals.

In particular examples, any of the filter/filter systems/methods may be for filtering for filtering neural signals.

In particular examples, any of the filter/filter systems/methods may be for filtering for filtering communications signals or audio signals.

In particular examples, any of the filter/filter systems/methods may be for vibration monitoring and/or condition monitoring of a mechanical or electrical system.

The term ‘block,’ ‘stage block,’ ‘integration stage block’ or ‘signal processing block’ may be used throughout these disclosures to indicate some means of performing a numerical calculation, whether by hardware, software, or other means. The term is not meant to imply any restriction in the computational architecture, methodology or instantiation; it is simply a convenient label to identify and discuss the various method or system steps presented in this disclosure.

The various illustrative logical blocks, modules, and processes described herein may be implemented or performed by a machine, such as a computer, a processor, a digital signal processor (DSP), a graphics processing unit (GPU), an application specific integrated circuit (ASIC), a field programmable gate array (FPGA) or other programmable logic device, discrete gate or transistor logic, discrete hardware components, or any combination thereof designed to perform the functions described herein. A processor may be a microprocessor, a controller, microcontroller, state machine, combinations of the same, or the like. A processor may also be implemented as a combination of computing devices, e.g., a combination of a DSP and a microprocessor, a plurality of microprocessors or processor cores, one or more graphics or stream processors, one or more microprocessors in conjunction with a DSP, or any other such configuration.

Any of the filters and filter systems used herein, the filters generated by the methods disclosed herein, and the methods of using filters disclosed herein may (including any example of filter system 200; any example of method 300; any example of method 400; any example of filter system 500; and any example of method 600) be implemented on a computer, or implemented on a computer readable medium, such as a non-tangible computer readable medium, or may implemented as a computer program. Any of the filters and filter systems used herein, the filters generated by the methods disclosed herein, and the methods of using filters disclosed herein (including any example of filter system 200; any example of method 300; any example of method 400; any example of filter system 500; and any example of method 600) may be implemented in a dedicated hardware filter block, configured for the sole-purpose of implanting the filter/s and filtering input signals. For example, the filter block may comprise a processor and a memory. The memory stores instructions which, when executed, cause the processor to perform any of the methods described above. Additionally or alternatively, the memory may store properties or coefficients of the filter or filter system, so that the filter or filter system can be instantiated on the processor to filter a received input signal. The filter block further comprise an output to output the filtered signal. The dedicated filter hardware block may be a standalone product, or may be incorporated into device, such as a sensor device. For example, the dedicated filter hardware block may be incorporated into a Coriolis meter.

In particular, certain implementations of the Prism-based filter/filter systems of the present disclosure are sufficiently mathematically, computationally, or technically complex that application-specific hardware (e.g., FPGAs or ASICs) or one or more physical computing devices (utilizing appropriate executable instructions) may be necessary to perform the functionality, for example, due to the volume or complexity of the calculations involved (e.g., filtering and tracking a signal in a low signal-to-noise environment) or to provide results (e.g., tracked signal) substantially in real-time.

The blocks or states of the processes described herein may be embodied directly in hardware, in a software module stored in a non-transitory memory and executed by a hardware processor, or in a combination of the two. For example, the filters/filter systems or methods may also be embodied in, and fully automated by, software modules (e.g. stored in a non-transitory memory) executed by one or more machines such as computers or computer processors. A module may reside in a computer readable medium such as RAM, flash memory, ROM, EPROM, EEPROM, registers, hard disk, an optical disc, memory capable of storing firmware, or any other form of computer-readable (e.g., storage) medium. A computer-readable medium can be coupled to a processor such that the processor can read information from, and write information to, the computer-readable medium. In the alternative, the computer-readable medium may be integral to the processor. The processor and the computer-readable medium may reside in an ASIC. The computer-readable medium may include non-transitory data storage (e.g., a hard disk, non-volatile memory, etc.).

The processes, methods, and systems may be implemented in a network (or distributed) computing environment. For example, the computing device may be implemented in a distributed, networked, computing environment. Network environments include enterprise-wide computer networks, intranets, local area networks (LAN), wide area networks (WAN), personal area networks (PAN), cloud computing networks, crowd-sourced computing networks, the Internet, the Internet of Things (IoT) and the World Wide Web. The network may be a wired or a wireless network, a terrestrial or satellite network, or any other type of communication network.

The filters, filter systems and methods disclosed herein have been discussed primarily in relation to real-time signal processing of an input signal, i.e. filtering the input signal whilst data is still being recorded that will in turn be passed to the filter. However, it is to be appreciated any filter, filter system or method may also be used for off-line analysis of input signals.

The following clauses, which are not claims, define further statements of invention.
1. A method of estimating characteristics of an input signal, the method comprising: inputting the input signal into a first tracker to determine a first estimate of characteristics of the input signal, the first estimate comprising a first amplitude estimate and a first frequency estimate,
   determining a normalised signal from the input signal by:
      normalising the amplitude of the input signal using the first amplitude estimate; and/or
      heterodyning the input signal using a heterodyne frequency determined based on a sum and/or difference between the first frequency estimate and a filter frequency; and
   inputting the normalised signal into a second tracker to determine a second estimate of characteristics of the input signal, the second tracker comprising at least one Prism filter, wherein the second tracker is configured to pass a narrower range of frequencies than the first tracker, and wherein the second tracker is configured to pass the filter frequency;
   wherein at least one of the first tracker and the second tracker comprises or is derived from at least one Prism filter, wherein:
   each Prism filter is configured to evaluate double integrals of the form:

$${I}_{[ S \vert C ] [ S \vert C ]}^{h} = {m}^{2} {\int }_{- \frac{1}{m}}^{0} [ sin \vert cos ] ( 2 π hmt + q ) ( {\int }_{t - \frac{{1}_{}}{m}}^{t} [ sin \vert cos ] ( 2 π hmt + q ) \cdot s ( t ) dt ) dt ,$$

where s(t) is an input to the respective Prism filter, m is a characteristic frequency of the respective Prism filter, [sin|cos] represents a sine or a cosine operation, and q is an optional phase offset variable, and h is a harmonic number of the respective Prism filter.
2. The method of clause 1, wherein the first tracker and/or second tracker comprises or is derived from a network of Prism filters arranged to receive the input signal as an input, the network of Prism filters comprising at least one cosine Prism filter and at least one sine Prism filter, wherein:
   each cosine Prism filter is configured to determine a respective cosine output G_{c}^{h}, where G_{c}^{h}=I_{cs}^{h}−I_{sc}^{h}; and
   each sine Prism filter is configured to determine a respective sine output Gₛ^{h}, where Gₛ^{h}=Iₛₛ^{h}+I_{cc}^{h};
wherein the network of Prism filters comprises a first branch in parallel with a second branch, each of the first branch and second branch arranged to receive the input signal as an input, the first branch comprising the at least one cosine Prism filter, the second branch comprising the at least one sine Prism filter, and wherein the network of Prism filters is arranged to generate an output signal based on a combination of an output of the first branch with an output of the second branch.
3. The method of clause 2, wherein the first branch of the network of Prism filters comprises two or more cosine filter sets connected in series such that an output of a respective preceding cosine filter set in the series is input into a respective subsequent cosine filter set of the series, wherein the output of the first branch is an output of a final cosine filter set in the series, and wherein each cosine filter set comprises at least one cosine Prism filter, and
   wherein the second branch of the network of Prism filters comprises two or more sine filter sets connected in series such that an output of a respective preceding sine filter set in the series is input into a respective subsequent sine filter set of the series, wherein the output of the second branch is an output of a final sine filter set in the series, and wherein each sine filter set comprises at least one sine Prism filter.
4. The method of clause 2, wherein one or more of the cosine filter sets and/or one or more of the sine filter sets comprises a plurality of cosine/sine Prism filters connected in parallel such that the input to the respective cosine/sine filter set is input into each of the plurality of cosine/sine Prism filters of that cosine/sine filter set, and the output of the respective cosine/sine filter set is a combination of the outputs of the plurality of cosine/sine Prism filters of that cosine/sine filter set.
5. The method of clause 4, wherein a respective weight is applied to the output of each of the plurality of cosine/sine Prism filters of a cosine/sine filter set prior to generating the output of that cosine/sine filter set.
6. The method of any of clauses 2 to 4, wherein each cosine filter set and/or each sine filter set comprises two cosine/sine Prism filters, or three cosine/sine Prism filters, or four cosine/sine Prism filters, or five cosine/sine Prism filters.
7. The method of any preceding clause, wherein the characteristic frequency, m₁, of all Prism filters in the first tracker or from which the first tracker is derived is the same, and/or the characteristic frequency, m₂, of all Prism filters in the second tracker or from which the second tracker is derived is the same.
8. The method of clause 7, wherein the value of m₂ is at least 1.5 times, or at least 10 times, or at least 20 times, or at least 50 times, or at least 100 times smaller than the value of m₁.
9. The method of any preceding clause, wherein the first tracker and/or second tracker is a convolutional filter derived from an impulse response of a network of Prism filters.
10. The method of any preceding clause, wherein the first tracker and/or second tracker comprises a filtering component and a tracking component.
11. The method of clause 10, wherein the filtering component is or comprises a low-pass filter or a bandpass filter.
12. The method of any preceding clause, wherein the normalisation signal is determined from the input signal after a predetermined delay.
13. The method of any preceding clause, wherein respective values of the first amplitude estimate and/or first frequency estimate are determined for each of a plurality of samples in the input signal.
14. The method of clause 13, wherein normalising the amplitude of the input signal comprises dividing each of the plurality of samples of the input signal by the respective value of the first amplitude estimate.
15. The method of clause 13 or clause 14, wherein heterodyning the input signal comprises heterodyning each of the plurality of samples of the input signal based on a sum and/or difference of the respective value of the first frequency estimate and the target frequency.
16. The method of any preceding clause, wherein the second estimate of characteristics of the input signal comprises a second amplitude estimate and/or a second frequency estimate.
17. The method of any preceding clause, wherein the second estimate of characteristics comprises or further comprises a phase of the input signal.
18. The method of any preceding clause, wherein determining the second estimate of characteristics of the input signal comprises adjusting a frequency and/or phase estimated by the second tracker based on the heterodyne frequency or frequencies and/or a heterodyne phase or phases.
19. The method of any preceding clause, further comprising instantiating the first tracker and the second tracker.
20. A signal characterisation device for estimating characteristics of an input signal, the device comprising:
   a first tracker configured to determine a first estimate of characteristics of the input signal;
   a second tracker configured to determine a second estimate of the characteristics of the input signal; and
   a control unit configured to perform the method of any of clauses 1 to 17 to estimate characteristics of the input signal;
   wherein at least one of the first tracker and the second tracker comprises or is derived from at least one Prism filter.
21. A method of filtering an input signal, the method comprising:
   applying a sequence of one or more filter stages to the input signal, wherein:
      the input to a first filter stage in the sequence is the input signal, and the input to any subsequent filter stages in the sequence is a respective downsampled signal generated by an immediately preceding filter stage; and
      applying a respective filter stage of the sequence of one or more filter stages comprises:
         heterodyning the input for the respective filter stage based on a respective target frequency and a respective filter frequency;
         applying a respective convolutional filter to a subset of samples of the heterodyned input selected based on a respective downsampling factor, the respective convolutional filter configured to pass the respective filter frequency;
         generating a respective downsampled signal from outputs of the respective convolutional filter applied to the subset of samples; and
   applying a tracker stage to the downsampled signal generated by a final filter stage in the sequence of one or more filter stages, wherein applying the tracker stage comprises:
      heterodyning the downsampled signal generated by the final filter stage based on a tracker target frequency and a tracker filter frequency;
      applying a tracker filter to the heterodyned downsampled signal generated by the final filter stage to determine one or more characteristics of the input signal;
   wherein each respective convolutional filter is derived from a network of Prism filters comprising at least one Prism filter, and the tracker filter comprises or is derived from at least one Prism filter, wherein each Prism filter is configured to evaluate double integrals of the form:

$${I}_{[ S \vert C ] [ S \vert C ]}^{h} = {m}^{2} {\int }_{- \frac{1}{m}}^{0} [ sin \vert cos ] ( 2 π hmt + q ) ( {\int }_{t - \frac{{1}_{}}{m}}^{t} [ sin \vert cos ] ( 2 π hmt + q ) \cdot s ( t ) dt ) dt ,$$

where s(t) is an input to the respective Prism filter, m is a characteristic frequency of the respective Prism filter, [sin|cos] represents a sine or a cosine operation, and q is an optional phase offset variable, and h is a harmonic number of the respective Prism filter.
22. The method of clause 21, wherein the sequence of one or more filter stages comprises one filter stage, two filter stages, or three filter stages.
23. The method of clause 21 or clause 22, wherein applying the final filter stage further comprises determining an estimate of characteristics of the respective input to the final filter stage by applying an estimator tracker to the respective subset of samples of the final filter stage, wherein the estimate of characteristics comprises a frequency estimate and/or an amplitude estimate, and wherein the estimator tracker is derived from at least one Prism filter.
24. The method of clause 23, wherein:
   the estimate of characteristics comprises a frequency estimate; and
   in the step of applying the tracker stage, the frequency estimate is used as the tracker target frequency.
25. The method of clause 23 or clause 24, wherein:
   the estimate of characteristics comprises an amplitude estimate; and
   in the step of applying the tracker stage, the heterodyned downsampled signal generated by the final filter stage is normalised using the amplitude estimate prior to before applying the tracker filter.
26. The method of any of clauses 23 to 25, wherein the estimator tracker comprises a low-pass component and a tracker component.
27. The method of clause 26, wherein the low-pass component of the estimator tracker is a convolutional filter derived from the same network of Prism filters as the respective convolutional filter of the final filter stage.
28. The method of any preceding clause, wherein for any respective filter stage, a ratio of a sample rate of the respective downsampled signal generated in the filter stage and the respective filter frequency is between 3:1 and 7:1, or is between 4:1 and 6:1, or is approximately 5:1.
29. The method of any preceding clause, wherein each respective convolutional filter is generated from an impulse response of a network of Prism filters.
30. The method of clause 29, further comprising generating the respective convolutional filters by:
   instantiating one or more networks of Prism filters;
   inputting an impulse signal into the one or more networks of Prism filters to generate respective impulse responses of the one or more networks of Prism filters; and
   generating the respective convolutional filters based on the impulse responses of the one or more networks of Prism filters.
31. The method of any preceding clause, wherein one or more of the respective convolutional filters is derived from a network of Prism filters arranged to receive the input signal as an input, the network of Prism filters comprising at least one cosine Prism filter and at least one sine Prism filter, wherein:
   each cosine Prism filter is configured to determine a respective cosine output G_{c}^{h}, where G_{c}^{h}=I_{cs}^{h}−I_{sc}^{h}; and
   each sine Prism filter is configured to determine a respective sine output Gₛ^{h}, where Gₛ^{h}=Iₛₛ^{h}+I_{cc}^{h};
wherein the network of Prism filters comprises a first branch in parallel with a second branch, each of the first branch and second branch arranged to receive the input signal as an input, the first branch comprising the at least one cosine Prism filter, the second branch comprising the at least one sine Prism filter, and wherein the network of Prism filters is arranged to generate an output signal based on a combination of an output of the first branch with an output of the second branch.
32. The method of clause 31, wherein the first branch of the network of Prism filters comprises two or more cosine filter sets connected in series such that an output of a respective preceding cosine filter set in the series is input into a respective subsequent cosine filter set of the series, wherein the output of the first branch is an output of a final cosine filter set in the series, and wherein each cosine filter set comprises at least one cosine Prism filter, and
   wherein the second branch of the network of Prism filters comprises two or more sine filter sets connected in series such that an output of a respective preceding sine filter set in the series is in input into a respective subsequent sine filter set of the series, wherein the output of the second branch is an output of a final sine filter set in the series, and wherein each sine filter set comprises at least one sine Prism filter.
33. The method of clause 32, wherein one or more of the cosine filter sets and/or one or more of the sine filter sets comprises a plurality of cosine/sine Prism filters connected in parallel such that the input to the respective cosine/sine filter set is input into each of the plurality of cosine/sine Prism filters of that cosine/sine filter set, and the output of the respective cosine/sine filter set is a combination of the outputs of the plurality of cosine/sine Prism filters of that cosine/sine filter set.
34. The method of any preceding clause, wherein the respective convolutional filters of all the filter stages are derived from respective networks of Prism filters having the same form but different characteristic frequencies, m.
35. The method of any preceding clause, wherein the each respective convolutional filter is or comprises a low-pass filter or a bandpass filter.
36. The method of any preceding clause, wherein the respective downsampling factor of each filter stage is at least 5, or at least 100, or at least 200, or at least 500, or at least 1000, or at least 2000, or at least 5000.
37. The method of any preceding clause, wherein the method is a method of ultra-narrowband filtering of the input signal.
38. A filter system for filtering an input signal, the filter system comprising:
   a sequence of one or more filter stages, each filter stage of the one or more filter stages comprising a respective convolutional filter, the first filter stage configured to receive the input signal as an input, and each subsequent filter stage configured to receive an output of an immediately preceding filter stage in the sequence of filter stages as a respective input;
   a tracker stage comprising a tracker filter configured to receive an output of a final filter stage of the sequence of filter stages as an input; and
   one or more heterodyne blocks configured to heterodyne the respective inputs of each filter stage;
   wherein the filter system is configured to perform the method of any of clauses 21 to 37.
38. The method of any of clauses 1 to 19 or 21 to 37, the signal characterisation device of clause 20, or the filter system of clause 39, wherein the input signal is, or is a representation of, an audio signal, video signal, communications signal, system control signal, seismological signal, biological signal, electrical power signal, radar signal, sonar signal, signal representing measurements of a mechanical or electrical system, or signal representing measurements of physical quantities measured by a scientific or industrial instrument.
39. The method of any of clauses 1 to 19 or 21 to 37, the signal characterisation device of clause 20, or the filter system of clause 39, wherein the filter system or convolutional filter is for low pass or bandpass filtering of the signal.
40. The method of any of clauses 1 to 19 or 21 to 37, the signal characterisation device of clause 20, or the filter system of clause 39, wherein the input signal is, or is a representation of, a signal output by a sensor.
41. The method of any of clauses 1 to 19 or 21 to 37, the signal characterisation device of clause 20, or the filter system of clause 39, wherein the input signal is or represents a measurement taken by a Coriolis meter.
42. A Coriolis meter comprising the signal characterisation device of clause 20 or the filter system of clause 39, and/or configured to perform the method of any of clauses 1 to 19 or 21 to 37.
43. The method of any of clauses 1 to 19 or 21 to 37, the signal characterisation device of clause 20, or the filter system of clause 39, wherein the input signal is a signal representative of a medical image.
44. The method of any of clauses 1 to 19 or 21 to 37, the signal characterisation device of clause 20, or the filter system of clause 39, wherein In any embodiment of the first to ninth aspects.
45. The method, device, or system of clause 44, wherein the biological signal is a neural signal.
46. The method of any of clauses 1 to 19 or 21 to 37, the signal characterisation device of clause 20, or the filter system of clause 39, wherein the input signal is a communications signal or audio signal.
47. The method of any preceding clause, wherein the characteristics of the input signal include a frequency of the input signal, and wherein the method further comprises detecting a change in the frequency of the input signal.
48. The method of any preceding clause, wherein the characteristics of the input signal include a frequency of the input signal, and wherein the method further comprises calibrating a clock frequency based on the determined frequency of the input signal.
49. The method of any of clauses 1 to 19 or 21 to 37, the signal characterisation device of clause 20, or the filter system of clause 39, wherein the input signal is a vibration monitoring and/or condition monitoring signal representative of a mechanical or electrical system.
50. The signal characterisation device of clause 20, or the filter system of 37, wherein the device or system is implemented on dedicated hardware.
51. The signal characterisation device of clause 20, or the filter system of 37, wherein the filter system is implemented on a computer, or is implemented on a computer readable medium, or is implemented as a computer program.
52. A computer program storing instructions which, when executed by a computer, cause the computer to perform the method of any preceding clause.
53. A computer readable medium storing the computer program of clause 52.
   101. A filter system for filtering an input signal, the filter system comprising: a network of Prism filters arranged to receive the input signal as an input, the network of Prism filters comprising at least one cosine Prism filter and at least one sine Prism filter, wherein:
      each Prism filter is configured to evaluate combinations of double integrals of the form:

$${I}_{[ S \vert C ] [ S \vert C ]}^{h} = {m}^{2} {\int }_{- \frac{1}{m}}^{0} [ sin \vert cos ] ( 2 π hmt + q ) ( {\int }_{t - \frac{{1}_{}}{m}}^{t} [ sin \vert cos ] ( 2 π hmt + q ) \cdot s ( t ) dt ) dt ,$$

where s(t) is an input to the respective Prism filter, m is a characteristic frequency of the respective Prism filter, [sin|cos] represents a sine or a cosine operation, q is an optional, arbitrary phase offset variable, and h is a harmonic number of the respective Prism filter of the network of Prism filters;
each cosine Prism filter is configured to determine a respective cosine output G_{c}^{h}, where G_{c}^{h}=I_{cs}^{h}−I_{sc}^{h}; and
each sine Prism filter is configured to determine a respective sine output Gₛ^{h}, where gₛ^{h}=Iₛₛ^{h}+I_{cc}^{h};
wherein the network of Prism filters comprises a first branch in parallel with a second branch, each of the first branch and second branch arranged to receive the input signal as an input, the first branch comprising the at least one cosine Prism filter, the second branch comprising the at least one sine Prism filter, and wherein the network of Prism filters is arranged to generate an output signal based on a combination of an output of the first branch with an output of the second branch.
102. The filter system of clause 101, wherein the first branch comprises two or more cosine filter sets connected in series such that an output of a respective preceding cosine filter set in the series is input into a respective subsequent cosine filter set of the series, wherein the output of the first branch is an output of a final cosine filter set in the series, and wherein each cosine filter set comprises at least one cosine Prism filter, and
   wherein the second branch comprises two or more sine filter sets connected in series such that an output of a respective preceding sine filter set in the series is in input into a respective subsequent sine filter set of the series, wherein the output of the second branch is an output of a final sine filter set in the series, and wherein each sine filter set comprises at least one sine Prism filter.
103. The filter system of clause 102, wherein the first branch comprises an even number of cosine filter sets, and the second branch comprises an even number of sine filter sets.
104. The filter system of clause 102 or clause 103, wherein the number of cosine filter sets in the first branch is equal to the number of sine filter sets in the second branch.
105. The filter system of clause 104, wherein the second branch comprises a corresponding sine filter set for each cosine filter set of the first branch, wherein the harmonic number, h, of a sine Prism filter in a sine filter set matches the harmonic number, h, of a cosine Prism filter in the corresponding cosine filter set.
106. The filter system of any of clauses 102 to 105, wherein one or more of the cosine filter sets and/or one or more of the sine filter sets comprises a plurality of cosine/sine Prism filters connected in parallel such that the input to the respective cosine/sine filter set is input into each of the plurality of cosine/sine Prism filters of that cosine/sine filter set, and the output of the respective cosine/sine filter set is a combination of the outputs of the plurality of cosine/sine Prism filters of that cosine/sine filter set.
107. The filter system of clause 106, wherein a respective weight is applied to the output of each of the plurality of cosine/sine Prism filters of a cosine/sine filter set prior to generating the output of that cosine/sine filter set.
108. The filter system of clause 107, wherein the respective weights are selected to provide a desired frequency response characteristic of the filter system.
109. The filter system of clause 108, wherein the weights are selected using optimisation based on gain functions of the Prism filters of the filter network.
110. The filter system of any of clauses 106 to 109, wherein each cosine filter set and/or each sine filter set comprises two cosine/sine Prism filters, or three cosine/sine Prism filters, or four cosine/sine Prism filters, or five cosine/sine Prism filters.
111. The filter system of any of clauses 106-110, wherein:
   each cosine filter set comprises n cosine filters;
   for each cosine filter set, each of the plurality of cosine Prism filters comprises a respective harmonic number hᵢ such that a set of harmonic frequencies h₁, . . . hₙ is used within the respective cosine filter set; and
   the set of harmonic frequencies h₁, . . . hₙ of cosine Prism filters of each cosine filter set is the same.
112. The filter system of any of clauses 106-111, wherein:
   each sine filter set comprises n sine Prism filters;
   for each sine filter set, each of the plurality of sine Prism filters comprises a respective harmonic number hᵢ such that a set of harmonic frequencies h₁, . . . hₙ is used within the respective sine filter set; and
   the set of harmonic frequencies h₁, . . . hₙ of sine filters of each sine filter set is the same.
113. The filter system of clause 112 as dependent upon clause 110, wherein the set of harmonic frequencies h₁, . . . hₙ of sine filters of each sine filter set and the set of harmonic frequencies h₁, . . . hₙ of cosine filters of each cosine filter set are the same.
114. The filter system of any preceding clause, wherein the characteristic frequency, m, of all sine Prism filters and cosine Prism filters in the network is the same.
115. The filter system of any preceding clause, wherein the network of Prism filters comprises a combined filter set comprising at least one combined Prism filter, each combined Prism filter configured to determine a respective cosine output G_{c}^{h} and a respective sine output Gₛ^{h}, wherein the combined filter set is arranged to provide a first filter set of both the first branch and the second branch by receiving the input signal and outputting a cosine output to the first branch and a sine output to the second branch.
116. The filter system of any preceding clause, wherein the filter system further comprises a tracker formed of one or more Prism filters, wherein the tracker is configured to receive the output signal from the network of Prism filters, and to generate an output indicative of a parameter of the input signal.
117. The filter system of any of clauses 100-115, wherein the filter system further comprises a tracker formed of one or more Prism filters, wherein the tracker is configured to receive the output signal from the network of Prism filters, and to generate one or more outputs selected from the group comprising: G_{c}¹, Gₛ¹, G_{c}², and Gₛ², where G_{c}^{h}=I_{cs}^{h}−I_{sc}^{h}, Gₛ^{h}=Iₛₛ^{h}+I_{cc}^{h}, G_{c}¹=G_{c}^{h} when h=1, G_{c}²=G_{c}^{h} when h=2, Gₛ²=Gₛ^{h} when h=1. and Gₛ²=Gₛ^{h} when h=2.
118. A method of filtering an input signal, the method comprising:
   instantiating a filter system according to any of clauses 1 to 17;
   inputting the input signal into the instantiated filter system to filter the input signal.
119. A method of designing a convolutional filter for filtering an input signal, the method comprising:
   generating a filter system arranged to receive the input signal, the filter system comprising at least one Prism filter, wherein:
      each Prism filter is configured to evaluate double integrals of the form:

$${I}_{[ S \vert C ] [ S \vert C ]}^{h} = {m}^{2} {\int }_{- \frac{1}{m}}^{0} [ sin \vert cos ] ( 2 π hmt + q ) ( {\int }_{t - \frac{{1}_{}}{m}}^{t} [ sin \vert cos ] ( 2 π hmt + q ) \cdot s ( t ) dt ) dt ,$$

where s(t) is an input to the respective Prism filter, m is a characteristic frequency of the respective Prism filter, [sin|cos] represents a sine or a cosine operation, q is an optional and/or arbitrary phase offset variable, and h is a harmonic number of the respective Prism filter,
inputting a test signal into the filter system to generate an impulse response of the filter system; and
generating a convolutional filter for filtering the input signal based on the impulse response of the filter system.
120. The method of clause 119, wherein the test signal is an impulse signal.
121. The method of clause 119 or clause 120, wherein generating the convolutional filter comprises outputting the impulse response as the convolutional filter.
122. The method of clause 119 or clause 120 or clause 121, further comprising combining the generated convolutional filter with a tracker arranged to receive the output of the convolutional filter, wherein the tracker comprises a Prism filter configured to generate an output indicative of a parameter of the input signal input into the convolutional filter.
123. The method of any of clauses 119 to 122, wherein the filter system is or comprises a tracker configured to generate an output indicative of a parameter of the input signal, such that the generated convolutional filter acts as a tracker configured to generate an output indicative of the parameter of the input signal.
124. The method of clause 122 or clause 123, wherein the parameter of the input signal comprises at least one of: amplitude, phase, and frequency.
125. The method of any of clauses 119 to 124, wherein generating the filter system comprises selecting, based on the input signal or a physical system represented by the input signal, at least one of:
   a number of Prism filters within the filter system;
   an arrangement of Prism filters within the filter system;
   a harmonic number of one or more of the Prism filters within the filter system;
   a characteristic frequency of one or more Prism filters within the filter system.
126. The method of any of clauses 119 to 125, wherein the filter system comprises a plurality of Prism filters connected in series such that an output of a respective preceding Prism filter in the series is in input into a respective subsequent filter of the series.
127. The method of any of clauses 119 to 126, wherein the filter system comprises a plurality of Prism filters connected in parallel such that each Prism filter connected in parallel receives a common input.
128. The method of any of clauses 119 to 127, wherein the filter system comprises a filter system according to any of clauses 101 to 112.
129. The method of any of clauses 119 to 128, wherein the filter system is arranged to generate an output selected from the group comprising: G_{c}¹, Gₛ¹, G_{c}², and Gₛ², such that the convolutional filter is configured to generate a corresponding output G_{c}¹, Gₛ¹, G_{c}², or Gₛ²
   where G_{c}^{h}=I_{cs}^{h}−I_{sc}^{h}, Gₛ^{h}=Iₛₛ^{h}+I_{cc}^{h}, G_{c}¹=G_{c}^{h} when h=1, G_{c}²=G_{c}^{h} when h=2, Gₛ¹=Gₛ^{h} when h=1, and Gₛ²=Gₛ^{h} when h=2,
130. The method of clause 129, wherein the filter system comprises a low-pass or band-pass Prism filter and a tracker Prism filter, the low-pass filter arranged to filter an input signal, and the tracker filter arranged to generate the respective output G_{c}¹, Gₛ¹, G_{c}², or Gₛ² from the output of the low-pass filter.
131. A method of filtering an input signal, the method comprising:
   providing two or more convolutional filters, each convolutional filter of the two or more convolution filters generated using the method of clause 29 or 30 and arranged to generate a respective one of the outputs G_{c}¹, Gₛ¹, G_{c}², and Gₛ²;
   applying each of the two or more convolutional filters to the input signal to generate the outputs G_{c}¹, Gₛ¹, G_{c}², and Gₛ²;
   generating at least one of the amplitude, frequency and phase of the input signal based on the outputs G_{c}¹, Gₛ¹, G_{c}², and Gₛ².
132. The method of clause 31, wherein the two or more convolutional filters comprise four convolutional filters, each convolutional filter of the four convolutional filters generated using the method of clause 128, and wherein:
   applying each of the four convolutional filters comprises:
      heterodyning the input signal using a plurality of heterodyne frequencies selected based on a pass-band of the low-pass or band-pass Prism filter, and
      applying each of the four convolutional filters to the heterodyned input signal for each heterodyne frequency to generate the outputs G_{c}¹, Gₛ¹, G_{c}², and Gₛ² for each heterodyne frequency; and
   generating at least one of the amplitude, frequency and phase of the input signal comprises generating the at least one of amplitude, frequency and phase of the heterodyned input signal for each heterodyne frequency based on the outputs G_{c}¹, Gₛ¹, G_{c}², and Gₛ² generated for that heterodyne frequency.
133. The method of clause 31, wherein a Fourier transform algorithm is applied to the output of each convolutional filter of the two or more convolutional filters to generate the outputs G_{c}¹, Gₛ¹, G_{c}², and Gₛ².
134. The method of any of clauses 131 to 133, further comprising:
   estimating frequencies of peaks in the generated amplitude, frequency and/or phase; and
   reapplying each of the two or more convolutional filters to the input signal based on the estimated peak frequencies to generate updated values for amplitude, frequency and/or phase by:
      heterodyning the input signal using heterodyne frequencies corresponding to each of the estimated peak frequencies; and
      applying each of the two or more convolutional filters to the heterodyned input signal for each heterodyne frequency corresponding to an estimated peak frequency to generate the outputs G_{c}¹, Gₛ¹, G_{c}², and Gₛ² for each heterodyne frequency; and
   generating updated values for amplitude, frequency and/or phase of the heterodyned input signal for each heterodyne frequency corresponding to an estimated peak frequency based on the outputs G_{c}¹, Gₛ¹, G_{c}², and Gₛ² generated for that heterodyne frequency.
135. The filter system of any of clauses 1 to 117, or the method of any of clauses 118 to
134, wherein the input signal is, or is a representation of, an audio signal, video signal, communications signal, system control signal, seismological signal, biological signal, electrical power signal, radar signal, sonar signal, vibration signal, condition monitoring signal, signal representing measurements of a mechanical or electrical system, or signal representing physical quantities measured by a scientific or industrial instrument.
136. The filter system of any of clauses 101 to 117, or the method of any of clauses 18 to 34, wherein the filter system or convolutional filter is for low pass or bandpass filtering of the signal.
137. The filter system of any of clauses 101 to 117, or the method of any of clauses 18 to 34, wherein the filter system or convolutional filter is for filtering a signal output by a sensor.
138. The filter system of any of clauses 101 to 117, or the method of any of clauses 18 to 34, wherein the filter system or convolutional filter is for filtering signals from a Coriolis meter.
139. A Coriolis meter comprising a filter system according to any of clauses 101 to 117, or a convolutional filter designed using the method of any of clauses 119 to 130.
140. The filter system of any of clauses 101 to 117, or the method of any of clauses 118 to 134, wherein the filter system or convolutional filter is for filtering signals representative of medical images.
141. The filter system of any of clauses 101 to 117, or the method of any of clauses 118 to 34, wherein the filter system or convolutional filter is for filtering biological signals.
142. The filter system or method of clause 141, wherein the filter system or convolutional filter is for filtering neural signals.
143. The filter system of any of clauses 101 to 117, or the method of any of clauses 118 to 131, wherein the filter system or convolutional filter is for filtering communications signals or audio signals.
144. The filter system of any of clauses 101 to 117, or the method of any of clauses 118 to 134, wherein the filter system or convolutional filter is for vibration monitoring and/or condition monitoring of a mechanical or electrical system.
145. The filter system of any of clauses 101 to 117, wherein the filter system is implemented on a computer, or is implemented on a computer readable medium, or is implemented as a computer program.
146. A computer program storing instructions which, when executed by a computer, cause the computer to perform the method of any of clauses 118 to 134.
147. A computer readable medium storing the computer program of clause 146.

### REFERENCES

### Patent Application References

[A] US2019294649A1 Method and system for tracking sinusoidal wave parameters from a received signal that includes noise.
[B] WO2019211309A1 Method and system for ultra-narrowband filtering with signal processing using a concept called Prism

### Scientific Literature References:

[1] Henry, MP. “The Prism: recursive FIR signal processing for instrumentation applications”. IEEE Transactions on Instrumentation and Measurement, April 2020.
[2] Henry, MP. Building Billion Tap Filters. IEEE Industrial Electronics Magazine, Nov 2020.
[3] Henry, MP. Spectral Analysis Techniques using Prism Signal Processing, Measurement, Sep 2020
[4] Henry, MP. “Low Pass, Low cost Prism Filters”, 2020 IEEE International Workshop on Metrology for Industry 4.0 & IoT, Rome, June 2020.
[5] Henry, M P et al., “The Prism: Efficient Signal Processing for the Internet of Things,” IEEE Industrial Electronics Magazine, pp 2-10, December 2017. DOI:

1. A method of estimating characteristics of an input signal, the method comprising:
inputting the input signal into a first tracker to determine a first estimate of characteristics of the input signal, the first estimate comprising a first amplitude estimate and a first frequency estimate,
determining a normalised signal from the input signal by:
normalising the amplitude of the input signal using the first amplitude estimate; and/or
heterodyning the input signal using a heterodyne frequency determined based on a sum and/or difference between the first frequency estimate and a filter frequency; and
inputting the normalised signal into a second tracker to determine a second estimate of characteristics of the input signal, the second tracker comprising at least one Prism filter, wherein the second tracker is configured to pass a narrower range of frequencies than the first tracker, and wherein the second tracker is configured to pass the filter frequency;
wherein at least one of the first tracker and the second tracker comprises or is derived from at least one Prism filter, wherein:
each Prism filter is configured to evaluate double integrals of the form:
$${I}_{[ S \vert C ] [ S \vert C ]}^{h} = {m}^{2} {\int }_{- \frac{1}{m}}^{0} [ sin \vert cos ] ( 2 π hmt + q ) ( {\int }_{t - \frac{{1}_{}}{m}}^{t} [ sin \vert cos ] ( 2 π hmt + q ) \cdot s ( t ) dt ) dt ,$$
where s(t) is an input to the respective Prism filter, m is a characteristic frequency of the respective Prism filter, [sin|cos] represents a sine or a cosine operation, and q is an optional phase offset variable, and h is a harmonic number of the respective Prism filter.

2. The method of claim 1, wherein the first tracker and/or second tracker comprises or is derived from a network of Prism filters arranged to receive the input signal as an input, the network of Prism filters comprising at least one cosine Prism filter and at least one sine Prism filter, wherein:
each cosine Prism filter is configured to determine a respective cosine output G_{c}^{h}, where G_{c}^{h}=I_{cs}^{h}−I_{sc}^{h}; and
each sine Prism filter is configured to determine a respective sine output Gₛ^{h}, where Gₛ^{h}=Iₛₛ^{h}+I_{cc}^{h};
wherein the network of Prism filters comprises a first branch in parallel with a second branch, each of the first branch and second branch arranged to receive the input signal as an input, the first branch comprising the at least one cosine Prism filter, the second branch comprising the at least one sine Prism filter, and wherein the network of Prism filters is arranged to generate an output signal based on a combination of an output of the first branch with an output of the second branch.

3. The method of claim 2, wherein the first branch of the network of Prism filters comprises two or more cosine filter sets connected in series such that an output of a respective preceding cosine filter set in the series is input into a respective subsequent cosine filter set of the series, wherein the output of the first branch is an output of a final cosine filter set in the series, and wherein each cosine filter set comprises at least one cosine Prism filter, and
wherein the second branch of the network of Prism filters comprises two or more sine filter sets connected in series such that an output of a respective preceding sine filter set in the series is input into a respective subsequent sine filter set of the series, wherein the output of the second branch is an output of a final sine filter set in the series, and wherein each sine filter set comprises at least one sine Prism filter.

4. The method of claim 2, wherein one or more of the cosine filter sets and/or one or more of the sine filter sets comprises a plurality of cosine/sine Prism filters connected in parallel such that the input to the respective cosine/sine filter set is input into each of the plurality of cosine/sine Prism filters of that cosine/sine filter set, and the output of the respective cosine/sine filter set is a combination of the outputs of the plurality of cosine/sine Prism filters of that cosine/sine filter set.

5. The method of claim 4, wherein a respective weight is applied to the output of each of the plurality of cosine/sine Prism filters of a cosine/sine filter set prior to generating the output of that cosine/sine filter set.

6. The method of claim 2, wherein each cosine filter set and/or each sine filter set comprises two cosine/sine Prism filters, or three cosine/sine Prism filters, or four cosine/sine Prism filters, or five cosine/sine Prism filters.

7. The method of claim 1, wherein the characteristic frequency, m₁, of all Prism filters in the first tracker or from which the first tracker is derived is the same, and/or the characteristic frequency, m₂, of all Prism filters in the second tracker or from which the second tracker is derived is the same.

8. The method of claim 7, wherein the value of m₂ is at least 1.5 times, or at least 10 times, or at least 20 times, or at least 50 times, or at least 100 times smaller than the value of m₁.

9. The method of claim 1, wherein the first tracker and/or second tracker is a convolutional filter derived from an impulse response of a network of Prism filters.

10. The method of claim 1, wherein the first tracker and/or second tracker comprises a filtering component and a tracking component.

11. The method of claim 10, wherein the filtering component is or comprises a low-pass filter or a bandpass filter.

12. The method of claim 1, wherein the normalisation signal is determined from the input signal after a predetermined delay.

13. The method of claim 1, wherein respective values of the first amplitude estimate and/or first frequency estimate are determined for each of a plurality of samples in the input signal.

14. The method of claim 13, wherein normalising the amplitude of the input signal comprises dividing each of the plurality of samples of the input signal by the respective value of the first amplitude estimate.

15. The method of claim 13, wherein heterodyning the input signal comprises heterodyning each of the plurality of samples of the input signal based on a sum and/or difference of the respective value of the first frequency estimate and the target frequency.

16. The method of claim 1, wherein the second estimate of characteristics of the input signal comprises a second amplitude estimate and/or a second frequency estimate, and/or, wherein the second estimate of characteristics comprises or further comprises a phase of the input signal.

17. The method of claim 1, wherein determining the second estimate of characteristics of the input signal comprises adjusting a frequency and/or phase estimated by the second tracker based on the heterodyne frequency or frequencies and/or a heterodyne phase or phases.

18. The method of claim 1, further comprising instantiating the first tracker and the second tracker.

19. A signal characterisation device for estimating characteristics of an input signal, the device comprising:
a first tracker configured to determine a first estimate of characteristics of the input signal;
a second tracker configured to determine a second estimate of the characteristics of the input signal; and
a control unit configured to perform the method of claim 1 to estimate characteristics of the input signal;
wherein at least one of the first tracker and the second tracker comprises or is derived from at least one Prism filter.

20. A method of filtering an input signal, the method comprising:
applying a sequence of one or more filter stages to the input signal, wherein:
the input to a first filter stage in the sequence is the input signal, and the input to any subsequent filter stages in the sequence is a respective downsampled signal generated by an immediately preceding filter stage; and
applying a respective filter stage of the sequence of one or more filter stages comprises:
heterodyning the input for the respective filter stage based on a respective target frequency and a respective filter frequency;
applying a respective convolutional filter to a subset of samples of the heterodyned input selected based on a respective downsampling factor, the respective convolutional filter configured to pass the respective filter frequency;
generating a respective downsampled signal from outputs of the respective convolutional filter applied to the subset of samples; and
applying a tracker stage to the downsampled signal generated by a final filter stage in the sequence of one or more filter stages, wherein applying the tracker stage comprises:
heterodyning the downsampled signal generated by the final filter stage based on a tracker target frequency and a tracker filter frequency;
applying a tracker filter to the heterodyned downsampled signal generated by the final filter stage to determine one or more characteristics of the input signal;
wherein each respective convolutional filter is derived from a network of Prism filters comprising at least one Prism filter, and the tracker filter comprises or is derived from at least one Prism filter, wherein each Prism filter is configured to evaluate double integrals of the form:
$${I}_{[ S \vert C ] [ S \vert C ]}^{h} = {m}^{2} {\int }_{- \frac{1}{m}}^{0} [ sin \vert cos ] ( 2 π hmt + q ) ( {\int }_{t - \frac{{1}_{}}{m}}^{t} [ sin \vert cos ] ( 2 π hmt + q ) \cdot s ( t ) dt ) dt ,$$
where s(t) is an input to the respective Prism filter, m is a characteristic frequency of the respective Prism filter, [sin|cos] represents a sine or a cosine operation, and q is an optional phase offset variable, and h is a harmonic number of the respective Prism filter.

21. The method of claim 1, wherein the input signal is, or is a representation of, an audio signal, video signal, communications signal, system control signal, seismological signal, biological signal, electrical power signal, radar signal, sonar signal, signal representing measurements of a mechanical or electrical system, or signal representing measurements of physical quantities measured by a scientific or industrial instrument.

22. The method of claim 1, wherein the input signal is, or is a representation of, a signal output by a sensor.

23. The method of claim 1, wherein the input signal is or represents a measurement taken by a Coriolis meter.

24. A Coriolis meter configured to perform the method of claim 1.

25. A computer program storing instructions which, when executed by a computer, cause the computer to perform the method of claim 1.
